(19) United States
(12) Patent Application Publication
(10) Pub. No.: US 2026/0371551 A1
(43) Pub. Date: Nov. 19, 2026

(54) SEMICONDUCTOR DEVICE

(71) Applicant: Semiconductor Energy Laboratory Co., Ltd., Atsugi-shi (JP)

(72) Inventors: Kazuki TSUDA, Atsugi (JP); Kiyotaka KIMURA, Isehara (JP); Yuto YAKUBO, Atsugi (JP)

(21) Appl. No.: 19/660,574

(22) Filed: Apr. 28, 2026

(30) Foreign Application Priority Data
May 9, 2025 (JP) 2025-078586

(51) Int. Cl. H10B 12/00; G11C 11/405

(52) U.S. Cl. CPC H10B 12/00; G11C 11/405

(57) ABSTRACT

A semiconductor device performing an arithmetic operation of a function with high accuracy is provided. The semiconductor device includes first and second circuits. The first circuit includes first and second input terminals and a first output terminal. The second circuit includes third and fourth input terminals and a second output terminal. The first circuit has functions of holding a first potential corresponding to a first current flowing through the first input terminal, generating a second current corresponding to the first potential, and making a fourth current flow through the first output terminal as a differential current between the second current and a third current flowing through the second input terminal. The second circuit has functions of holding a second potential corresponding to the third current flowing through the third input terminal, generating a fifth current corresponding to the second potential, and making a sixth current flow through the second output terminal as a differential current between a fifth current and the first current flowing through the fourth input terminal.

### BACKGROUND OF THE INVENTION

### 1. Field of the Invention

One embodiment of the present invention relates to a semiconductor device.

Note that one embodiment of the present invention is not limited to the above technical field. The technical field of the invention disclosed in this specification relates to an object, an operation method, or a manufacturing method. Alternatively, one embodiment of the present invention relates to a process, a machine, manufacture, or a composition of matter. Therefore, specific examples of the technical field of one embodiment of the present invention disclosed in this specification include a semiconductor device, a display device (including a liquid crystal display device), a light-emitting device, a power storage device, an imaging device, a memory device, a processing device, a signal processing device, a sensor, an arithmetic device (including a processor), an electronic device, a system, a driving method thereof, a manufacturing method thereof, and a testing method thereof.

### 2. Description of the Related Art

Integrated circuits that imitate the mechanism of the human brain are currently under active development. The integrated circuits incorporate electronic circuits as the brain mechanism and include circuits imitating neurons and synapses of the human brain. Such integrated circuits may therefore be referred to as “neuromorphic”, “brain-morphic”, or “brain-inspired” circuits, for example. The integrated circuits have a non-von Neumann architecture and are expected to be able to perform parallel processing with extremely low power consumption as compared with a von Neumann architecture, which consumes higher power with increasing processing speed.

An information processing model that imitates a biological neural network including neurons and synapses is referred to as an artificial neural network (ANN). An example of a “circuit that imitates a ‘synapse’” is a circuit that performs multiplication of a value of a signal transmitted between neurons and the connection strength between the neurons (a weight coefficient) together. Examples of a “circuit that imitates a ‘neuron’” include a circuit that sums the values of signals (the results of the multiplication) transmitted from a plurality of neurons to one neuron and a circuit that calculates a value of an activation function where the sum is substituted as a variable. As an example of a circuit that performs an arithmetic operation of an activation function, a circuit having a function of performing an arithmetic operation of a rectified linear unit (ReLU) function, which is a kind of an activation function used in an artificial neural network, is disclosed in Patent Documents 1 and 2.

### REFERENCE

[Patent Document 1] PCT International Publication No. 2021/165799
[Patent Document 2] PCT International Publication No. 2020/254909

### SUMMARY OF THE INVENTION

Note that the activation function used in an artificial neural network is not limited to the ReLU function, and often varies with the model of the artificial neural network. For example, in order to solve a vanishing gradient problem that may arise in an artificial neural network depending on the kind of the activation function, a sigmoid function, a Tanh function, or the like is sometimes used instead of the ReLU function. Furthermore, an identity function, a Leaky ReLU function, a Hard Tanh function, or the like, which can output a negative value, is also used as the activation function in some cases.

In the case where an arithmetic operation of a function is performed by an analog circuit, a value corresponding to the result of the arithmetic operation is output from the analog circuit. In that case, when the electrical characteristics vary among the transistors included in the analog circuit, the results of the arithmetic operation output from the analog circuit also vary, leading to low arithmetic operation accuracy in some cases.

An object of one embodiment of the present invention is to provide a semiconductor device capable of performing an arithmetic operation of a function. Another object of one embodiment of the present invention is to provide a semiconductor device capable of performing an arithmetic operation of a function with high accuracy. Another object of one embodiment of the present invention is to provide a semiconductor device with a small circuit area. Another object of one embodiment of the present invention is to provide a novel semiconductor device.

Note that objects of one embodiment of the present invention are not limited to the above objects. The above objects do not preclude the existence of other objects. Note that the other objects are objects that are not described in this section and are described below. The objects that are not described in this section are derived from the description of the specification, the drawings, and the like and can be extracted as appropriate from the description by those skilled in the art. Note that one embodiment of the present invention achieves at least one of the above objects and the other objects and does not necessarily achieve all of the above objects and the other objects.

One embodiment of the present invention includes a first circuit as a sample-and-hold circuit holding a potential corresponding to an input first current and generating a second current equal to the first current, and has a function of generating a differential current between the generated second current and a third current that is input separately. When the first current and the generated second current flow between a source and a drain of the same transistor, a difference between the input first current and the generated second current can be small.

Using the above circuit in combination with a circuit having the same structure, a current generation circuit, or the like enables an arithmetic operation of an identity function, a Hard Tanh function, or the like.

Specific structure examples of the semiconductor device of one embodiment of the present invention are described below.

(1)

One embodiment of the present invention is a semiconductor device including a first circuit and a second circuit. The first circuit includes a first input terminal, a second input terminal, and a first output terminal. The second circuit includes a third input terminal, a fourth input terminal, and a second output terminal. The first circuit has a function of holding a first potential corresponding to a first current flowing through the first input terminal, generating a second current corresponding to the first potential, and making a fourth current flow through the first output terminal as a differential current between a third current flowing through the second input terminal and the second current. The second circuit has a function of holding a second potential corresponding to the third current flowing through the third input terminal, generating a fifth current corresponding to the second potential, and making a sixth current flow through the second output terminal as a differential current between the first current flowing through the fourth input terminal and the fifth current.

(2)

In another embodiment of the present invention having the above structure (1), each of the first and second circuits may include first to fifth transistors and a first capacitor.

In each of the first and second circuits, it is preferable that one of a source and a drain of the first transistor be electrically connected to one of a source and a drain of the second transistor, one of a source and a drain of the third transistor, one of a source and a drain of the fourth transistor, and one of a source and a drain of the fifth transistor, and the other of the source and the drain of the fifth transistor be electrically connected to a gate of the fourth transistor and a first terminal of the first capacitor. In the first circuit, it is preferable that the other of the source and the drain of the first transistor be electrically connected to the first input terminal, the other of the source and the drain of the second transistor be electrically connected to the second input terminal, and the other of the source and the drain of the third transistor be electrically connected to the first output terminal. In the second circuit, it is preferable that the other of the source and the drain of the first transistor be electrically connected to the third input terminal, the other of the source and the drain of the second transistor be electrically connected to the fourth input terminal, and the other of the source and the drain of the third transistor be electrically connected to the second output terminal. It is preferable that the first input terminal be electrically connected to the fourth input terminal and the second input terminal be electrically connected to the third input terminal.

(3)

In another embodiment of the present invention having the above structure (2), in each of the first and second circuits, a gate of the first transistor may be electrically connected to a first wiring, a gate of the second transistor may be electrically connected to a second wiring, a gate of the third transistor may be electrically connected to a third wiring, and a gate of the fifth transistor may be electrically connected to a fourth wiring.

(4) In another embodiment of the present invention according to (1) or (2), in each of the first and second circuits, each of the first to fourth transistors may contain silicon in a channel formation region, and the fifth transistor may contain an oxide semiconductor in a channel formation region.

In each of the first and second circuits, the first to fourth transistors are preferably n-channel transistors or p-channel transistors.

(5)

Another embodiment of the present invention is a semiconductor device including a first circuit, a second circuit, a first current generation circuit, a second current generation circuit, and a current supply circuit. The first circuit includes a first input terminal, a second input terminal, and a first output terminal. The second circuit includes a third input terminal, a fourth input terminal, and a second output terminal. The first current generation circuit includes a fifth input terminal, a sixth input terminal, and a third output terminal. The second current generation circuit includes a seventh input terminal, an eighth input terminal, and a fourth output terminal. The current supply circuit includes a fifth output terminal and a sixth output terminal.

The first circuit has a function of holding a first potential corresponding to a first current flowing through the first input terminal, generating a second current corresponding to the first potential, and making a fourth current flow through the first output terminal as a differential current between a third current flowing through the second input terminal and the second current. The second circuit has a function of holding a second potential corresponding to the third current flowing through the third input terminal, generating a fifth current corresponding to the second potential, and making a sixth current flow through the second output terminal as a differential current between the first current flowing through the fourth input terminal and the fifth current. The current supply circuit has a function of generating a seventh current flowing through the fifth output terminal and an eighth current flowing through the sixth output terminal. The first current generation circuit has a function of generating a ninth current flowing through the third output terminal with reference to the smaller of the fourth current flowing through the fifth input terminal and the seventh current flowing through the sixth input terminal, with its mirroring function. The second current generation circuit has a function of generating a tenth current flowing through the fourth output terminal with reference to the smaller of the sixth current flowing through the seventh input terminal and the eighth current flowing through the eighth input terminal, with its mirroring function.

(6)

In another embodiment of the present invention according to (5), each of the first and second circuits may include first to fifth transistors and a first capacitor.

In each of the first and second circuits, it is preferable that one of a source and a drain of the first transistor be electrically connected to one of a source and a drain of the second transistor, one of a source and a drain of the third transistor, one of a source and a drain of the fourth transistor, and one of a source and a drain of the fifth transistor, and the other of the source and the drain of the fifth transistor be electrically connected to a gate of the fourth transistor and a first terminal of the first capacitor. In the first circuit, it is preferable that the other of the source and the drain of the first transistor be electrically connected to the first input terminal, the other of the source and the drain of the second transistor be electrically connected to the second input terminal, and the other of the source and the drain of the third transistor be electrically connected to the first output terminal. In the second circuit, it is preferable that the other of the source and the drain of the first transistor be electrically connected to the third input terminal, the other of the source and the drain of the second transistor be electrically connected to the fourth input terminal, and the other of the source and the drain of the third transistor be electrically connected to the second output terminal. It is preferable that the first input terminal be electrically connected to the fourth input terminal, and the second input terminal be electrically connected to the third input terminal.

(7)

In another embodiment of the present invention according to (6), each of the first and second current generation circuits may include sixth to eleventh transistors.

In the first current generation circuit, it is preferable that one of a source and a drain of the sixth transistor be electrically connected to the fifth input terminal, one of a source and a drain of the seventh transistor be electrically connected to the sixth input terminal, one of a source and a drain of the eighth transistor be electrically connected to the third output terminal, gates of the sixth to eighth transistors be electrically connected to one of the fifth and sixth input terminals, and gates of the ninth to eleventh transistors be electrically connected to the other of the fifth and sixth input terminals. In the second current generation circuit, it is preferable that one of the source and the drain of the sixth transistor be electrically connected to the seventh input terminal, one of the source and the drain of the seventh transistor be electrically connected to the eighth input terminal, one of the source and the drain of the eighth transistor be electrically connected to the fourth output terminal, the gates of the sixth to eighth transistors be electrically connected to one of the seventh and eighth input terminals, and the gates of the ninth to eleventh transistors be electrically connected to the other of the seventh and eighth input terminals. In each of the first and second current generation circuits, it is preferable that the other of the source and the drain of the sixth transistor be electrically connected to one of a source and a drain of the ninth transistor, the other of the source and the drain of the seventh transistor be electrically connected to one of a source and a drain of the tenth transistor, and the other of the source and the drain of the eighth transistor be electrically connected to one of a source and a drain of the eleventh transistor.

(8)

In another embodiment of the present invention according to (7), in each of the first and second circuits, a gate of the first transistor may be electrically connected to a first wiring, a gate of the second transistor may be electrically connected to a second wiring, a gate of the third transistor may be electrically connected to a third wiring, and a gate of the fifth transistor may be electrically connected to a fourth wiring.

(9)

In another embodiment of the present invention according to (7) or (8), in each of the first and second circuits, each of the first to fourth transistors may contain silicon in a channel formation region, and the fifth transistor may contain an oxide semiconductor in a channel formation region. In each of the first and second current generation circuits, each of the sixth to eleventh transistors may contain silicon in a channel formation region.

In each of the first and second circuits, the first to fourth transistors are preferably one of n-channel transistors and p-channel transistors. In each of the first and second current generation circuits, the sixth to eleventh transistors are preferably the other of the n-channel transistors and the p-channel transistors.

When the semiconductor device of one embodiment of the present invention has the above structure (1), a difference between the first current, which is the input current, and the generated second current, which is the output current, can be small in the first circuit. The use of the second current and the input third current allows the fourth current to be a highly accurate differential current. The same applies to the second circuit. With the fourth current output from the first circuit and the sixth current output from the second circuit, a highly accurate arithmetic operation result of an identity function can be expressed. When the semiconductor device of one embodiment of the present invention has the above structure (5), a highly accurate arithmetic operation result of a Hard Tanh function can be expressed.

One embodiment of the present invention can provide a semiconductor device capable of performing an arithmetic operation of a function. Another embodiment of the present invention can provide a semiconductor device capable of performing an arithmetic operation of a function with high accuracy. Another embodiment of the present invention can provide a semiconductor device with a small circuit area. Another embodiment of the present invention can provide a novel semiconductor device.

Note that the effects of one embodiment of the present invention are not limited to the effects mentioned above. The above effects do not preclude the existence of other effects. Note that the other effects are effects that are not described in this section and are described below. The effects that are not described in this section are derived from the description of the specification, the drawings, and the like and can be extracted as appropriate from the description by those skilled in the art. Note that one embodiment of the present invention has at least one of the above effect. Accordingly, one embodiment of the present invention does not have the effects listed above in some cases.

### BRIEF DESCRIPTION OF THE DRAWINGS

FIG. 1A is a circuit diagram illustrating a structure example of a semiconductor device, and

FIG. 1B is a timing chart showing an operation example of the semiconductor device.

FIG. 2 is a graph showing the relationship between variables and outputs of a function calculated by a semiconductor device.

FIGS. 3A to 3C are circuit diagrams illustrating structure examples of a semiconductor device.

FIG. 4 is a block diagram illustrating a structure example of a semiconductor device.

FIG. 5 is a graph showing the relationship between variables and outputs of a function calculated by a semiconductor device.

FIGS. 6A and 6B are circuit diagrams illustrating structure examples of a semiconductor device.

FIG. 7 is a block diagram illustrating a structure example of a semiconductor device.

FIG. 8 is a circuit diagram illustrating a structure example of a semiconductor device.

FIGS. 9A and 9B are circuit diagrams illustrating structure examples of a current generation circuit included in a semiconductor device.

FIG. 10 is a graph showing the relationship between variables and outputs of a function calculated by a semiconductor device.

FIG. 11 is a block diagram illustrating a structure example of a semiconductor device.

FIG. 12 is a graph showing the relationship between variables and outputs of a function calculated by a semiconductor device.

FIG. 13 is a circuit diagram illustrating a structure example of a semiconductor device.

FIG. 14 is a circuit diagram illustrating a structure example of a semiconductor device.

FIGS. 15A to 15B are circuit diagrams illustrating structure examples of a current generation circuit included in a semiconductor device.

FIGS. 16A to 16D are circuit diagrams illustrating structure examples of a current source circuit included in a semiconductor device.

FIGS. 17A to 17C are circuit diagrams illustrating structure examples of a current generation circuit included in a semiconductor device.

FIG. 18 is a circuit diagram illustrating a structure example of a semiconductor device.

FIG. 19 is a timing chart showing an operation example of a semiconductor device.

FIG. 20 is a circuit diagram illustrating a structure example of a current generation circuit included in a semiconductor device.

FIG. 21 is a block diagram illustrating a structure example of a semiconductor device.

FIG. 22 is a block diagram illustrating a structure example of a semiconductor device.

FIG. 23 is a block diagram illustrating a structure example of a semiconductor device.

FIG. 24 is a schematic plan view illustrating a structure example of a semiconductor device.

FIG. 25 is a schematic cross-sectional view illustrating a structure example of a semiconductor device.

FIGS. 26A and 26B are schematic cross-sectional views illustrating structure examples of a transistor included in an arithmetic device.

FIGS. 27A and 27B are schematic cross-sectional views illustrating a structure example of a transistor included in an arithmetic device.

FIGS. 28A to 28D illustrate examples of electronic components.

FIG. 29 illustrates an example of an information processing system.

FIG. 30 illustrates an example of space equipment.

FIG. 31 illustrates an example of a storage system that can be used in a data center.

FIGS. 32A1 to 32A7 and FIGS. 32B1 to 32B6 are circuit diagrams showing electrical connection.

### DETAILED DESCRIPTION OF THE INVENTION

(Supplementary Notes on this Specification)

In this specification and the like, a semiconductor device means a device that utilizes semiconductor characteristics, and refers to a circuit including a semiconductor element (e.g., a transistor, a diode, or a photodiode), and a device including the circuit. The semiconductor device also means all devices that can function by utilizing semiconductor characteristics. As an example of a semiconductor device, an integrated circuit can be given. As another example of a semiconductor device, a chip including an integrated circuit can be given. As another example of a semiconductor device, an electronic component in which a chip is stored in a package can be given. Furthermore, a memory device, a display device, a light-emitting device, a lighting device, and an electronic device themselves are semiconductor devices in some cases and include a semiconductor device in other cases.

The expression “connection” in this specification includes “electrical connection”, for example.

When the expression “electrical connection” is used to specify the connection relation of a circuit element as an object, “electrical connection” includes “direct connection” and “indirect connection”, for example. The expression “A and B are directly connected” means that A and B are connected to each other without a circuit element (e.g., a transistor or a switch; a wiring is not a circuit element) therebetween, for example. Meanwhile, the expression “A and B are indirectly connected” means that A and B are connected to each other with at least one circuit element therebetween, for example. Note that A, B, and later-described C each denote an object such as an element, a circuit, a wiring, an electrode, a terminal, a semiconductor layer, or a conductive layer.

Here, in the case where a connection relation is specified as “A and B are indirectly connected”, the following connection relations are included, for example. That is, on the assumption that a circuit is in operation, the circuit can be specified as “A and B are indirectly connected” as an object when electric signal transmission and reception, potential interaction, or the like between A and B occurs at some point during the operation period of the circuit. Note that even when neither electric signal transmission and reception nor potential interaction between A and B occurs at some point during the operation of the circuit, the circuit can be specified as “A and B are indirectly connected” as long as electric signal transmission and reception or potential interaction between A and B occurs at another point during the operation period of the circuit. Note that the expression “A and B are indirectly connected” specifies the connection relation of a circuit element as an object. Thus, even when a circuit is not supplied with a power supply voltage and is not in operation, for example, the circuit can be specified as “A and B are indirectly connected” as an object (note that this specification is limited to, for example, the case where electric signal transmission and reception, potential interaction, or the like between A and B occurs during the operation period of the circuit when the circuit is supplied with a power supply voltage to be in operation).

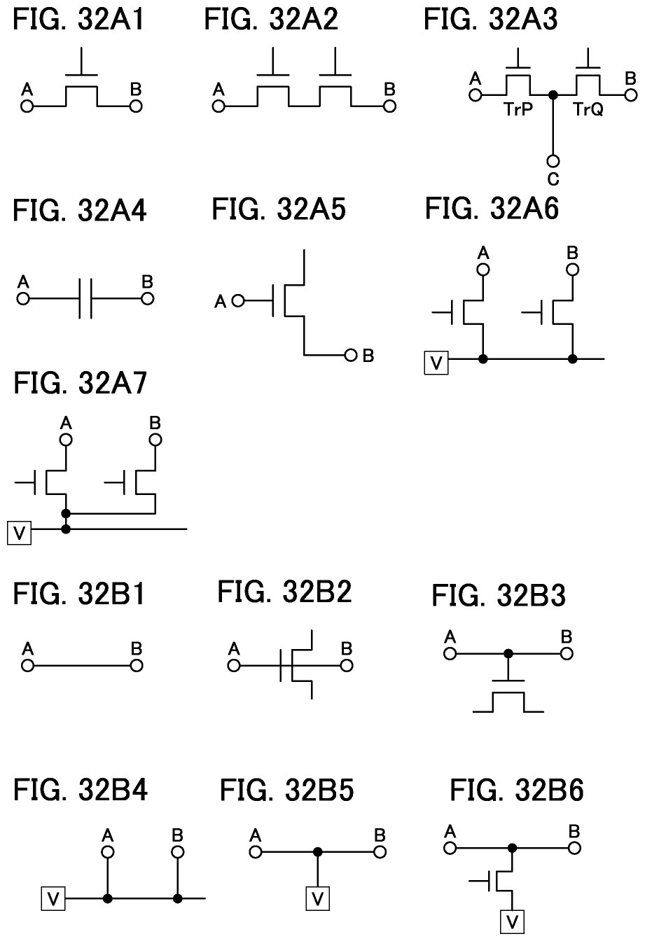

Specific examples of the case of “indirect connection” are described below. First, examples of the case where the expression “A and B are indirectly connected” can be used include the case where A and B are connected to each other through a source and a drain of at least one transistor as in FIGS. 32A1 and 32A2. Another example thereof is the case where A and B are connected to each other with at least one switch therebetween. In the case where the expression “A and B are indirectly connected” can be used, one transistor between A and B is brought into an on state, a conduction state, or a state where current can flow at least once on the assumption that a circuit is in operation. The case where the expression “A and B are indirectly connected” can be used may include a period in which the one transistor between A and B is brought into an off state or a non-conduction state. In the case where the expression “A and B are indirectly connected” can be used, each of a plurality of transistors between A and B is brought into an on state, a conduction state, or a state where current can flow at least once when the plurality of transistors are connected between A and B on the assumption that a circuit is in operation. That is, in the case where the expression “A and B are indirectly connected” can be used, it is not necessary that all of the plurality of transistors be brought into an on state, a conduction state, or a state where current can flow at the same time. Accordingly, in the case where the expression “A and B are indirectly connected” can be used, the plurality of transistors between A and B may be brought into an off state or a non-conduction state at the same time or at different times. For another example, when A and C are connected to each other through a source and a drain of a transistor TrP and B and C are connected to each other through a source and a drain of a transistor TrQ as illustrated in FIG. 32A3, it can be specified as “A and C are indirectly connected”, “B and C are indirectly connected”, or “A and B are indirectly connected”. Note that in the case where a constant potential V is supplied to C from a power source, GND, or the like as described later, the expression “A and C are indirectly connected” or “B and C are indirectly connected” can be used; however, the expression “A and B are indirectly connected” cannot be used.

The examples of the cases where the expression “indirect connection” can be used and cannot be used are described above, and another example of the case where the expression “indirect connection” cannot be used is described below. Even when electric signal transmission and reception, potential interaction, or the like between A and B occurs during the operation period of the circuit, the expression “A and B are indirectly connected” cannot be used in some cases exceptionally. Examples of the exceptional case include the case where A and B are connected to each other with an insulator therebetween. That is, in the case where A and B are connected to each other with an insulator therebetween, the expression “A and B are indirectly connected” cannot be used. A specific example of the case where A and B are connected to each other with an insulator therebetween is the case where a capacitor is connected between A and B as in FIG. 32A4. Another example thereof is the case where there is a gate insulating film of a transistor or the like between A and B as in FIG. 32A5. In this case, the expression “A (a gate of the transistor) and B (a source or a drain of the transistor) are indirectly connected” cannot be used.

Another example of the case where the expression “A and B are indirectly connected” cannot be used is the case where neither electric signal transmission and reception nor potential interaction between A and B occurs. For example, a plurality of transistors are connected through their sources and drains on the path from A to B and a constant potential V is supplied from a power source, GND, or the like to a node between one of the transistors and another one of the transistors as in FIGS. 32A6 and 32A7. In this case, the expression “A and B are indirectly connected” cannot be used; however, the expression “A and V are indirectly connected” or “B and V are indirectly connected” can be used. Note that in FIG. 32A3, when A and C are connected to each other through the source and the drain of the transistor TrP, B and C are connected to each other through the source and the drain of the transistor TrQ, and a constant potential V is supplied to C from a power source, a GND, or the like, the same connection relation as that in FIGS. 32A6 and 32A7 is established; thus, the expression “A and B are indirectly connected” cannot be used; however, the expression “A and C are indirectly connected” or “B and C are indirectly connected” can be used.

The examples of “indirect connection” are described above. The specification of “indirect connection” is included in the specification of “electrical connection”, for example; thus, in the case where the expression “A and B are indirectly connected” is used, the expression “A and B are electrically connected” can also be used.

Next, specific examples of the case of “direct connection” are described. Examples of the case where the expression “A and B are directly connected” can be used include the case where A and B are connected to each other without a circuit element therebetween as in FIGS. 32B1, 32B2, and 32B3. When A and B are connected to a power source, GND, or the like from which a constant potential V is supplied without a circuit element therebetween as in FIGS. 32B4 and 32B5, the expression “A and B are directly connected”, “A and V are directly connected”, or “B and V are directly connected” can be used. Note that when A (or B) is connected to a constant potential V through a source and a drain of a transistor as in FIG. 32B6, the expression “A and B are directly connected” can also be used. Note that A and V or B and V are connected to each other through the source and the drain of the transistor, and thus, they cannot be regarded as being in direct connection, and the expression “A and V are indirectly connected” or “B and V are indirectly connected” can be used.

The examples of “direct connection” are described above. The specification of “direct connection” is included in the specification of “electrical connection”, for example; thus, in the case where the expression “A and B are directly connected” is used, the expression “A and B are electrically connected” can also be used.

Even when independent components are connected to each other in a circuit diagram, one component has functions of a plurality of components in some cases. For example, when part of a “wiring” also functions as an “electrode”, one conductive film has functions of both components: a function of the “wiring” and a function of the “electrode”. For example, when part of a “wiring” also functions as a “terminal”, one conductive film has functions of both components: a function of the “wiring” and a function of the “terminal”. Thus, it can be sometimes said that two or more selected from “electrode”, “wiring”, and “terminal” are formed in an integrated manner. Moreover, the terms “electrode”, “wiring”, and “terminal” are sometimes replaced with the term “region”, for example. Thus, “connection” in this specification includes in its category such a case where one conductive film has functions of a plurality of components.

The term “switch” mentioned in this specification is described as an element that is turned on or off, thereby having a function of controlling whether current flows or not or a function of selecting and switching a path where current flows.

In this specification, the expression “conduction state” refers to a state where current can flow between two input/output terminals, and the expression “non-conduction state” refers to a state where the two input/output terminals are regarded as being electrically disconnected. In this specification, the on state of the switch is included in the scope of “conduction state”, and the off state of the switch is included in the scope of “non-conduction state”. Thus, for the switch in this specification, the expressions “conduction state” and “on state” can be replaced with each other, and the expressions “non-conduction state” and “off state” can be replaced with each other.

In this specification, the expression “electrical continuity” or “conduction state” used in the case where conductive layers are in direct contact with each other refers to a state where current can flow between the conductive layers, for example.

The switch may have two or more terminals through which current flows, in addition to a control terminal. For example, an electrical switch or a mechanical switch can be used. That is, the switch is not limited to a certain element as long as it has a function of controlling current.

Examples of an electrical switch include a transistor (e.g., a bipolar transistor and a MOS transistor), a diode (e.g., a PN diode, a PIN diode, a Schottky diode, a metal-insulator-metal (MIM) diode, a metal-insulator-semiconductor (MIS) diode, and a diode-connected transistor), and a logic circuit combining such elements. An example of a mechanical switch is a switch using a microelectromechanical systems (MEMS) technology. Such a switch includes an electrode that can be moved mechanically, and its on state and off state are controlled with movement of the electrode.

In this specification and the like, a transistor includes three terminals called a gate, a source, and a drain. The gate is a control terminal for controlling the conduction state and the non-conduction state of the transistor. The two terminals functioning as the source and the drain are input/output terminals of the transistor. Functions of the two input/output terminals of the transistor depend on the conductivity type (n-channel type or p-channel type) of the transistor and the levels of potentials applied to the three terminals of the transistor, and one of the two terminals serves as a source and the other serves as a drain. Therefore, the terms “source” and “drain” can be sometimes used interchangeably in this specification and the like. In this specification, the expressions “one of a source and a drain” and “the other of the source and the drain” are used in description of the connection relationship of a transistor. In this specification, one of a source and a drain is sometimes referred to as a “first electrode of a transistor” or a “first terminal of a transistor”, and the other of the source and the drain is sometimes referred to as a “second electrode of a transistor” or a “second terminal of a transistor”. Depending on the structure, a transistor may include a back gate in addition to the above three terminals. In that case, in this specification and the like, one of the gate and the back gate of the transistor may be referred to as a first gate and the other of the gate and the back gate of the transistor may be referred to as a second gate. In some cases, the terms “gate” and “back gate” can be replaced with each other in one transistor. In the case where a transistor includes three or more gates, the gates may be referred to as a first gate, a second gate, and a third gate, for example, in this specification and the like.

Examples of the transistor described in this specification include a transistor with a multi-gate structure having two or more gate electrodes in some cases. With the multi-gate structure, channel formation regions are connected in series; accordingly, a plurality of transistors are connected in series. Thus, with the multi-gate structure, the amount of off-state current can be reduced, and the breakdown voltage of the transistor can be increased (the reliability can be improved). Moreover, with the multi-gate structure, a source-drain current (I_{d}) does not change very much even if a drain-source voltage (V_{ds}) changes when the transistor operates in a saturation region of I_{d}−V_{ds} characteristics, so that a flat slope of the I_{d}−V_{ds} characteristics can be obtained. By utilizing the flat slope of the I_{d}−V_{ds} characteristics, an ideal current source circuit or an active load having an extremely high resistance can be obtained. Accordingly, a differential circuit, a current mirror circuit, or the like having excellent properties can be obtained.

In this specification, a current means an electric charge transfer (electrical conduction); for example, the expression “electrical conduction of positively charged particles is caused” can be replaced with “electrical conduction of negatively charged particles is caused in the opposite direction”. Therefore, unless otherwise specified, a “current” in this specification and the like refers to an electric charge transfer phenomenon (electrical conduction) caused by carrier movement. Examples of a carrier here include an electron, a hole, an anion, a cation, and a complex ion, and the type of carrier differs between current flow systems (e.g., a semiconductor, a metal, an electrolyte solution, and a vacuum). The direction of a current in a wiring or the like refers to the direction in which a carrier with a positive electric charge moves, and the current amount is expressed as a positive value. In other words, the direction in which a carrier with a negative electric charge moves is opposite to the direction of a current, and the current amount is expressed as a negative value. Thus, in the case where the polarity of a current (or the direction of a current) is not specified in this specification and the like, the expression “a current flows from an element A to an element B” can be replaced with “a current flows from an element B to an element A”.

In this specification, the description “a current flows through an input terminal of a circuit”, for example, does not limit the direction of the current. For example, in the description “a current flows through an input terminal of a circuit”, the current is not limited to a current flowing from the outside to the input terminal of the circuit, i.e., a sink current, and is sometimes a current flowing from the input terminal of the circuit to the outside, i.e., a discharge current. Similarly, for example, in the description “a current flows through an output terminal of a circuit”, the current is not limited to a current flowing from the output terminal of the circuit to the outside, i.e., a discharge current, and is sometimes a current flowing from the outside to the output terminal of the circuit, i.e., a sink current.

In this specification, a current sometimes refers to the amount of electric charge flowing per unit time. For example, in the case where the term “current T” is used in this specification, “I” is used not only as a symbol or a reference numeral for distinguishing it from other currents but also as a variable representing the amount of electric charge flowing per unit time. Thus, for example, the description “current I flows through an input terminal of a circuit” means that “current denoted by I flows through an input terminal of a circuit” and “electric charge in an amount of I flows through an input terminal of a circuit per unit time”.

Ordinal numbers such as “first”, “second”, and “third” in this specification and the like are used in order to avoid confusion among components. Thus, the terms do not limit the number of components. The terms do not limit the order of components including, for example, the order of steps, the stacking order of layers, either. A term without an ordinal number in this specification might be provided with an ordinal number in a claim in order to avoid confusion among components. A term with an ordinal number in this specification might be provided with a different ordinal number in a claim. Moreover, a term with an ordinal number in this specification might not be provided with any ordinal number in a claim and the like. For example, a component provided with an ordinal number “first” in one embodiment in this specification can be a component provided with a different ordinal number such as “second” or “third” in other embodiments or the scope of claims. For another example, a component provided with an ordinal number “first” in one embodiment in this specification can be omitted in other embodiments or the scope of claims.

In this specification, the expression “A and B are equal” means that the ratio of one of A and B to the other is greater than or equal to 0.9 and less than or equal to 1.1 unless otherwise specified. Note that the expression “A and B are equal” is also used in the case where the ratio of B to A is greater than or equal to 0.9 and less than or equal to 1.1 and the ratio of A to B is not greater than or equal to 0.9 and less than or equal to 1.1, for example. The expression “A and B are substantially equal” means that the ratio of one of A and B to the other is greater than or equal to 0.8 and less than or equal to 1.2 unless otherwise specified. Note that the expression “A and B are substantially equal” is also used in the case where the ratio of B to A is greater than or equal to 0.8 and less than or equal to 1.2 and the ratio of A to B is not greater than or equal to 0.8 and less than or equal to 1.2, for example.

In this specification and the like, a timing chart is used in some cases to describe an operation method of a semiconductor device. In this specification and the like, the timing chart shows an ideal operation example, and a period, a level of a signal (e.g., a potential or a current), and a timing described in the timing chart are not limited unless otherwise specified. In the timing chart described in this specification and the like, the level of a signal (e.g., a potential or a current) input to a wiring (including a node) and a timing can be changed as appropriate depending on the circumstances. For example, even when two periods are shown to have an equal length, the two periods have different lengths in some cases. Furthermore, for example, even when one of two periods is shown longer than the other, the two periods can have the equal length in some cases, or the one of the two periods has a shorter length than the other in other cases. To clearly show the timing chart, two or more overlapping signals are sometimes shown to be intentionally shifted from each other, for example.

The embodiments in this specification are described with reference to drawings. Note that the embodiments can be implemented in many different modes, and it will be readily appreciated by those skilled in the art that modes and details can be changed in various ways without departing from the spirit and scope of the present invention. Therefore, the present invention should not be construed as being limited to the description of the embodiments. Note that in the structures of the invention described in the embodiments, the same portions or portions having similar functions are denoted by the same reference numerals in different drawings and the description of such portions is not repeated in some cases. In order to clarify a component to be described in drawings such as perspective views, illustration of another component might be omitted.

In this specification and the like, when a plurality of components denoted by the same reference numerals need to be distinguished from each other, identification signs such as “_1”, “[n]”, and “[m,n]” are sometimes added to the reference numerals. Components denoted with identification signs such as “_1”, “[n]”, and “[m,n]” in drawings and the like are sometimes denoted without such identification signs in this specification and the like when the components do not need to be distinguished from each other.

In the drawings of this specification, the size, the layer thickness, or the region is exaggerated for clarity in some cases. Thus, the size, the layer thickness, or the region is not limited to the shown scale. The drawings are schematic views showing ideal examples, and embodiments of the present invention are not limited to shapes, values, or the like shown in the drawings. For example, the following can be included: a variation in a signal, a voltage, or a current due to noise or difference in timing.

### Embodiment 1

In this embodiment, a semiconductor device of one embodiment of the present invention will be described.

### Structure Example 1 of Semiconductor Device

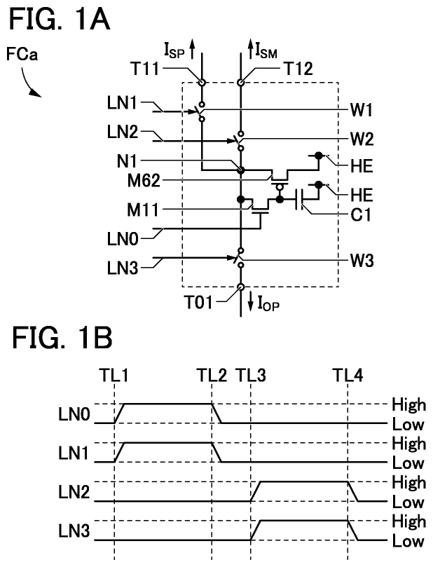

FIG. 1A is a circuit diagram illustrating a structure example of a circuit that is the semiconductor device of one embodiment of the present invention and can perform an arithmetic operation of a function. In particular, the circuit can perform an arithmetic operation of a ReLU function that can be used as an activation function of an artificial neural network, for example. A circuit FCa illustrated in FIG. 1A can perform an arithmetic operation of a ReLU function with high accuracy.

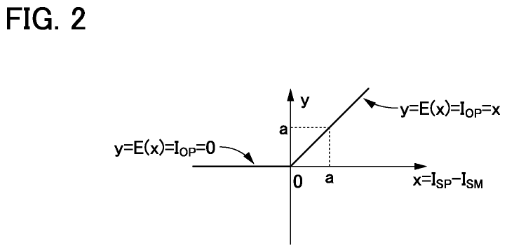

FIG. 2 is a graph where x(=I_{SP}−I_{SM}) represents a differential current between a current I_{SP} flowing through a first input terminal (a terminal T11 described later) and a current I_{SM} flowing through a second input terminal (a terminal T12 described later) and y represents a current I_{OP} flowing through an output terminal (a terminal T01 described later) in the circuit FCa. Specifically, y=E(x) is indicated by a thick solid line in FIG. 2. Note that a shown in FIG. 2 is a given current that is greater than 0 [A] and within the possible range of I_{SP}−I_{SM}.

As shown in FIG. 2, in the case where I_{SP} is larger than I_{SM}(x>0) in the circuit FCa, the current I_{OP}=x flows through the terminal T01 as the result of the arithmetic operation of the ReLU function where x(=I_{SP}−I_{SM}>0) is substituted as a variable. In the case where I_{SM} is larger than I_{SP}(x<0) in the circuit FCa, the result of the arithmetic operation of the ReLU function where x(=I_{SP}−I_{SM}<0) is substituted as a variable is I_{OP}=0; thus, a current does not flow through the terminal T01. In the case where I_{SP} and I_{SM} are equal to each other (x=0) in the circuit FCa, the result of the arithmetic operation of the ReLU function where x=0 is substituted as a variable is I_{OP}=0; thus, a current does not flow through the terminal T01 also in this case.

As described above, the circuit FCa can perform the arithmetic operation of the ReLU function where the differential current between the currents I_{SP} and I_{SM} is used as the variable x; y=E(x)=I_{OP}=x when x>0, and y=E(x)=I_{OP}=0 when x<0.

The circuit FCa includes, for example, a transistor M11 that is an n-channel transistor, a transistor M62 that is a p-channel transistor, a switch W1, a switch W2, a switch W3, and a capacitor C1. The circuit FCa includes terminals T11 and T12 functioning as input terminals and the terminal T01 functioning as an output terminal, for example.

In addition, the current I_{SP} flowing through the terminal T11, the current I_{SM} flowing through the terminal T12, and the current I_{OP} flowing through the terminal T01 are shown. Note that the currents I_{SP}, I_{SM}, and I_{OP} are each a discharge current in the circuit FCa. Thus, the circuit FCa has a function of a current source circuit.

The circuit FCa also has a function of a current sample-and-hold circuit. Specifically, the circuit FCa has a function of holding a potential corresponding to the current I_{SP} flowing through the terminal T11 and a function of generating a current equal to the current I_{SP} using the potential. Furthermore, the circuit FCa also has a function of making the current I_{OP} flow through the terminal T01 as a differential current between the current I_{SM} flowing through the terminal T12 and the generated current I_{SP}. Note that in the circuit FCa, when I_{SP}−I_{SM}>0, I_{OP}=I_{SP}−I_{SM} and the current I_{OP} flows through the terminal T01, and when I_{SP}−I_{SM}≤0, I_{OP}=0 and a current does not flow through the terminal T01.

As each of the switches W1 to W3, an electrical switch can be used, for example. As the electrical switch, a transistor can be used, for example. In particular, an OS transistor having a characteristic of an extremely low off-state current described later or an analog switch combining a plurality of transistors is preferably used as the electrical switch. Other than the electrical switch, a mechanical switch may be used as each of the switches W1 to W3, for example.

Note that each of the switches W1 to W3 described in this embodiment is a switching circuit or a switching element whose on state or off state is determined by a potential supplied to a control terminal, for example. Here, each of the switches W1 to W3 is turned on when a high-level potential is supplied to the control terminal as a control signal, and turned off when a low-level potential is supplied to the control terminal as a control signal.

The transistor M62 that is a p-channel transistor has a function of obtaining a gate potential corresponding to the current I_{SP}, which flows from the terminal T11 to its source and drain. Note that the gate potential is held in the capacitor C1. The transistor M62 has a function of generating the current I_{SP} as a source-drain current corresponding to a gate-source voltage.

As the transistor M62, a transistor containing silicon in a channel formation region (also referred to as Si transistor) can be used, for example. As the silicon, amorphous silicon, microcrystalline silicon, polycrystalline silicon, or single crystal silicon can be used. Low temperature polysilicon (LTPS) is included as a type of polycrystalline silicon. LTPS can be formed at a temperature equivalent to that for forming amorphous silicon and thus enables low manufacturing cost. In this specification, a transistor containing LTPS in a channel formation region is referred to as an LTPS transistor in some cases.

The Si transistor has high field-effect mobility and thus can make a large amount of on-state current flow. In some cases, this can increase the driving speed of the circuit FCa and expand the range of analog current that can be handled by the circuit FCa, for example.

The transistor M11 that is an n-channel transistor has a function of a switching transistor. Thus, a transistor containing an oxide semiconductor in a channel formation region (also referred to as an OS transistor) is preferably used as the transistor M11. Since the OS transistor has a characteristic of an extremely low source-drain current flowing in an off state (such a current is also referred to as an off-state current), a malfunction due to the off-state current can be prevented. Examples of an oxide semiconductor include indium oxide and an indium gallium zinc oxide. In particular, a transistor containing indium oxide in a channel formation region (hereinafter referred to as an IO transistor) can have characteristics of a low off-state current and a high on-state current. Thus, when an IO transistor is used as the transistor M11, a malfunction due to an off-state current can be prevented, and a high operation speed owing to a high on-state current can be achieved. Note that indium oxide will be described later in Embodiment 4.

The OS transistor can be formed through a deposition step by physical vapor deposition, chemical vapor deposition, or the like and a patterning step by a lithography method or the like, which allows the OS transistor to be provided above a Si transistor after formation of the Si transistor, for example. Thus, the transistor M62 that is a p-channel transistor can be formed as a Si transistor first, and then the transistor M11 that is an n-channel transistor can be provided as an OS transistor above the transistor M62. That is, the transistors can be provided to overlap with each other, reducing the area of the circuit FCa.

As the transistor M11, a Si transistor may be used instead of an OS transistor. When a Si transistor is used as the transistor M11 as well as the transistor M62, the time required for manufacturing the circuit FCa can be shortened.

A first terminal of the switch W1 is connected to the terminal T11, a first terminal of the switch W2 is connected to the terminal T12, and a first terminal of the switch W3 is connected to the terminal T01. A first terminal of the transistor M11 is connected to a second terminal of the switch W1, a second terminal of the switch W2, a second terminal of the switch W3, and a first terminal of the transistor M62. A second terminal of the transistor M11 is connected to a gate of the transistor M62 and a first terminal of the capacitor C1. A second terminal of the transistor M62 is connected to a wiring HE. A second terminal of the capacitor C1 is connected to the wiring HE.

Note that in this embodiment, a connection portion of the first terminal of the transistor M11, the second terminal of the switch W1, the second terminal of the switch W2, the second terminal of the switch W3, and the first terminal of the transistor M62 is referred to as a node N1.

A gate of the transistor M11 is connected to a wiring LN0. The control terminal of the switch W1 is connected to a wiring LN1, the control terminal of the switch W2 is connected to a wiring LN2, and the control terminal of the switch W3 is connected to a wiring LN3.

The wiring HE connected to the second terminal of the transistor M62 functions as a wiring for supplying a fixed potential, for example. The fixed potential is preferably a high-level potential at which the second terminal of the transistor M62 serves as a source.

The capacitor C1 holds the gate potential of the transistor M62. Since the wiring HE is connected to the second terminal of the capacitor C1, the capacitor C1 can hold a voltage between the gate and the first terminal of the transistor M62. In particular, in the case where the fixed potential supplied from the wiring HE is a high-level potential at which the second terminal of the transistor M62 serves as a source, the capacitor C1 holds the gate-source voltage of the transistor M62.

Note that the wiring HE connected to the capacitor C1 may be different from the wiring HE connected to the second terminal of the transistor M62. In this case, a fixed potential supplied to the wiring HE connected to the capacitor C1 can be different from a fixed potential supplied to the wiring HE connected to the second terminal of the transistor M62.

The wiring LN0 functions as a wiring for transmitting a control signal to switch the on state and the off state of the transistor M11. For example, the transistor M11 is turned on when the control signal is a high-level potential, and turned off when the control signal is a low-level potential.

The wirings LN1 to LN3 function as wirings for transmitting a control signal to switch the on state and the off state of the switches W1 to W3, respectively, for example.

Next, an operation example of the circuit FCa illustrated in FIG. 1A will be described.

FIG. 1B is a timing chart showing the operation example of the circuit FCa. Note that FIG. 1B shows changes in potentials, which are control signals supplied to the wirings LN0 to LN3, in and around the period from Time TL1 to Time TL4.

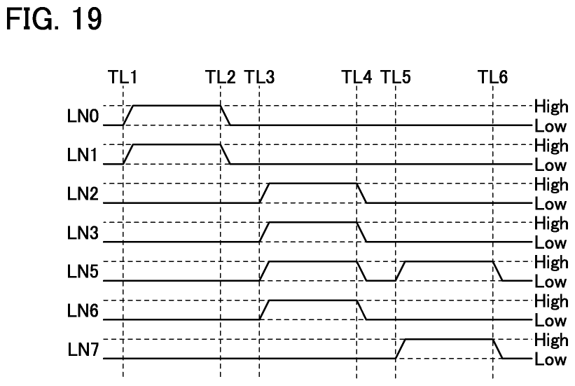

In the timing chart in FIG. 1B, reference numerals of wirings and the like are shown on the left side and the potential levels are shown on the right side. Specifically, in the timing chart, “High” represents a high-level potential of the wiring and “Low” represents a low-level potential of the wiring. Note that the same applies to the timing chart in FIG. 19 described later.

At Time TL1, a high-level potential is supplied to each of the wirings LN0 and LN1. Thus, the transistor M11 and the switch W1 are turned on.

At Time TL1, a low-level potential is supplied to each of the wirings LN2 and LN3. Thus, the switches W2 and W3 are turned off.

When the switch W1 is turned on, the current I_{SP} flows through the terminal T11 of the circuit FCa. Since the transistor M11 is also in an on state, electrical continuity is established between the gate and the first terminal of the transistor M62, and ideally, the voltage between the gate and the first terminal of the transistor M62 is 0 [V].

The current I_{SP} flows between the first and second terminals of the transistor M62 as a source-drain current. When the potential supplied to the wiring HE is a constant high-level potential, the gate potential of the transistor M62 is determined in accordance with the current I_{SP}, which is the source-drain current of the transistor M62.

At Time TL2, a low-level potential is supplied to each of the wirings LN0 and LN1. Thus, the transistor M11 and the switch W1 are turned off.

When the transistor M11 is turned off, the gate of the transistor M62 is brought into a floating state, and the gate potential of the transistor M62 is held by the capacitor C1. When the switch W1 is turned off, the current I_{SP} stops flowing through the terminal T11 of the circuit FCa.

At this time, the gate-source voltage of the transistor M62 corresponding to the current I_{SP} is held; this specification sometimes expresses it as “the source-drain current of the transistor M62 is fixed to I_{SP}”, “the source-drain current of the transistor M62 is maintained at I_{SP}”, “the source-drain current of the transistor M62 is stored as I_{SP}”, “I_{SP} is written (programed) as the source-drain current of the transistor M62”, or the like.

At Time TL3, a high-level potential is supplied to each of the wirings LN2 and LN3. Thus, the switches W2 and W3 are turned on.

When the switch W2 is turned on, the current I_{SM} flows through the terminal T12 of the circuit FCa. When the switch W3 is turned on, the current I_{OP} flows through the terminal T01 of the circuit FCa.

At this time, the gate potential of the transistor M62 is continuously held by the capacitor C1 and a high-level potential is continuously supplied to the second terminal of the transistor M62 from the wiring HE; thus, the transistor M62 functions as a current source and generates the current I_{SP} as the source-drain current between the first and second terminals.

At this time, the current I_{SP} flows from the first terminal of the transistor M62 to the node N1, and the current I_{SM} is discharged from the node N1 to the terminal T12. Here, when I_{SP}>I_{SM}, i.e., I_{SP}−I_{SM}>0, the differential current I_{SP}−I_{SM} is discharged as the current I_{OP} from the node N1 to the terminal T01 in accordance with Kirchhoff s current law.

When I_{SP}=I_{SM}, i.e., I_{SP}−I_{SM}=0, the source-drain current I_{SP} flowing through the transistor M62 and the current I_{SM} flowing through the terminal T12 are equal to each other, so that the current I_{OP} corresponding to the differential current becomes 0 [A] and a current does not flow through the terminal T01. In addition, when I_{SP}≤I_{SM}, i.e., I_{SP}−I_{SM}≤0, the current I_{SM} flowing through the terminal T12 gradually decreases and finally becomes equal to the source-drain current I_{SP} flowing through the transistor M62; thus, the current I_{OP} becomes 0 [A] and a current does not flow through the terminal T01 also in this case.

At Time TL4, a low-level potential is supplied to each of the wirings LN2 and LN3. Thus, the switches W2 and W3 are turned off. When the switch W2 is turned off, the current I_{SM} stops flowing through the terminal T12 of the circuit FCa, and when the switch W3 is turned off, the current I_{OP} stops flowing through the terminal T01 of the circuit FCa.

In the above manner, the circuit FCa in FIG. 1A can obtain a potential corresponding to the current I_{SP} flowing through the terminal T11 and generate the current I_{SP} by the transistor M62 at Time TL1, obtain a differential current between the current I_{SM} flowing through the terminal T12 and the generated current I_{SP} at Time TL3, and make the differential current flow through the terminal T01 as shown in the graph in FIG. 2. In particular, when I_{SP}>I_{SM}, I_{OP}=I_{SP}−I_{SM} can flow through the terminal T01 as the differential current, and when I_{SP}≤I_{SM}, I_{OP}=0 and the differential current between I_{SP} and I_{SM} does not flow through the terminal T01. That is, the circuit FCa in FIG. 1A can perform the arithmetic operation of the ReLU function as shown in FIG. 2.

As shown in the timing chart in FIG. 1B, a high-level potential or a low-level potential is supplied to the wirings LN0 and LN1 at the same timing. Thus, in the case where the circuit FCa in FIG. 1A operates in accordance with the timing chart in FIG. 1B, the wirings LN0 and LN1 may be combined into one wiring. Similarly, as shown in the timing chart in FIG. 1B, a high-level potential or a low-level potential is supplied to the wirings LN2 and LN3 at the same timing; thus, the wirings LN2 and LN3 may be combined into one wiring also in this case.

### Variation Example 1-1 of Semiconductor Device

Note that the structure of the semiconductor device of one embodiment of the present invention is not limited to the circuit structure in FIG. 1A. The semiconductor device of one embodiment of the present invention can have a structure which is changed from the circuit structure in FIG. 1A as appropriate.

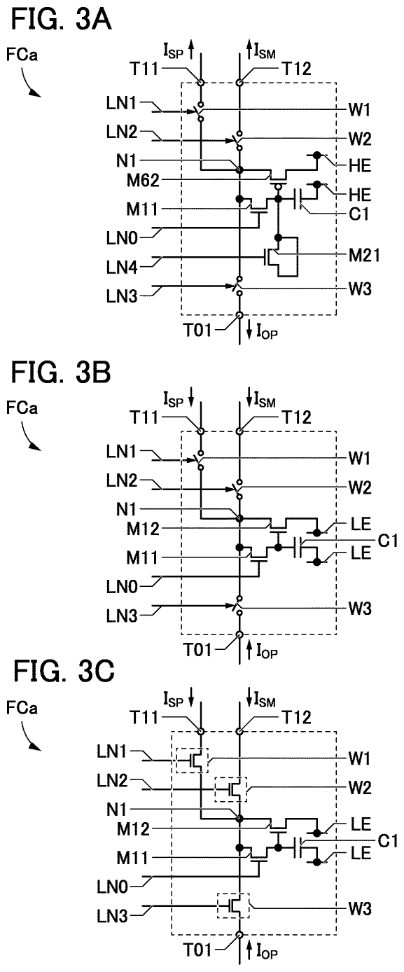

The circuit FCa illustrated in FIG. 3A is a variation example of the circuit FCa in FIG. 1A, and is different therefrom in including a transistor M21.

A first terminal and a second terminal of the transistor M21 are connected to the second terminal of the transistor M11, the gate of the transistor M62, and the first terminal of the capacitor C1. A gate of the transistor M21 is connected to a wiring LN4.

The wiring LN4 functions as a wiring supplying a potential to the gate of the transistor M21 in order to increase the gate potential of the transistor M62 by capacitive coupling when the transistor M11 is in an off state, i.e., when the gate of the transistor M62 is in a floating state, for example. Thus, the wiring LN4 functions as a wiring transmitting a signal with the inverted logic of a signal supplied to the wiring LN0.

The transistor M21, whose first and second terminals are connected to each other, has a function of a capacitor where the gate capacitance serves as capacitance. The gate capacitance of the transistor M21 is preferably equal to that of the transistor M11. Thus, the structure and the like of the transistor M21 are preferably the same as those of the transistor M11. Assuming the same structure, the size of the transistor M21 is preferably half the size of the transistor M11. For example, it is preferable that the channel length or the channel width of the transistor M21 be substantially half that of the transistor M11. It is further preferable that a transistor that can be used as the transistor M11 be used as the transistor M21, for example.

The transistor M21 is provided to prevent the gate potential of the transistor M62 from being changed by a potential supplied to the gate of the transistor M11. For example, in the circuit structure of the circuit FCa in FIG. 1A, when the gate potential of the transistor M11 changes from a high-level potential to a low-level potential, the gate potential of the transistor M62 sometimes decreases due to capacitive coupling by the gate capacitance of the transistor M11. Meanwhile, in the circuit FCa in FIG. 3A, the change in the gate potential of the transistor M62 can be roughly canceled by changing the gate potential of the transistor M11 from a high-level potential to a low-level potential and changing the gate potential of the transistor M21 from a low-level potential to a high-level potential.

In the circuit FCa, a capacitor having capacitance substantially equal to half the gate capacitance of the transistor M11 may be used instead of the transistor M21.

### Variation Example 1-2 of Semiconductor Device

The circuit FCa illustrated in FIG. 3B is a variation example of the circuit FCa in FIG. 1A, and is different therefrom in that a transistor M12 that is an n-channel transistor is provided instead of the transistor M62 that is a p-channel transistor.

In the circuit FCa in FIG. 3B, a first terminal of the transistor M12 is connected to the second terminal of the switch W1, the second terminal of the switch W2, the second terminal of the switch W3, and the first terminal of the transistor M11. A gate of the transistor M12 is connected to the second terminal of the transistor M11 and the first terminal of the capacitor C1. A second terminal of the transistor M12 is connected to a wiring LE, and the second terminal of the capacitor C1 is connected to the wiring LE.

The wiring LE connected to the second terminal of the transistor M12 functions as a wiring for supplying a fixed potential, for example. The fixed potential is preferably a low-level potential at which the second terminal of the transistor M12 serves as a source.

When the transistor M62 that is a p-channel transistor provided in the circuit FCa in FIG. 1A is changed into the transistor M12 that is an n-channel transistor, the directions of the currents I_{SP}, I_{SM}, and I_{OP} flowing respectively through the terminals T11, T12, and T01 can be changed. Specifically, the currents I_{SP}, I_{SM}, and I_{OP}, which are discharge currents in the circuit FCa in FIG. 1A, can be sink currents in the circuit FCa in FIG. 3B. In the case where the currents flowing through the terminals T11 and T12 of the circuit FCa are sink currents, with the use of the circuit FCa in FIG. 3B instead of that in FIG. 1A, an arithmetic operation of a ReLU function where the differential current between I_{SP} and I_{SM} is substituted as a variable can be performed and a sink current can flow through the terminal T01 as the arithmetic operation result, as in FIG. 1A.

FIG. 3C is a circuit diagram in which transistors are used as electrical switches as the switches W1 to W3 illustrated in FIG. 3B, for example. The transistor used as the switches W1 to W3 are n-channel transistors in FIG. 3C, and preferably OS transistors having a characteristic of an extremely low off-state current, as described above. In addition, when the transistors used as the switches W1 to W3 are n-channel transistors having the same polarity as the transistor M12, a decrease in the source-drain voltage of each of the transistors by the threshold voltage can be prevented. In each of the switches W1 to W3 in FIG. 3C, the first terminal corresponds to one of a source and a drain of the transistor, the second terminal corresponds to the other of the source and the drain of the transistor, and the control terminal corresponds to the gate of the transistor.

### Structure Example 2 of Semiconductor Device

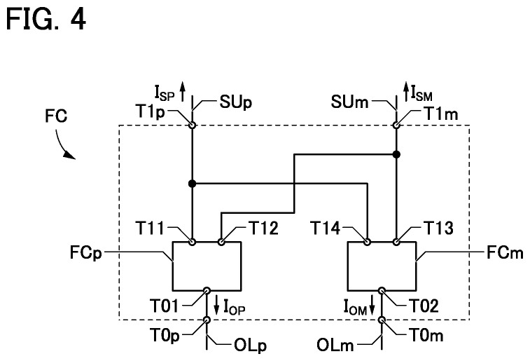

FIG. 4 is a block diagram illustrating a structure example of a circuit that is the semiconductor device of one embodiment of the present invention and can perform an arithmetic operation of a function, which is different from that in FIG. 1A. In particular, the circuit can perform an arithmetic operation of an identity function used as an activation function of an artificial neural network.

A circuit FC illustrated in FIG. 4 is connected to a wiring SUp, a wiring SUm, a wiring OLp, and a wiring OLm. The circuit FC has a function of obtaining the current I_{SP} flowing through the wiring SUp and the current I_{SM} flowing through the wiring SUm and generating the differential current between I_{SP} and I_{SM}. Note that in the circuit FC in FIG. 4, an output current flowing through the wiring OLp is denoted by I_{OP} and an output current flowing through the wiring OLm is denoted by I_{OM}. Note that I_{OP} is I_{SP}−I_{SM} when I_{SP}>I_{SM} and 0 [A] when I_{SP}≤I_{SM}. In addition, I_{OM} is I_{SM}−I_{SP} when I_{SM}>I_{SP} and 0 [A] when I_{SM}≤I_{SP}.

That is, when the current I_{SP} is larger than the current I_{SM} in the circuit FC, the current I_{OP}=I_{SP}−I_{SM} flows through the wiring OLp, and a current does not flow through the wiring OLm because I_{OM}=0. When the current I_{SM} is larger than the current I_{SP} in the circuit FC, a current does not flow through the wiring OLp because I_{OP}=0, and the current I_{OM}=I_{SM}−I_{SP} flows through the wiring OLm. When the currents I_{SM} and I_{SP} are equal to each other in the circuit FC, a current does not flow through the wiring OLp or OLm because I_{OP}−I_{OM}=0.

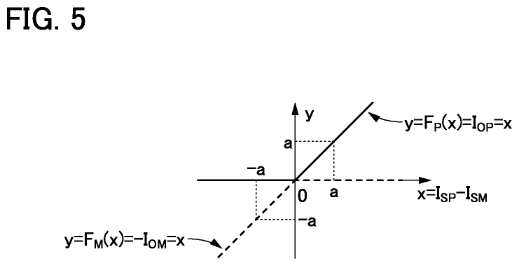

FIG. 5 is a graph where x(=I_{SP}−I_{SM}) represents the differential current between the current I_{SP} flowing through a first input terminal (a terminal T1p described later) and the current I_{SM} flowing through a second input terminal (a terminal T1m described later) and y represents the current I_{OP} flowing through a first output terminal (a terminal T0p described later) and a value obtained by multiplying −1 by I_{OM} flowing through a second output terminal (a terminal T0m described later), in the circuit FC. Specifically, in FIG. 5, y=F_{P}(x)=I_{OP}=x is indicated by a thick solid line, and y=F_{M}(x)=−I_{OM}=x is indicated by a thick dashed line. Note that a shown in FIG. 5 is a given current amount that is greater than 0 [A] and within the possible range of I_{SP}−I_{SM}, for example.

As shown in FIG. 5, in the case where the current I_{SP} is larger than the current I_{SM}(I_{SP}−I_{SM}=x>0) in the circuit FC, the current I_{OP}=x flows through the wiring OLp as the result of the arithmetic operation of the identity function where I_{SP}−I_{SM}(=x) is substituted as a variable. Note that a current does not flow through the wiring OLm because I_{OM}=0. In the case where the current I_{SM} is larger than the current I_{SP}(I_{SP}−I_{SM}=x<0) in the circuit FC, the current I_{OM}=−x flows through the wiring OLm as a value obtained by multiplying −1 by the result of the arithmetic operation of the identity function where I_{SP}−I_{SM}(=x) is substituted as a variable. Note that a current does not flow through the wiring OLp because I_{OP}=0. In the case where I_{SP} and I_{SM} are equal to each other (x=0) in the circuit FC, a current does not flow through the wiring OLp or OLm because I_{OP}=0 and I_{OM}=0.

As described above, in the circuit FC, a current based on y=F_{P}(x)=I_{OP}=x can flow through the terminal T0p, and a current based on y=F_{M}(x)=−I_{OM}=x can flow through the terminal T0m. Thus, the circuit FC can perform the arithmetic operation of the identity function that outputs a value equal to x.

The circuit FC in FIG. 4 includes a circuit FCp and a circuit FCm, for example. The circuit FC includes the terminals T1p and T1m functioning as the input terminals and the terminals T0p and T0m functioning as the output terminals.

In the circuit FC, the circuit FCp includes the terminals T11 and T12 functioning as input terminals and the terminal T01 functioning as an output terminal. The circuit FCm includes terminals T13 and T14 functioning as input terminals and a terminal T02 functioning as an output terminal.

The circuit FCa illustrated in FIG. 1A can be used as each of the circuits FCp and FCm, for example. In this case, the terminals T11, T12, and T01 of the circuit FCp correspond to the terminals T11, T12, and T01 of the circuit FCa in FIG. 1A, and the terminals T13, T14, and T02 of the circuit FCm correspond to the terminals T11, T12, and T01 of the circuit FCa in FIG. 1A.

The terminal T1p of the circuit FC is connected to the terminal T11 of the circuit FCp and the terminal T14 of the circuit FCm, and the terminal T1m of the circuit FC is connected to the terminal T13 of the circuit FCm and the terminal T12 of the circuit FCp. The terminal T0p of the circuit FC is connected to the terminal T01 of the circuit FCp, and the terminal T0m of the circuit FC is connected to the terminal T02 of the circuit FCm.

In the circuit FC, the terminal T1p is connected to the wiring SUp, the terminal T1m is connected to the wiring SUm, the terminal T0p is connected to the wiring OLp, and the terminal T0m is connected to the wiring OLm.

The circuits FCp and FCm each have a function of a current source circuit and a sample-and-hold circuit as in the description of the circuit FCa in FIG. 1A.

For example, in the circuit FC in FIG. 4, the circuit FCp has a function of holding a potential corresponding to the current I_{SP} flowing through the terminal T11 and a function of generating a current equal to the current I_{SP} using the potential. Furthermore, the circuit FCp also has a function of making the current I_{OP} flow through the terminal T01 as a differential current between the current I_{SM} flowing through the terminal T12 and the generated current equal to the current I_{SP}. Note that in the circuit FCp, when I_{SP}−I_{SM}>0, I_{OP}=I_{SP}−I_{SM} and the current I_{OP} flows through the terminal T01, and when I_{SP}−I_{SM}≤0, I_{OP}=0 and a current does not flow through the terminal T01.

The circuit FCm has a function of holding a potential corresponding to the current I_{SM} flowing through the terminal T13 and a function of generating a current equal to the current I_{SM} using the potential, for example. Furthermore, the circuit FCm also has a function of making the current I_{OM} flow through the terminal T02 as a differential current between the current I_{SP} flowing through the terminal T14 and the generated current equal to the current I_{SM}. Note that in the circuit FCm, when I_{SM}−I_{SP}>0, I_{OM}=I_{SM}−I_{SP} and the current I_{OM} flows through the terminal T02, and when I_{SM}−I_{SP}≤0, I_{OM}=0 and a current does not flow through the terminal T02.

That is, when the circuit FCa in FIG. 1A is used as each of the circuits FCp and FCm in the circuit FC in FIG. 4, the circuit FC can perform the arithmetic operation of the identity function where the differential current between the currents I_{SP} and I_{SM} is substituted as a variable as shown in FIG. 5, and make the currents I_{OP} and I_{OM} flow through the terminals T01 and T02, respectively, as the arithmetic operation results.

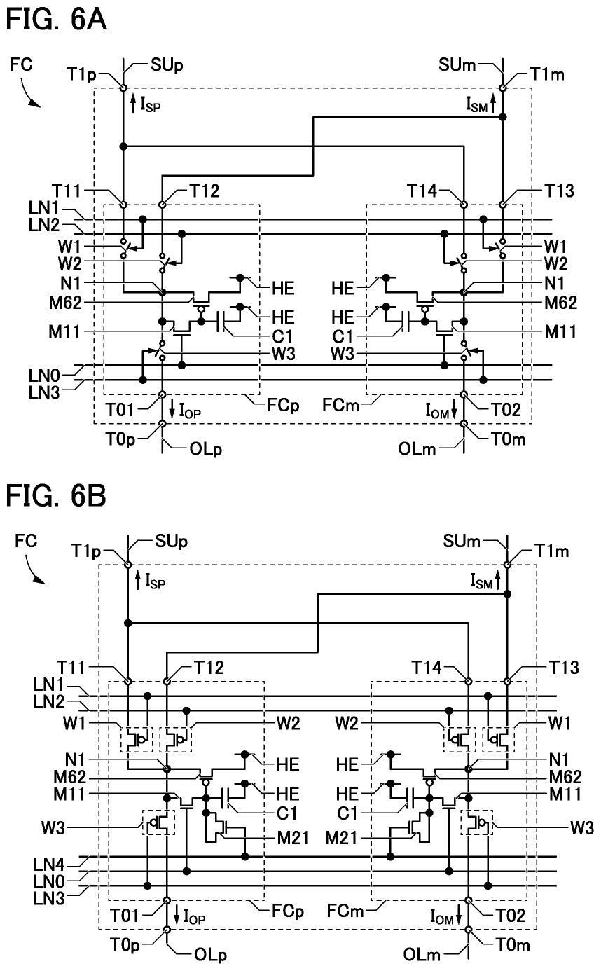

FIG. 6A is a circuit diagram illustrating a circuit structure of the circuit FC where the circuit FCa in FIG. 1A is used as each of the circuits FCp and FCm illustrated in FIG. 4. Thus, the description of the circuit FCa in FIG. 1A can be referred to for the circuit structures of the circuits FCp and FCm.

In FIG. 6A, the same wiring LN1 is connected to the control terminals of the switches W1 included in the circuits FCp and FCm. Similarly, the same wiring LN2 is connected to the control terminals of the switches W2 included in the circuits FCp and FCm, and the same wiring LN3 is connected to the control terminals of the switches W3 included in the circuits FCp and FCm. The same wiring LN0 is connected to the gates of the transistors M11 included in the circuits FCp and FCm. Thus, in the circuit FC in FIG. 6A, the circuits FCp and FCm can operate in synchronization with each other.

FIG. 6B is a circuit diagram in which transistors are used as electrical switches as the switches W1 to W3 illustrated in FIG. 6A, for example. In FIG. 6B, the transistors are p-channel transistors having the same polarity as the transistor M62. Note that the circuit FCp or FCm illustrated in FIG. 6B has a circuit structure partly changed from that in FIG. 3C. Specifically, the transistors used as the switches W1 to W3 and the transistor M12 are n-channel transistors in FIG. 3C, whereas the transistors used as the switches W1 to W3 and the transistor M62 are p-channel transistors in FIG. 6B.

When the transistors used as the switches W1 to W3 are p-channel transistors having the same polarity as the transistor M62, a decrease in the source-drain voltage of each of the transistors by the threshold voltage can be prevented. The same transistor as the transistor M62 can be used as each of the transistors. In each of the switches W1 to W3 in FIG. 6B, the first terminal corresponds to one of a source and a drain of the transistor, the second terminal corresponds to the other of the source and the drain of the transistor, and the control terminal corresponds to the gate of the transistor.

FIG. 6B also illustrates the transistor M21 having a function of a capacitor described with reference to FIG. 3A as an example. Specifically, FIG. 6B illustrates an example where the transistor M21 is included in each of the circuits FCp and FCm and the same wiring LN4 is connected to the gates of the transistors M21. When the same wiring is connected to the gates of the transistors M21 in the circuits FCp and FCm, the circuits FCp and FCm can operate in synchronization with each other in the circuit FC in FIG. 6B, as described above.

Next, an operation example of the circuit FC in FIG. 6A will be described. For the operation of the circuit FC in FIG. 6A, the operation in the timing chart in FIG. 1B can be referred to. The operation of the circuit FC in FIG. 6A will be described below with reference to the timing chart in FIG. 1B.

At Time TL1, a high-level potential is supplied to each of the wirings LN0 and LN1. Thus, the transistor M11 and the switch W1 are turned on in each of the circuits FCp and FCm. Accordingly, in the circuit FCp, the current I_{SP} flowing through the terminals T11 and T1p flows between the first and second terminals of the transistor M62, and the gate potential of the transistor M62 is determined in accordance with the current I_{SP}. Similarly, in the circuit FCm, the current I_{SM} flowing through the terminals T13 and T1m flows between the first and second terminals of the transistor M62, and the gate potential of the transistor M62 is determined in accordance with the current I_{SM}.

At Time TL2, a low-level potential is supplied to each of the wirings LN0 and LN1. Thus, the transistor M11 and the switch W1 are turned off in each of the circuits FCp and FCm. Accordingly, in the circuit FCp, the potential corresponding to the current I_{SP} is held in the gate of the transistor M62 by the capacitor C1, and in the circuit FCm, the potential corresponding to the current I_{SM} is held in the gate of the transistor M62 by the capacitor C1.

At Time TL3, a high-level potential is supplied to each of the wirings LN2 and LN3. Thus, the switches W2 and W3 are turned on. Accordingly, the current I_{SM} flows through the terminal T12 of the circuit FCp, and the current I_{OP} flows through the terminal T01 of the circuit FCp (the terminal T0p of the circuit FC) as a differential current obtained by subtracting the current I_{SM} from the current I_{SP}. Note that in the case where the current I_{SP} is smaller than or equal to the current I_{SM}, a current does not flow through the terminal T01 (the terminal T0p of the circuit FC) because I_{OP}=0. Similarly, the current I_{SP} flows through the terminal T14 of the circuit FCm, and the current I_{OM} flows through the terminal T02 of the circuit FCm (the terminal T0m of the circuit FC) as a differential current obtained by subtracting the current I_{SP} from the current I_{SM}. Note that in the case where the current I_{SM} is smaller than or equal to the current I_{SP}, a current does not flow through the terminal T02 (the terminal T0m of the circuit FC) because I_{OM}=0.

At Time TL4, a low-level potential is supplied to each of the wirings LN2 and LN3, so that the switches W2 and W3 are turned off in each of the circuits FCp and FCm. Thus, in the circuit FC, a current can stop flowing through each of the terminals T0p and T0m.

Thus, in the circuit FC in FIG. 6A, when I_{SP}>I_{SM}, I_{OP}=I_{SP}−I_{SM} flows through the terminal T0p as the differential current, and a current does not flow through the terminal T0m because I_{OM}=0. When I_{SP}<I_{SM}, I_{OM} I_{SM}−I_{SP} flows through the terminal T0m as the differential current, and a current does not flow through the terminal T0p because I_{OP}=0. When I_{SP}=I_{SM}, a current does not flow through the terminal T0p or T0m. That is, the circuit FC in FIG. 4 or FIG. 6A can perform the arithmetic operation of the identity function as shown in FIG. 5.

### Variation Example 2-1 of Semiconductor Device

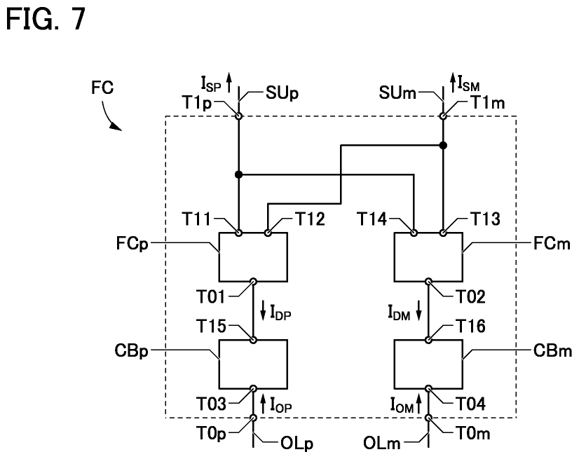

In the circuit FC illustrated in FIG. 4, the current I_{OP} flowing through the wiring OLp and the current I_{OM} flowing through the wiring OLm are discharge currents; however, the circuit structure may be changed such that the currents flowing through the wirings OLp and OLm are sink currents. Specifically, the structure of the circuit FC in FIG. 4 may be changed to that of the circuit FC illustrated in FIG. 7.

The circuit FC illustrated in FIG. 7 has a circuit structure where a current generation circuit CBp and a current generation circuit CBm are additionally provided in the circuit FC in FIG. 4. The current generation circuit CBp includes a terminal T15 functioning as an input terminal and a terminal T03 functioning as an output terminal. The current generation circuit CBm includes a terminal T16 functioning as an input terminal and a terminal T04 functioning as an output terminal.

In the circuit FC in FIG. 7, unlike in the circuit FC in FIG. 4, the terminal T01 of the circuit FCp is connected to the terminal T15 of the current generation circuit CBp instead of the terminal T0p, and the terminal T03 of the current generation circuit CBp is connected to the terminal T0p of the circuit FC. The terminal T02 of the circuit FCm is connected to the terminal T16 of the current generation circuit CBm instead of the wiring OLm, and the terminal T04 of the current generation circuit CBm is connected to the terminal T0m of the circuit FC.

In FIG. 7, a current flowing between the terminal T01 of the circuit FCp and the terminal T15 of the current generation circuit CBp is denoted by I_{DP}, and a current flowing between the terminal T02 of the circuit FCm and the terminal T16 of the current generation circuit CBm is denoted by I_{DM}. That is, the current I_{DP} flowing through the terminal T01 of the circuit FCp is I_{DP}=I_{SP}−I_{SM} when I_{SP}−I_{SM}>0, and I_{DP}=0 when I_{SP}−I_{SM}≤0. Similarly, the current I_{DM} flowing through the terminal T02 of the circuit FCm is I_{DM}=I_{SM}−I_{SP} when I_{SM}−I_{SP}>0, and I_{DM}=0 when I_{SM}−I_{SP}≤0.

The current generation circuits CBp and CBm in FIG. 7 each have a function of an n-type current mirror circuit with one input and one output. That is, the current generation circuit CBp has a function of generating the current I_{OP} flowing through the terminal T03 as a sink current with reference to the sink current (the current I_{DP}) flowing through the terminal T15, with its mirroring function. Similarly, the current generation circuit CBm has a function of generating the current I_{OM} flowing through the terminal T04 as a sink current with reference to the sink current (the current I_{DM}) flowing through the terminal T16, with its mirroring function. Thus, the circuit FC can make the currents I_{OP} and I_{OM} flow through the terminals T0p and T0m, respectively, as sink currents.

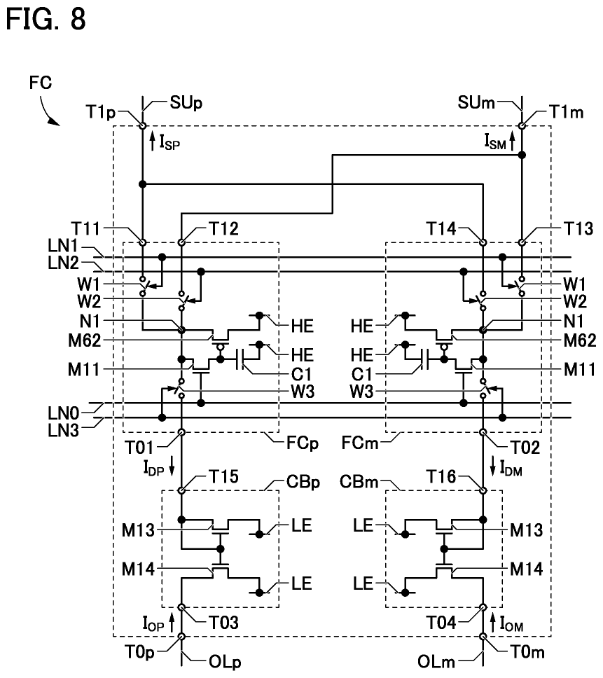

FIG. 8 is a circuit diagram illustrating a specific circuit structure of the circuit FC in FIG. 7.

In the circuit FC illustrated in FIG. 8, the circuits FCp and FCm employ the circuit structures of the circuits FCp and FCm illustrated in FIG. 6A. Thus, the description of the circuits FCp and FCm in FIG. 6A can be referred to for the circuits FCp and FCm included in the circuit FC in FIG. 8.

In FIG. 8, the current generation circuits CBp and CBm each include, for example, a transistor M13 and a transistor M14 that are n-channel transistors. As each of the transistors M13 and M14, a transistor that can be used as the transistor M11 can be used.

In each of the current generation circuits CBp and CBm, a first terminal of the transistor M13 is connected to the wiring LE, and a first terminal of the transistor M14 is connected to the wiring LE. A gate of the transistor M13 is connected to a second terminal of the transistor M13 and a gate of the transistor M14.

In the current generation circuit CBp, the second terminal of the transistor M13 is connected to the terminal T15, and a second terminal of the transistor M14 is connected to the terminal T03. In the current generation circuit CBm, the second terminal of the transistor M13 is connected to the terminal T16, and the second terminal of the transistor M14 is connected to the terminal T04.

Since the current generation circuits CBp and CBm each have a function of an n-type current mirror circuit, the transistors M13 and M14 preferably have the same structure. For example, the channel lengths of these transistors are preferably equal to each other. For example, the channel widths of these transistors are preferably equal to each other.

In the current generation circuit CBp in FIG. 8, the current I_{DP}, which is the sink current input to the terminal T15, flows to the wiring LE through a source and a drain of the transistor M13. At this time, the gate potential of the transistor M13 is determined in accordance with the current I_{DP} flowing through the terminal T15. Therefore, ideally, the gate-source voltage of the transistor M14 can be equal to that of the transistor M13, and the source-drain current of the transistor M14 can be equal to that of the transistor M13, which is the current I_{DP}. As a result, the circuit FC can make the current I_{OP} equal to the current I_{DP} flow through the terminal T0p as a sink current.

Similarly, in the current generation circuit CBm in FIG. 8, the current I_{DM}, which is the sink current input to the terminal T16, flows to the wiring LE through the source and the drain of the transistor M13. Accordingly, the gate potential of the transistor M13 is determined in accordance with the current I_{DM}, and the source-drain current of the transistor M14, which is also the current I_{OM} flowing through the terminal T04, can ideally be equal to that of the transistor M13, which is the current I_{DM}. As a result, the circuit FC can make the current I_{OM} equal to the current I_{DM} flow through the terminal T0m as a sink current.

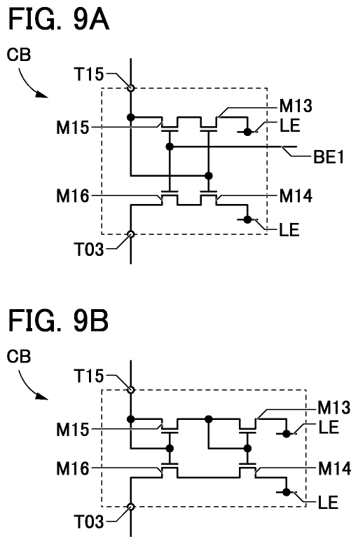

The circuit structures of the current generation circuits CBp and CBm in FIG. 7 of the semiconductor device of one embodiment of the present invention are not limited to those of the current generation circuits CBp and CBm in FIG. 8. For example, the current generation circuits CBp and CBm in FIG. 7 may employ the circuit structure of a current generation circuit CB illustrated in FIG. 9A.

The current generation circuit CB in FIG. 9A is a variation example of the current generation circuits CBp and CBm illustrated in FIG. 8, and is different therefrom in including a transistor M15 and a transistor M16 that are n-channel transistors.

Since the current generation circuit CB in FIG. 9A has a function of an n-type current mirror circuit, the transistors M15 and M16 preferably have the same structure. For example, the channel lengths of these transistors are preferably equal to each other. For example, the channel widths of these transistors are preferably equal to each other.

The terminals T15 and T03 illustrated in FIG. 9A correspond respectively to the terminals T15 and T03 in the current generation circuit CBp in FIG. 7. The terminals T15 and T03 illustrated in FIG. 9A correspond respectively to the terminals T16 and T04 in the current generation circuit CBm in FIG. 7.

In FIG. 9A, the second terminal of the transistor M13 is connected to a first terminal of the transistor M15 instead of the terminal T15. A second terminal of the transistor M15 is connected to the gate of the transistor M13, the gate of the transistor M14, and the terminal T15. A second terminal of the transistor M14 is connected to a first terminal of the transistor M16 instead of the terminal T03. A second terminal of the transistor M16 is connected to the terminal T03. A gate of the transistor M15 and a gate of the transistor M16 are connected to a wiring BE1.

That is, the transistor M15 is cascode-connected to the transistor M13, and the transistor M16 is cascode-connected to the transistor M14. Thus, the transistor M15 has a function of a clamp transistor for the transistor M13, and the transistor M16 has a function of a clamp transistor for the transistor M14. Thus, a predetermined bias potential is supplied to the gates of the transistors M15 and M16 from the wiring BE1.

Accordingly, the wiring BE1 functions as a wiring for supplying a bias potential. Specifically, the bias potential is preferably a potential at which the transistors M15 and M16 operate in a saturation region.

Thus, the potential of the terminal T15 can be prevented from being directly input to the second terminal of the transistor M13. In other words, a sudden change in the potential of the second terminal of the transistor M13 can be prevented, and a decrease in the threshold voltage of the transistor M13 due to drain-induced barrier lowering (DIBL) can also be prevented. This can prevent a change in the source-drain current of the transistor M13 in the current generation circuit CB, so that the accuracy of the arithmetic operation of a function performed in the circuit FC can be increased. Note that the same applies to the transistor M14.

Alternatively, the current generation circuits CBp and CBm in FIG. 7 may employ the circuit structure of the current generation circuit CB illustrated in FIG. 9B, for example.

The current generation circuit CB in FIG. 9B is a variation example of the current generation circuit CB in FIG. 9A. The current generation circuit CB in FIG. 9B includes the transistors M15 and M16 as the clamp transistors for the transistors M13 and M14 like the current generation circuit CB in FIG. 9A, but is different therefrom in the connection portions of the gates of the transistors M13 to M16.

In the current generation circuit CB in FIG. 9B, the gates of the transistors M13 and M14 are connected to the second terminal of the transistor M13 and the first terminal of the transistor M15 instead of the second terminal of the transistor M15 and the terminal T15. The gates of the transistors M15 and M16 are connected to the second terminal of the transistor M15 and the terminal T15.

In the current generation circuit CB in FIG. 9B, a decrease in the threshold voltage of the transistors M13 and M14 due to DIBL can be prevented.

### Variation Example 2-2 of Semiconductor Device

Although the current generation circuit CBm in FIG. 7 is described as a circuit having a function of an n-type current mirror circuit, the semiconductor device of one embodiment of the present invention is not limited thereto. The current generation circuit CBm may have a function of, for example, a current amplifier that amplifies a current flowing through the terminal T16 by a factor of k (here, k is a real number greater than 0 and less than 1) and makes the amplified current flow through terminal T04. In this case, the current I_{OM} flowing through the terminal T04 of the current generation circuit CBm is k times the current I_{DM} flowing through the terminal T16, and thus can be expressed as I_{OM}=kI_{DM}.

When the current generation circuit CBm has a function of a current amplifier, the circuit FC in FIG. 7 can perform an arithmetic operation of a Leaky ReLU function.

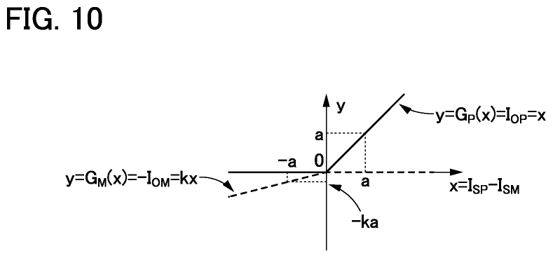

FIG. 10 is a graph where x(=I_{SP}−I_{SM}) represents the differential current between the current I_{SP} flowing through the terminal T1p and the current I_{SM} flowing through the terminal T1m and y represents the current I_{OP} flowing through the terminal T0p and a value obtained by multiplying −1 by I_{OM} flowing through the terminal T0m, in the circuit FC including the current generation circuit CBm having a function of a current amplifier in FIG. 7. Specifically, in FIG. 10, y=G_{P}(x)=I_{OP}=x is indicated by a thick solid line, and y=G_{M}(x)=−I_{OM}=x is indicated by a thick dashed line. Note that a shown in FIG. 10 is a given current amount that is greater than 0 [A] and within the possible range of I_{SP}−I_{SM}, for example.

As shown in FIG. 10, in the case where the current I_{SP} is larger than the current I_{SM}(I_{SP}−I_{SM}=x>0) in the circuit FC, the current I_{OP}=x flows through the wiring OLp as the result of the arithmetic operation of the identity function where I_{SP}−I_{SM}(=x) is substituted as a variable. Note that a current does not flow through the wiring OLm because I_{OM}=0. In the case where the current I_{SM} is larger than the current I_{SP}(I_{SP}−I_{SM}=x<0) in the circuit FC, the current I_{OM}=−kx flows through the wiring OLm as a value obtained by multiplying −1 by the result of the arithmetic operation of the identity function where I_{SP}−I_{SM}(=x) is substituted as a variable. Note that a current does not flow through the wiring OLp because I_{OP}=0. In the case where I_{SP} and I_{SM} are equal to each other (x=0) in the circuit FC, a current does not flow through the wiring OLp or OLm because I_{OP}=0 and I_{OM}=0.

As described above, when the current generation circuit CBm has a function of a current amplifier, in the circuit FC in FIG. 7, a current based on y=G_{P}(x)=I_{OP}=x can flow through the terminal T0p, and a current based ony=G_{M}(x)=−I_{OM}=kX can flow through the terminal T0m. Thus, the circuit FC can perform the arithmetic operation of the Leaky ReLU function.

Even in the case where the current generation circuit CBm has a function of a current amplifier in the circuit FC in FIG. 7, the circuit FC can employ the circuit structure of the circuit FC illustrated in FIG. 8. Note that the current I_{OM} flowing through the terminal T04 of the current generation circuit CBm is k times the current I_{DM} flowing through the terminal T16; thus, the sizes and structures of the transistors M13 and M14 are preferably determined such that the source-drain current of the transistor M14 to be the current I_{OM} is k times that of the transistor M13 to be the current I_{DM}. Specifically, for example, the current generation circuit CBm is preferably designed such that the channel lengths of the transistors M13 and M14 are equal to each other and the channel width of the transistor M14 is k times that of the transistor M13.

### Structure Example 3 of Semiconductor Device

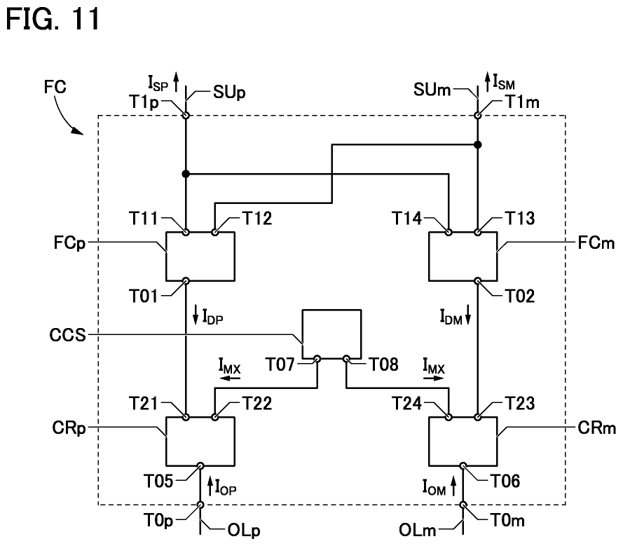

FIG. 11 is a block diagram illustrating a structure example of a circuit that is the semiconductor device of one embodiment of the present invention and can perform an arithmetic operation of a function, which is different from that in FIG. 1A. In particular, the circuit can perform an arithmetic operation of a Hard Tanh function used as an activation function of an artificial neural network.

Like the circuit FC in FIG. 4, the circuit FC in FIG. 11 is connected to the wirings SUp, SUm, OLp, and OLm. Like the circuit FC in FIG. 4, the circuit FC in FIG. 11 has a function of obtaining the current I_{SP} flowing through the wiring SUp and the current I_{SM} flowing through the wiring SUm and generating the currents I_{DP} and I_{DM} as the differential currents between the currents I_{SP} and I_{SM}. Note that the current I_{DP} is I_{DP}=I_{SP}−I_{SM} when I_{SP}>I_{SM} and I_{DP}=0 [A] when I_{SP}≤I_{SM}, and the current I_{DM} is I_{DM}=I_{SM}−I_{SP} when I_{SM}>I_{SP} and I_{DM}=0 [A] when I_{SM}≤I_{SP}. The circuit FC in FIG. 11 has a function of substituting the currents I_{DP} and I_{DM} as variables of the Hard Tanh function and making the currents I_{OP} and I_{OM} flow through the wirings OLp and OLm as the results of the arithmetic operations of the Hard Tanh function.

Specifically, in the case where the current I_{SP} is larger than the current I_{SM} in the circuit FC, the current I_{OP} corresponding to the result of the arithmetic operation of the Hard Tanh function where I_{DP}(>0) is substituted as a variable can flow through the wiring OLp, and a current does not flow through the wiring OLm because I_{DM}=0. In the case where the current I_{SM} is larger than the current I_{SP} in the circuit FC, the current I_{OM} corresponding to the result of the arithmetic operation of the Hard Tanh function where I_{DM}(>0) is substituted as a variable can flow through the wiring OLm, and a current does not flow through the wiring OLp because I_{DP}=0. In the case where I_{SM} and I_{SP} are equal to each other in the circuit FC, a current does not flow through the wiring OLp or OLm.

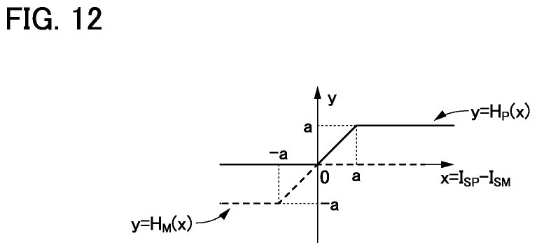

FIG. 12 is a graph where x(=I_{SP}−I_{SM}) represents the differential current between the current I_{SP} flowing through the wiring SUp and the current I_{SM} flowing through the wiring SUm and y represents the current I_{OP} flowing through the wiring OLp and a value obtained by multiplying −1 by I_{OM} flowing through the wiring OLm, in the circuit FC in FIG. 11. Specifically, FIG. 12 shows a function H_{P}(x) indicated by a thick solid line: y=H_{P}(x)=0 when x is less than or equal to 0 [A]; y=H_{P}(x)=I_{OP}=x (identity function) when x is greater than 0 [A] and less than a; and y=H_{P}(x)=a when x is greater than or equal to a. FIG. 12 also shows a function H_{M}(x) indicated by a solid dashed line: y=H_{M}(X)=−a when x is less than or equal to −a; y=H_{M}(x)=−I_{OM}=x (identity function) when x is greater than −a and less than 0 [A], and y=H_{M}(X)=0 when x is greater 0 [A]. Note that a shown in FIG. 12 is a given current amount that is greater than 0 [A] and within the possible range of I_{MX} described later.

As shown in FIG. 12, in the case where the current I_{SP} is larger than the current I_{SM} and smaller than the current I_{MX}(0<x<a) in the circuit FC, the current I_{OP}=x flows through the wiring OLp as the result of the arithmetic operation of the identity function where the current I_{DP}(>0) is substituted as a variable, and a current does not flow through the wiring OLm because I_{OM}=0. In the case where I_{SP} is larger than or equal to I_{MX}(x≥a) in the circuit FC, the current I_{OP}=I_{MX}=a flows through the wiring OLp, and a current does not flow through the wiring OLm because I_{OM}=0.

As shown in FIG. 12, in the case where the current I_{SM} is larger than the current I_{SP} and smaller than the current I_{MX}(−a<−x<0) in the circuit FC, the current I_{OM}=−x flows through the wiring OLm as a value obtained by multiplying −1 by the result of the arithmetic operation of the identity function where the current I_{DM}(>0) is substituted as a variable, and a current does not flow through the wiring OLp because I_{OP}=0. In the case where I_{SM} is larger than or equal to I_{MX}(x≥a) in the circuit FC, the current I_{OM}=I_{MX}=a flows through the wiring OLm, and a current does not flow through the wiring OLp because I_{OP}=0.

As shown in FIG. 12, in the case where the currents I_{SP} and I_{SM} are equal to each other (x=0) in the circuit FC, a current does not flow through the wiring OLp or OLm because I_{OP}=0 and I_{OM}=0.

As described above, in the circuit FC, a current based on y=H_{P}(x) can flow through the terminal T0p, and a current based on y=H_{M}(X) can flow through the terminal T0m. Thus, the circuit FC can perform the arithmetic operation of the Hard Tanh function. The value of a(=I_{MX}) can be determined freely.

The circuit FC illustrated in FIG. 11 has a circuit structure where a current generation circuit CRp, a current generation circuit CRm, and a current supply circuit CCS are additionally provided in the circuit FC in FIG. 4. The current generation circuit CRp includes terminals T21 and T22 functioning as input terminals and a terminal T05 functioning as an output terminal. The current generation circuit CRm includes terminals T23 and T24 functioning as input terminals and a terminal T06 functioning as an output terminal. The current supply circuit CCS includes terminals T07 and T08 functioning as output terminals.

In the circuit FC in FIG. 11, unlike in the circuit FC in FIG. 4, the terminal T01 of the circuit FCp is connected to the terminal T21 of the current generation circuit CRp instead of the terminal T0p, the terminal T22 of the current generation circuit CRp is connected to the terminal T07 of the current supply circuit CCS, and the terminal T05 of the current generation circuit CRp is connected to the terminal T0p of the circuit FC. The terminal T02 of the circuit FCm is connected to the terminal T23 of the current generation circuit CRm instead of the terminal T0m, the terminal T24 of the current generation circuit CRm is connected to the terminal T08 of the current supply circuit CCS, and the terminal T06 of the current generation circuit CRm is connected to the terminal T0m of the circuit FC.

In FIG. 11, a current flowing between the terminal T01 of the circuit FCp and the terminal T21 of the current generation circuit CRp is denoted by I_{DP}, and a current flowing between the terminal T02 of the circuit FCm and the terminal T23 of the current generation circuit CRm is denoted by I_{DM}. That is, as described above, the current I_{DP} flowing through the terminal T01 of the circuit FCp is I_{DP}=I_{SP}−I_{SM} when I_{SP}−I_{SM}>0, and I_{DP}=0 when I_{SP}−I_{SM}≥0. Similarly, the current I_{DM} flowing through the terminal T02 of the circuit FCm is I_{DM}=I_{SM}−I_{SP} when I_{SM}−I_{SP}>0, and I_{DM}=0 when I_{SM}−I_{SP}≤0.

The current supply circuit CCS has a function of, for example, generating the current I_{MX} and making it flow through the terminals T07 and T08 in response to a power supply potential input to an input terminal (not illustrated). Note that the current I_{MX} is a discharge current for the current supply circuit CCS in FIG. 11. In this case, the current I_{MX} is a sink current for the current generation circuits CRp and CRm described later. It is preferable that the current supply circuit CCS can determine the amount of the current I_{MX} freely.

The current generation circuit CRp has a function of, for example, generating a current flowing through the terminal T05 with reference to the smaller of the current I_{DP} flowing through the terminal T21 and the current I_{MX} flowing through the terminal T22, with its mirroring function. That is, the current generation circuit CRp has a function of a 2-input minimum pooling circuit that can select the smaller of currents flowing through its two input terminals and make a current in the same amount as the selected current flow through its output terminal. Note that in FIG. 11, a current flowing through the terminal T05 of the current generation circuit CRp is denoted by I_{OP}, and the current I_{OP} is a sink current for the current generation circuit CRp. Thus, the current generation circuit CRp, which is an n-type 2-input minimum pooling circuit, generates the current I_{OP} as a sink current and makes it flow between the terminal T05 and the wiring OLp.

Like the current generation circuit CRp, the current generation circuit CRm has a function of, for example, a 2-input minimum pooling circuit that can select the smaller of currents flowing through its two input terminals and make a current in the same amount as the selected current flow through its output terminal. That is, the current generation circuit CRm has a function of generating a current flowing through the terminal T06 with reference to the smaller of the current I_{DM} flowing through the terminal T23 and the current I_{MX} flowing through the terminal T24, with its mirroring function. Note that in FIG. 11, a current flowing through the terminal T06 of the current generation circuit CRm is denoted by I_{OM}, and the current I_{OM} is a sink current for the current generation circuit CRm. Thus, the current generation circuit CRm, which is an n-type 2-input minimum pooling circuit, generates the current I_{OM} as a sink current and makes it flow between the terminal T06 and the wiring OLm.

Since a sink current flows through each of the terminals T21, T22, and T05 of the current generation circuit CRp and the terminals T23, T24, and T06 of the current generation circuit CRm, it can be said that the current generation circuits CRp and CRm each have a function of a current sink circuit.

In the above manner, the circuit FC in FIG. 11 can obtain the differential current between the current I_{SP} flowing through the wiring SUp and the current I_{SM} flowing through the wiring SUm, and make currents flow through the wirings OLp and OLm as shown in the following table.

TABLE 1

| Differential | Differential | Output | Output |
|---|---|---|---|
| current I_{DP} | current I_{DM} | current I_{OP} | current I_{OM} |
| I_{SP} − I_{SM} | 0 | I_{MX} | 0 |
| (I_{DP} ≥ I_{MX}) | | | |
| I_{SP} − I_{SM} | 0 | I_{DP} | 0 |
| (0 < I_{DP} < I_{MX}) | | | |
| I_{SP} − I_{SM} = 0 | I_{SM} − I_{SP} = 0 | 0 | 0 |
| (I_{DP} = 0) | (I_{DM} = 0) | | |
| 0 | I_{SM} − I_{SP} | 0 | I_{DM} |
| | (0 < I_{DM} < I_{MX}) | | |
| 0 | I_{SM} − I_{SP} | 0 | I_{MX} |
| | (I_{DM} ≥ I_{MX}) | | |

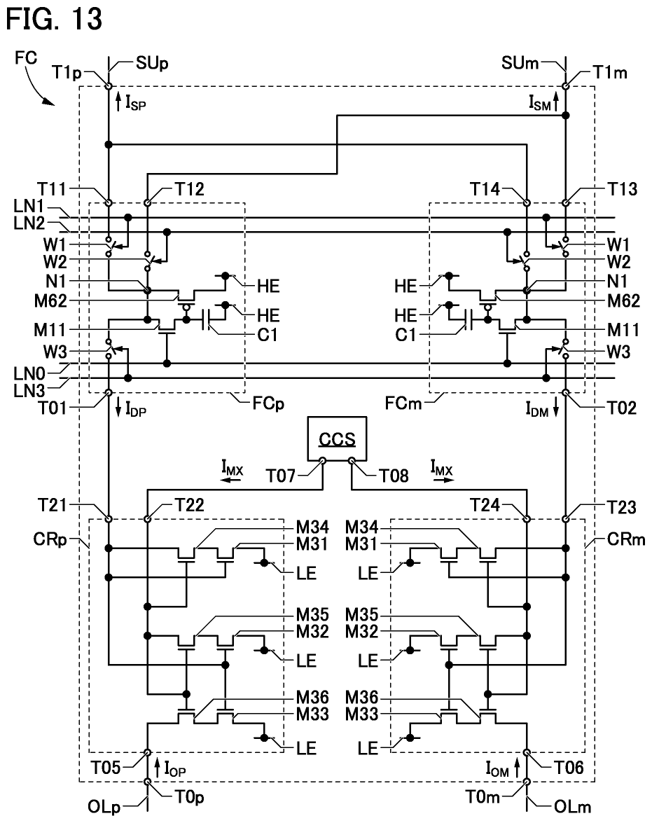

Next, a specific circuit structure example of the circuit FC illustrated in FIG. 11 is described. Here, description is made with reference to FIG. 13, which is a circuit diagram illustrating a specific circuit structure example of the circuit FC in FIG. 11.

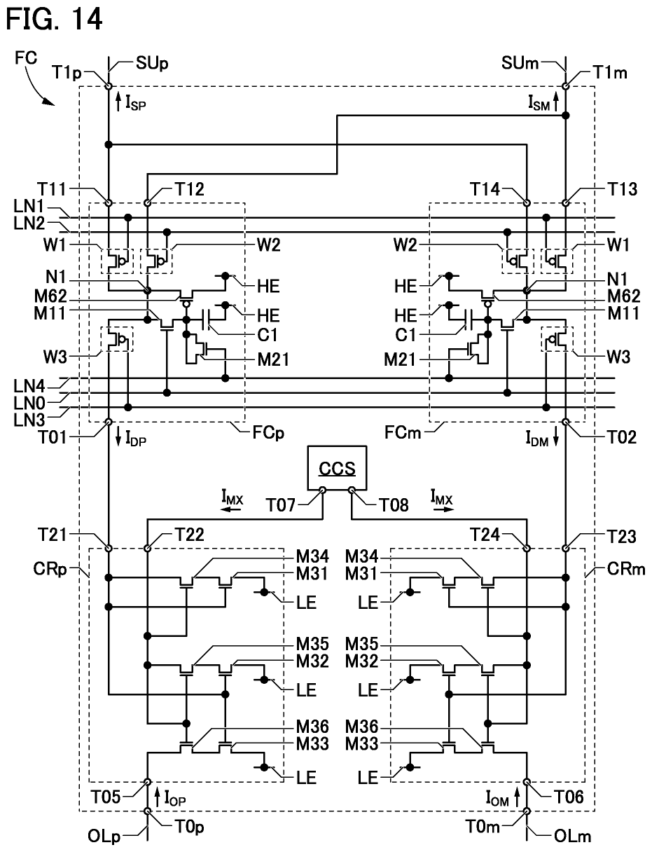

In the circuit FC illustrated in FIG. 13, the circuits FCp and FCm employ the circuit structures of the circuits FCp and FCm illustrated in FIG. 6A. Thus, the description of the circuits FCp and FCm in FIG. 6A can be referred to for the circuits FCp and FCm included in the circuit FC in FIG. 13. Alternatively, in the circuit FC illustrated in FIG. 13, the circuits FCp and FCm illustrated in FIG. 6B may be used instead (see FIG. 14).

In FIG. 13, the current generation circuits CRp and CRm each include, for example, a transistor M31 to a transistor M36 that are n-channel transistors. As each of the transistors M31 to M36, a transistor that can be used as the transistor M11 can be used.

Note that the transistors M31 to M33 preferably have the same structure. For example, the channel lengths of these transistors are preferably equal to each other. For example, the channel widths of these transistors are preferably equal to each other.

Similarly, the transistors M34 to M36 preferably have the same structure. For example, the channel lengths of these transistors are preferably equal to each other. For example, the channel widths of these transistors are preferably equal to each other.

Furthermore, the transistors M31 to M36 preferably have the same structure, equal channel length, and equal channel width.

In the case of the circuit FC in FIG. 14, specifically, in the case where the transistors used as the switches W1 to W3 and the transistor M62 included in the circuits FCp and FCm are p-channel transistors, the transistors M31 to M36 in the current generation circuits CRp and CRm are preferably n-channel transistors having the opposite polarity to the transistor M62. In that case, since the circuit FCp in FIG. 14 makes a discharge current flow through the terminal T01, the current generation circuit CRp in FIG. 14 preferably uses n-channel transistors as the transistors M31 to M36 to obtain a current flowing from the terminal T01 as a sink current through the terminal T21. Similarly, since the circuit FCm in FIG. 14 makes a discharge current flow through the terminal T02, the current generation circuit CRm in FIG. 14 preferably uses n-channel transistors as the transistors M31 to M36 to obtain a current flowing from the terminal T02 as a sink current through the terminal T23.

As each of the n-channel transistors included in the current generation circuits CRp and CRm, an OS transistor can be used, for example. As the OS transistor, it is particularly preferable to use an IO transistor having both a low off-state current and a high on-state current. When an IO transistor is used as each of the transistors M31 to M36, a malfunction due to an off-state current can be prevented, and a high operation speed owing to a high on-state current can be achieved.

For the effects of using IO transistors as the n-channel transistors included in the current generation circuits CRp and CRm, the above description of the effect of using an IO transistor as the transistor M11 in the circuit FCa in FIG. 1A can be referred to.

As each of the transistors M31 to M36, a Si transistor may be used instead of an OS transistor. In the case where the current generation circuit CRp, the current generation circuit CRm, and the current supply circuit CCS each include a Si transistor, using a Si transistor as each of the transistors M31 to M36 allows the current generation circuit CRp, the current generation circuit CRm, and the current supply circuit CCS to be manufactured through the same process. Thus, the time required for manufacturing the circuit FC can be shortened.

In the current generation circuits CRp and CRm, a first terminal of the transistor M31, a first terminal of the transistor M32, and a first terminal of the transistor M33 are each connected to the wiring LE. A second terminal of the transistor M31 is connected to a first terminal of the transistor M34, a second terminal of the transistor M32 is connected to a first terminal of the transistor M35, and a second terminal of the transistor M33 is connected to a first terminal of the transistor M36.

Note that the first terminals of the transistors M31, M32, and M33 may be connected to different wirings; in that case, the same potential is preferably supplied to the wirings.

In the current generation circuit CRp, a second terminal of the transistor M34, a gate of the transistor M31, a gate of the transistor M32, and a gate of the transistor M33 are connected to the terminal T21. A second terminal of the transistor M35, a gate of the transistor M34, a gate of the transistor M35, and agate of the transistor M36 are connected to the terminal T22. A second terminal of the transistor M36 is connected to the terminal T05.

In the current generation circuit CRm, the second terminal of the transistor M34, the gate of the transistor M31, the gate of the transistor M32, and the gate of the transistor M33 are connected to the terminal T23. The second terminal of the transistor M35, the gate of the transistor M34, the gate of the transistor M35, and the gate of the transistor M36 are connected to the terminal T24. The second terminal of the transistor M36 is connected to the terminal T06.

Like the wiring LE illustrated in FIG. 3B, the wiring LE can be a wiring for supplying a fixed potential. Since the current generation circuits CRp and CRm each have a function of a current sink circuit in FIG. 13, a fixed potential supplied from the wiring LE is preferably a low-level potential at which the first terminals of the transistors M31 to M33 serve as the sources.

In the current generation circuit CRp, the current I_{DP}, which is the sink current flowing through the terminal T21, flows to the wiring LE through the sources and the drains of the transistors M34 and M31. At this time, the gate potentials of the transistors M31 to M33 are determined in accordance with the current I_{DP} flowing through the terminal T21. Thus, the gate-source voltage of each of the transistors M32 and M33 is ideally equal to that of the transistor M31, and accordingly the current I_{DP} can flow between the source and the drain of the transistor M32 and between the source and the drain of the transistor M33.

In the current generation circuit CRp, the current I_{MX}, which is the sink current flowing through the terminal T22, flows to the wiring LE through the sources and the drains of the transistors M35 and M32. At this time, the gate potentials of the transistors M34 to M36 are determined in accordance with the current I_{MX} flowing through the terminal T22. Thus, the gate-source voltage of each of the transistors M34 and M36 is ideally equal to that of the transistor M35, and accordingly the current I_{MX} can flow between the source and the drain of the transistor M34 and between the source and the drain of the transistor M36.

Accordingly, the source-drain current of the transistor M33 can be I_{DP}, and the source-drain current of the transistor M36 can be I_{MX}. Since the transistors M33 and M36 are connected in series, the upper limit of a current flowing between the terminal T05 and the wiring LE is the smaller of the currents I_{DP} and I_{MX}. Thus, in the case where the current I_{DP} is smaller than the current I_{MX}, the current I_{OP} equal to the current I_{DP} flows through the terminal T05 as a sink current, and in the case where the current I_{MX} is smaller than the current I_{DP}, the current I_{OP} equal to the current I_{MX} flows through the terminal T05 as a sink current.

Thus, the current generation circuit CRp can select the smaller of the currents flowing through the terminals T21 and T22, and make a current in the same amount as the selected current flow through the terminal T05. In addition, the current I_{OP} flows through the terminal T05 as a sink current.

In the current generation circuit CRm, as in the above-described current generation circuit CRp, the source-drain current of the transistor M33 can be equal to the current I_{DM} flowing through the terminal T23, and the source-drain current of the transistor M36 can be equal to the current I_{MX} flowing through the terminal T24. Since the transistors M33 and M36 are connected in series, the upper limit of a current flowing between the terminal T06 and the wiring LE is the smaller of the currents I_{DP} and I_{MX}. Thus, in the case where the current I_{DM} is smaller than the current I_{MX}, the current I_{OM} equal to the current I_{DM} flows through the terminal T06 as a sink current, and in the case where the current I_{MX} is smaller than the current I_{DM}, the current I_{OM} equal to the current I_{MX} flows through the terminal T06 as a sink current.

Note that in the case where the upper limit of the current I_{MX} is larger than the current I_{DP} in the current generation circuit CRp, the current generation circuit CRp can be regarded substantially as a current mirror circuit that generates the current I_{OP} flowing through the terminal T05 with reference to the current I_{DP} flowing through the terminal T21, with its mirroring function. In this case, the circuit FC makes the current I_{OP} flow through the terminal T0p as the differential current between the current I_{SP} flowing through the wiring SUp and the current I_{SM} flowing through the wiring SUm. At this time, the circuit FC can be regarded substantially as a circuit that performs an arithmetic operation of a ReLU function. In other words, setting the current I_{MX} in the current generation circuit CRp allows selection between a Hard Tanh function and a ReLU function used in an arithmetic operation of an activation function performed in the circuit FC. Thus, the circuit FC can perform an arithmetic operation using a Hard Tanh function or a ReLU function as the activation function. Since the circuit FC can perform two kinds of arithmetic operations of a Hard Tanh function and a ReLU function, the area of the circuit FC can be smaller than that of the case where the circuits for the two kinds of functions are provided.

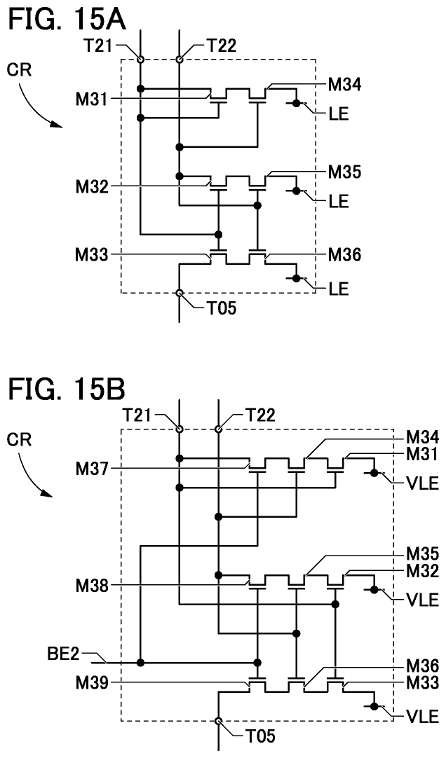

The circuit structures of the current generation circuits CRp and CRm illustrated in FIG. 11 of the semiconductor device of one embodiment of the present invention are not limited to those of the current generation circuits CRp and CRm illustrated in FIG. 13. For example, the current generation circuits CRp and CRm in FIG. 11 may employ the circuit structure of a current generation circuit CR illustrated in FIG. 15A.

The current generation circuit CR in FIG. 15A includes the terminal T21 corresponding to the terminal T21 of the current generation circuit CRp or the terminal T23 of the current generation circuit CRm in FIG. 13, the terminal T22 corresponding to the terminal T22 of the current generation circuit CRp or the terminal T24 of the current generation circuit CRm in FIG. 13, and the terminal T05 corresponding to the terminal T05 of the current generation circuit CRp or the terminal T06 of the current generation circuit CRm in FIG. 13.

The current generation circuit CR in FIG. 15A is a variation example of the current generation circuits CRp and CRm illustrated in FIG. 13, and is different therefrom in the connection order of the transistors M31 and M34 between the wiring LE and the terminal T21, the connection order of the transistors M32 and M35 between the wiring LE and the terminal T22, and the connection order of the transistors M33 and M36 between the wiring LE and the terminal T05.

Specifically, in the current generation circuit CR in FIG. 15A, the first terminal of the transistor M34 is connected to the wiring LE, the second terminal of the transistor M34 is connected to the first terminal of the transistor M31, and the second terminal of the transistor M31 is connected to the terminal T21. The first terminal of the transistor M35 is connected to the wiring LE, the second terminal of the transistor M35 is connected to the first terminal of the transistor M32, and the second terminal of the transistor M32 is connected to the terminal T22. The first terminal of the transistor M36 is connected to the wiring LE, the second terminal of the transistor M36 is connected to the first terminal of the transistor M33, and the second terminal of the transistor M33 is connected to the terminal T05.

Note that in the current generation circuit CR in FIG. 15A, the connection destinations of the gates of the transistors M31 to M36 are not changed from those in the current generation circuits CRp and CRm in FIG. 13.

Even when the connection orders of the transistors M31 and M34, the transistors M32 and M35, and the transistors M33 and M36 are changed from those in the current generation circuits CRp and CRm in FIG. 13 as illustrated in FIG. 15A, the current generation circuit CR in FIG. 15A can have a function of an n-type 2-input minimum pooling circuit like the current generation circuits CRp and CRm in FIG. 13.

Alternatively, for example, the current generation circuits CRp and CRm in FIG. 11 may employ the circuit structure of the current generation circuit CR illustrated in FIG. 15B.

The current generation circuit CR in FIG. 15B is a variation example of the current generation circuits CRp and CRm illustrated in FIG. 13, and is different therefrom in including a transistor M37 to a transistor M39 that are n-channel transistors.

As each of the transistors M37 to M39, a transistor that can be used as any of the transistors M31 to M36 described above can be used, for example.

In FIG. 15B, the terminal T21 is connected to a first terminal of the transistor M37 instead of the second terminal of the transistor M34. The second terminal of the transistor M34 is connected to a second terminal of the transistor M37. The terminal T22 is connected to a first terminal of the transistor M38 instead of the second terminal of the transistor M35. The second terminal of the transistor M35 is connected to a second terminal of the transistor M38. The terminal T05 is connected to a first terminal of the transistor M39 instead of the second terminal of the transistor M36. The second terminal of the transistor M36 is connected to a second terminal of the transistor M39. Gates of the transistors M37 to M39 are connected to a wiring BE2.

The wiring BE2 functions as a wiring for supplying a bias potential to the gates of the transistors M37 to M39. Specifically, the bias potential is preferably a potential at which the transistors M37 to M39 operate in a saturation region.

The transistors M37 to M39 in FIG. 15B each have a function of a clamp transistor like the transistors M15 and M16 in FIG. 9A. Thus, as the clamp transistor for the transistor M34, the transistor M37 can prevent a decrease in the threshold voltage of the transistor M34 due to DIBL. Similarly, as the clamp transistor for the transistor M35, the transistor M38 can prevent a decrease in the threshold voltage of the transistor M35 due to DIBL, and as the clamp transistor for the transistor M36, the transistor M39 can prevent a decrease in the threshold voltage of the transistor M36 due to DIBL. This accordingly can prevent changes in the source-drain currents of the transistors M34 to M36 in the current generation circuit CR, thereby increasing the accuracy of the arithmetic operation of the function performed in the circuit FC.

As the each of circuits FCp and FCm illustrated in FIG. 13 of the semiconductor device of one embodiment of the present invention, the circuit FCa illustrated in FIG. 3C may be used. That is, the transistors used as the switches W1 to W3 may be n-channel transistors, and the transistor M62 that is a p-channel transistor may be changed to the transistor M12 that is an n-channel transistor. At this time, the transistors M31 to M36 in the current generation circuits CRp and CRm are preferably p-channel transistors having the opposite polarity to the transistor M12. In that case, since the circuit FCp makes a sink current flow through the terminal T01, the current generation circuit CRp preferably uses p-channel transistors as the transistors M31 to M36 to obtain a current flowing from the terminal T01 as a discharge current through the terminal T21. Similarly, since the circuit FCm makes a sink current flow through the terminal T02, the current generation circuit CRm preferably uses p-channel transistors as the transistors M31 to M36 to obtain a current flowing from the terminal T02 as a discharge current through the terminal T23.

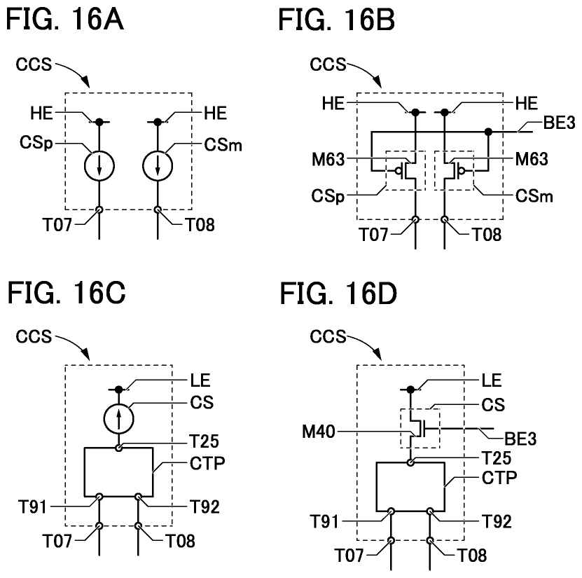

As the current supply circuit CCS illustrated in FIGS. 11 and 13, the current supply circuit CCS illustrated in FIG. 16A can be used, for example.

The current supply circuit CCS in FIG. 16A includes a current source CSp and a current source CSm, for example. An input terminal of the current source CSp is connected to the wiring HE, and an output terminal of the current source CSp is connected to the terminal T07. An input terminal of the current source CSm is connected to the wiring HE, and an output terminal of the current source CSm is connected to the terminal T08.

The current sources CSp and CSm each have a function of, for example, generating the current I_{MX} and making it flow through the output terminal in response to a fixed potential (here, a high power supply potential) input to the input terminal from the wiring HE. Note that the current sources CSp and CSm are discharge current sources, and the currents I_{MX} supplied from the current sources CSp and CSm serve as sink currents for the current generation circuits CRp and CRm. It is preferable that the current source CSp can determine the current I_{MX} freely.

The current sources CSp and CSm can each include a p-channel transistor, for example. Specifically, as illustrated in FIG. 16B, the current sources CSp and CSm can each include a transistor M63 that is a p-channel transistor. As the transistor M63, a transistor that can be used as the above-described transistor M62 can be used.

In each of the current sources CSp and CSm, a first terminal of the transistor M63 is connected to the wiring HE through the input terminal, and a gate of the transistor M63 is connected to a wiring BE3. A second terminal of the transistor M63 in the current source CSp is connected to the terminal T07 through the output terminal, and the second terminal of the transistor M63 in the current source CSm is connected to the terminal T08 through the output terminal.

The wiring BE3 functions as a wiring for supplying a predetermined bias potential to the gates of the transistors M63 in the current sources CSp and CSm.

In each of the current sources CSp and CSm, a predetermined potential is supplied to each of the gate and the first terminal of the transistor M63, whereby the current I_{MX} flows between the source and the drain of the transistor M63. Note that the amount of the current I_{MX} flowing through the output terminal of the current source CSp can be changed to a desired amount by changing one or both of a high power supply potential supplied by the wiring HE and a potential supplied by the wiring BE3.

The current source circuits CCS in FIGS. 11 and 13 can employ the circuit structure of the current supply circuits CCS in FIGS. 16C and 16D, other than those in FIGS. 16A and 16B.

The current supply circuit CCS in FIG. 16C includes a current source CS and a current generation circuit CTP, for example. The current generation circuit CTP includes a terminal T25 functioning as an input terminal and terminals T91 and T92 functioning as output terminals.

An input terminal of the current source CS is connected to the wiring LE, and an output terminal of the current source CS is connected to the terminal T25 of the current generation circuit CTP. The terminal T91 of the current generation circuit CTP is connected to the terminal T07, and the terminal T92 of the current generation circuit CTP is connected to the terminal T08.

The current source CS has a function of, for example, generating the current I_{MX} and making it flow through the output terminal in response to a fixed potential (here, a low power supply potential) input to the input terminal from the wiring LE. Note that the current source CS is a sink current source, and the current I_{MX} supplied from the current source CS serves as a discharge current for the current generation circuit CTP. It is preferable that the current source CS can determine the current I_{MX} freely.

The current source CS can include an n-channel transistor, for example. Specifically, as illustrated in FIG. 16D, the current source CS can include a transistor M40 that is an n-channel transistor. As the transistor M40, a transistor that can be used as the above-described transistor M13 or M14 can be used, for example.

In the current source CS, a first terminal of the transistor M40 is connected to the wiring LE through the input terminal, and a gate of the transistor M40 is connected to the wiring BE3. A second terminal of the transistor M40 is connected to the terminal T25 of the current generation circuit CTP.

The wiring BE3 here functions as a wiring for supplying a predetermined bias potential to the gate of the transistor M40.

In the current source CS, a predetermined potential is supplied to each of the gate and the first terminal of the transistor M40, whereby the current I_{MX} flows between the source and the drain of the transistor M40. Note that the amount of the current I_{MX} flowing through the output terminal of the current source CS can be changed to a desired amount by changing one or both of a low power supply potential supplied by the wiring LE and a potential supplied by the wiring BE3.

The current generation circuit CTP has a function of a p-type current mirror circuit with one input and two outputs. Specifically, the current generation circuit CTP has a function of generating a current flowing through each of the terminals T91 and T92 with reference to a current flowing through the terminal T25, with its mirroring function. That is, with the mirroring function, the current generation circuit CTP can make the current I_{MX} flow through each of the terminals T91 and T92 as a discharge current with reference to the current I_{MX} flowing between the terminal T25 and the output terminal of the current source CS.

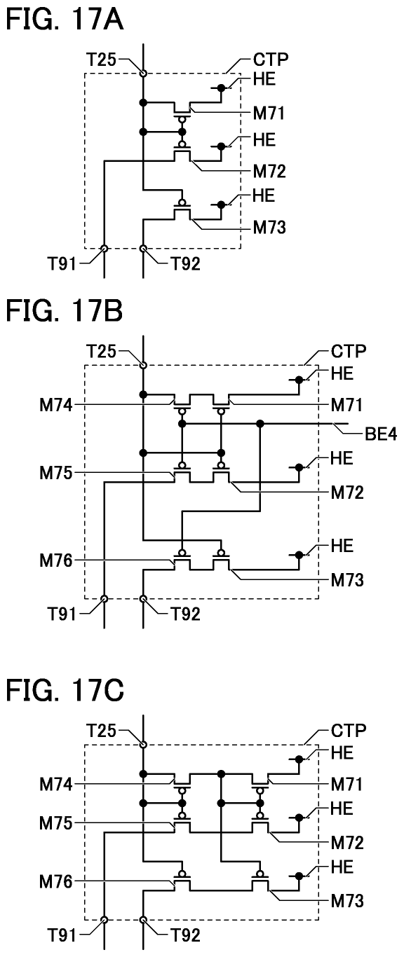

FIGS. 17A to 17C illustrate circuit structure examples of the current generation circuit CTP in FIGS. 16C and 16D.

The current generation circuit CTP in FIG. 17A is a variation example of the current generation circuit CBp (or the current generation circuit CBm) illustrated in FIG. 8, and is different therefrom in being not an n-type current mirror circuit but a p-type current mirror circuit and having a larger number of output terminals.

The current generation circuit CTP in FIG. 17A includes a transistor M71 to a transistor M73 that are p-channel transistors. First terminals of the transistors M71 to M73 are connected to the wiring HE, and gates of the transistors M71 to M73 and a second terminal of the transistor M71 are connected to the terminal T25. A second terminal of the transistor M72 is connected to the terminal T91, and a second terminal of the transistor M73 is connected to the terminal T92.

The current generation circuit CTP in FIG. 17B is a variation example of the current generation circuit CB in FIG. 9A, and is different therefrom in being not an n-type current mirror circuit but a p-type current mirror circuit and having a larger number of output terminals.

The current generation circuit CTP in FIG. 17B includes the transistor M71 to a transistor M76 that are p-channel transistors. The first terminals of the transistors M71 to M73 are electrically connected to the wiring HE. The second terminal of the transistor M71 is connected to the first terminal of the transistor M74, the second terminal of the transistor M72 is connected to a first terminal of the transistor M75, and the second terminal of the transistor M73 is connected to a first terminal of the transistor M76. The gates of the transistors M71 to M73 and a second terminal of the transistor M74 are connected to the terminal T25. A second terminal of the transistor M75 is connected to the terminal T91, and a second terminal of the transistor M76 is connected to the terminal T92.

The current generation circuit CTP in FIG. 17C is a variation example of the current generation circuit CB in FIG. 9B, and is different therefrom in being not an n-type current mirror circuit but a p-type current mirror circuit and having a larger number of output terminals.

The current generation circuit CTP in FIG. 17C includes the transistors M71 to M76 that are p-channel transistors. The first terminals of the transistors M71 to M73 are connected to the wiring HE. The gates of the transistors M71 to M73 are connected to the second terminal of the transistor M71 and the first terminal of the transistor M74. Gates of the transistors M74 to M76 are connected to the second terminal of the transistor M74 and the terminal T25. The second terminal of the transistor M75 is connected to the terminal T91, and the second terminal of the transistor M76 is connected to the terminal T92.

Like the wiring HE illustrated in FIG. 1A, the wiring HE functions as a wiring for supplying a fixed potential, for example. The fixed potential is preferably a high-level potential at which the first terminals of the transistors M71 to M73 serve as the sources.

As each of the p-channel transistors illustrated in FIGS. 17A to 17C, a transistor that can be used as the transistor M62 illustrated in FIG. 1A can be used.

As described above, the current generation circuit CTP in FIG. 17A is different from the current generation circuits CBp and CBm illustrated in FIG. 8 in that the polarity of the current mirror circuit is changed from n-type to p-type and the number of output terminals is increased from one to two; thus, like the current generation circuits CBp and CBm illustrated in FIG. 8, the current generation circuit CTP in FIG. 17A can make the current I_{MX} flow through each of the terminals T91 and T92 with reference to the current I_{MX} flowing between the terminal T25 and the output terminal of the current source CS, with its mirroring function. Note that a sink current flows through each of the terminals T91 and T92 in the current generation circuits CBp and CBm in FIG. 8, whereas a discharge current flows through each of the terminals T91 and T92 in the current generation circuit CTP in FIG. 17A.

Note that like the current generation circuit CTP in FIG. 17A, the current generation circuits CTP illustrated in FIGS. 17B and 17C can also make the current I_{MX} flow through each of the terminals T91 and T92 with reference to the current I_{MX} flowing between the terminal T25 and the output terminal of the current source CS, with its mirroring function. In the current generation circuits CTP in FIGS. 17B and 17C, the transistors M74 to M76 are provided as the clamp transistors for the transistors M71 to M73, as in the current generation circuits CB in FIGS. 9A and 9B; thus, a decrease in the threshold voltage of the transistors M71 to M73 due to DIBL can be prevented.

Although the current generation circuit CTP is a p-type current mirror circuit in FIGS. 17A to 17C, in the case where discharge currents flowing through the terminals T07 and T08 of the current supply circuit CCS are desired to be changed to sink currents, the current generation circuit CTP is preferably changed to an n-type current mirror circuit. In that case, all the p-channel transistors in FIGS. 17A to 17C are preferably changed to n-channel transistors. In addition, the wiring HE supplying a high-level potential is preferably changed to a wiring supplying a low-level potential (e.g., the wiring LE).

### Variation Example 3 of Semiconductor Device

Note that the structure of the semiconductor device of one embodiment of the present invention is not limited to the circuit structure in FIG. 13. The semiconductor device of one embodiment of the present invention can have a structure which is changed from the circuit structure in FIG. 13 as appropriate.

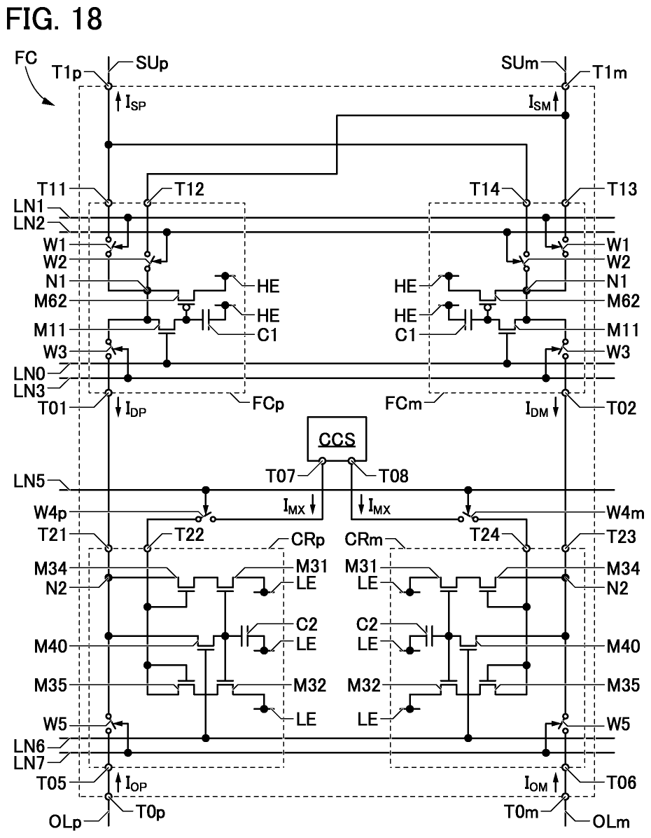

The circuit FC illustrated in FIG. 18 is a variation example of the circuit FC in FIG. 13, and is different therefrom in that a switch W4p and a switch W4m are provided and the current generation circuits CRp and CRm each include a switch W5, the transistor M40, and a capacitor C2.

Note that the switches W4p and W4m may be included in each of the current generation circuits CRp and CRm. Alternatively, the switches W4p and W4m may be included in the current supply circuit CCS.

The terminal T07 of the current supply circuit CCS is connected to a first terminal of the switch W4p instead of the terminal T22 of the current generation circuit CRp, and a second terminal of the switch W4p is connected to the terminal T22 of the current generation circuit CRp. Similarly, the terminal T08 of the current supply circuit CCS is connected to a first terminal of the switch W4m instead of the terminal T24 of the current generation circuit CRm, and a second terminal of the switch W4m is connected to the terminal T24 of the current generation circuit CRm. Control terminals of the switches W4p and W4m are connected to a wiring LN5.

In the current generation circuit CRp, the terminal T21 is connected to a first terminal of the switch W5 instead of the terminal T05, and a second terminal of the switch W5 is connected to the terminal T05. A control terminal of the switch W5 is connected to a wiring LN7.

In the current generation circuit CRp, the gates of the transistors M31 and M32 are connected to the first terminal of the transistor M40 and a first terminal of the capacitor C2 instead of the terminal T21 and the second terminal of the transistor M34. A second terminal of the capacitor C2 is connected to the wiring LE. The gate of the transistor M40 is connected to a wiring LN6. The second terminal of the transistor M40 is connected to the terminal T21, the second terminal of the transistor M34, and the first terminal of the switch W5.

Note that in this specification, a connection portion of the second terminal of the transistor M40, the second terminal of the transistor M34, and the first terminal of the switch W5 in the current generation circuit CRp is referred to as a node N2.

For the circuit structure of the current generation circuit CRm, the above description of the circuit structure of the current generation circuit CRp can be referred to. Specifically, for example, the above description of the circuit structure of the current generation circuit CRp can be applied to the circuit structure of the current generation circuit CRm in FIG. 18 by replacing the terminal T21 with the terminal T23, replacing the terminal T22 with the terminal T24, and replacing the terminal T05 with the terminal T06.

The wiring LN5 functions as a wiring for transmitting a control signal to switch the on state and the off state of the switches W4p and W4m, for example. Similarly, the wiring LN7 functions as a wiring for transmitting a control signal to switch the on state and the off state of the switch W5, for example.

The wiring LN6 functions as a wiring for transmitting a control signal to switch the on state and the off state of the transistor M40, for example. For example, the transistor M40 is turned on when the control signal is a high-level potential, and turned off when the control signal is a low-level potential.

Next, an operation example of the circuit FC illustrated in FIG. 18 will be described.

FIG. 19 is a timing chart showing an operation example of the circuit FC. Note that changes in potentials of the wirings LN0 to LN3 in the period from Time TL1 to Time TL4 shown in FIG. 19 are similar to those in the timing chart shown in FIG. 1B. That is, the operation in the timing chart in FIG. 1B is referred to for the operation of the circuits FCp and FCm included in the circuit FC. FIG. 19 also shows changes in potentials, which are control signals supplied to the wirings LN5 to LN7, in and around the period from Time TL1 to Time TL6.

In the period from Time TL1 to Time TL3, a low-level potential is supplied to each of the wirings LN5 to LN7. Thus, the switches W4p, W4m, and W5 and the transistor M40 are in an off state.

At Time TL3, a high-level potential is supplied to the wiring LN5, so that the switches W4p and W4m are turned on. Accordingly, the current I_{MX} can flow from the terminal T07 of the current supply circuit CCS to the terminal T22 of the current generation circuit CRp. Similarly, the current I_{MX} can flow from the terminal T08 of the current supply circuit CCS to the terminal T24 of the current generation circuit CRp. At this time, the gate potentials of the transistors M34 and M35 are determined in accordance with the current I_{MX}.

At Time TL3, a high-level potential is supplied to the wiring LN6, so that the transistor M40 is turned on in each of the current generation circuits CRp and CRm. At Time TL3, a high-level potential is supplied to each of the wirings LN2 and LN3, so that the switches W2 and W3 are turned on in each of the circuits FCp and FCm; accordingly, the current I_{DP} flows through the terminal T01 of the circuit FCp and the current I_{DM} flows through the terminal T02 of the circuit FCm. Thus, in the current generation circuit CRp, a potential corresponding to the current I_{DP} can be supplied to the gates of the transistors M31 and M32, so that the current I_{DP} can flow between the source and the drain of each of the transistors M31 and M32. Similarly, in the current generation circuit CRm, a potential corresponding to the current I_{DM} can be supplied to the gates of the transistors M31 and M32, so that the current I_{DM} can flow between the source and the drain of each of the transistors M31 and M32.

At Time TL4, a low-level potential is supplied to the wiring LN5, so that the switches W4p and W4m are turned off and supply of the current I_{MX} from the terminal T07 of the current supply circuit CCS to the terminal T22 of the current generation circuit CRp is stopped. Similarly, supply of the current I_{MX} from the terminal T08 of the current supply circuit CCS to the terminal T24 of the current generation circuit CRm is stopped. At Time TL4, a low-level potential is supplied to the wiring LN6, so that the transistor M40 is turned off in each of the current generation circuits CRp and CRm. Thus, in the current generation circuit CRp, a potential corresponding to the current I_{DP} is held at the first terminal of the capacitor C2, and in the current generation circuit CRm, a potential corresponding to the current I_{DM} is held at the first terminal of the capacitor C2. At Time TL4, a low-level potential is supplied to the wiring LN3, so that the switch W3 is turned off in each of the circuits FCp and FCm, and the currents stop flowing through the terminal T01 of the circuit FCp and the terminal T02 of the circuit FCm.

At Time TL5, a high-level potential is supplied to the wiring LN5. Accordingly, the switch W4p is turned on and the current I_{MX} flows from the terminal T07 of the current supply circuit CCS to the terminal T22 of the current generation circuit CRp. Since the potential corresponding to the current I_{DP} is held at the gates of the transistors M31 and M32 in the current generation circuit CRp, the current I_{DP} can flow between the source and the drain of each of the transistors M31 and M32. At Time TL5, a high-level potential is supplied to the wiring LN7, so that the switch W5 is turned on and the smaller of the currents I_{DP} and I_{MX} flows as the current I_{OP} from the terminal T05 to the wiring LE through the transistors M31 and M34 in the current generation circuit CRp.

Similarly, a high-level potential is supplied to the wiring LN5, so that the switch W4m is turned on and the current I_{MX} flows from the terminal T08 of the current supply circuit CCS to the terminal T24 of the current generation circuit CRm. Since the potential corresponding to the current I_{DM} is held at the gates of the transistors M31 and M32 in the current generation circuit CRm, the current I_{DM} can flow between the source and the drain of each of the transistors M31 and M32. At Time TL5, a high-level potential is supplied to the wiring LN7, so that the switch W5 is turned on and the smaller of the currents I_{DM} and I_{MX} flows as the current I_{OM} from the terminal T06 to the wiring LE through the transistors M31 and M34 in the current generation circuit CRm.

At Time TL6, a low-level potential is supplied to each of the wirings LN5 and LN7. Accordingly, the switches W4p and W4m are turned off, and the switch W5 in each of the current generation circuits CRp and CRm is turned off Thus, output of the currents from the terminal T05 of the current generation circuit CRp and the terminal T06 of the current generation circuit CRm is stopped.

In the current generation circuit CRp in FIG. 13, an input current and an output current flow between sources and drains of different transistors; thus, variation in the electrical characteristics of these transistors is likely to make a difference between the input and output currents, leading to inaccurate mirroring in some cases. By contrast, in the current generation circuit CRp in FIG. 18, both an input current and an output current flow between the source and the drain of the transistor M31; thus, there is no influence of the variation in electrical characteristics mentioned above, and the difference between the input and output currents can be small.

As shown in the timing chart in FIG. 19, a high-level potential or a low-level potential is supplied to the wirings LN6, LN2, and LN3 at the same timing. Thus, in the case where the circuit FC in FIG. 18 operates in accordance with the timing chart in FIG. 19, the wirings LN2, LN3, and LN6 may be combined into one wiring. In addition, as shown in the timing chart in FIG. 19, a signal transmitted to the wiring LN5 can be a logical sum of a signal transmitted to the wiring LN2 and a signal transmitted to the wiring LN7. For example, the circuit FC of one embodiment of the present invention may have a structure including a logic circuit performing an OR operation, with its two input terminals connected to the wirings LN2 and LN7 and its output terminal connected to the control terminals of the switches W4p and W4m.

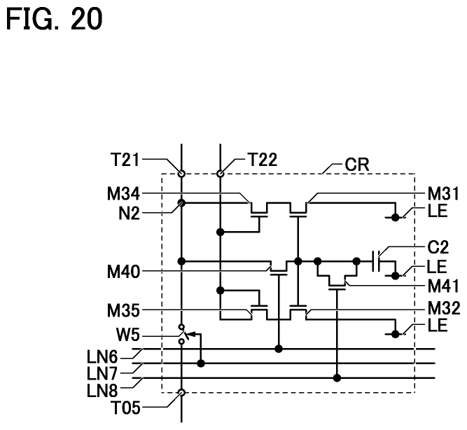

The circuit structures of the current generation circuits CRp and CRm included in the circuit FC in FIG. 18 can be changed into that of the current generation circuit CR illustrated in FIG. 20.

The current generation circuit CR illustrated in FIG. 20 has a structure including a transistor M41 that has a function of a capacitor where the gate capacitance serves as capacitance like the transistor M21 in FIG. 3A. Specifically, the first terminal of the transistor M40, the gate of the transistor M31, the gate of the transistor M32, and the first terminal of the capacitor C2 are connected to a first terminal and a second terminal of the transistor M41, and a wiring LN8 is connected to a gate of the transistor M41.

Like the wiring LN4 illustrated in FIG. 3A, the wiring LN8 functions as a wiring for supplying a potential to the gate of the transistor M41 in order to increase the gate potentials of the transistors M31 and M32 by capacitive coupling when the transistor M40 is in an off state, i.e., when the gates of the transistors M31 and M32 are in a floating state. Thus, the wiring LN8 preferably functions as a wiring transmitting a signal with the inverted logic of a signal supplied to the wiring LN6.

With the use of the circuit FCa as the semiconductor device described in this embodiment, a difference between the input current I_{SP} and the maintained current I_{SP} can be small. Furthermore, with the use of the input current I_{SM} and the maintained current I_{SP}, a highly accurate arithmetic operation result of a ReLU function can be expressed. Furthermore, by combining two circuits FCa, a highly accurate arithmetic operation result of an identity function can be expressed. By combining two circuits FCa and two 2-input minimum pooling circuits, a highly accurate arithmetic operation result of a Hard Tanh function can be expressed.

Note that this embodiment can be combined with the same embodiment or any of the other embodiments in this specification as appropriate. For example, the configurations, structures, methods, and the like described in this embodiment can be used in an appropriate combination with any of the other configurations, the other structures, the other methods, and the like described in this embodiment. Alternatively, for example, the configurations, structures, methods, and the like described in this embodiment can be used in an appropriate combination with any of the configurations, structures, methods, and the like described in the other embodiments and the like.

### Embodiment 2

In this embodiment, an arithmetic device using the semiconductor device described in the above embodiment is described.

### Structure Example 1 of Arithmetic Device

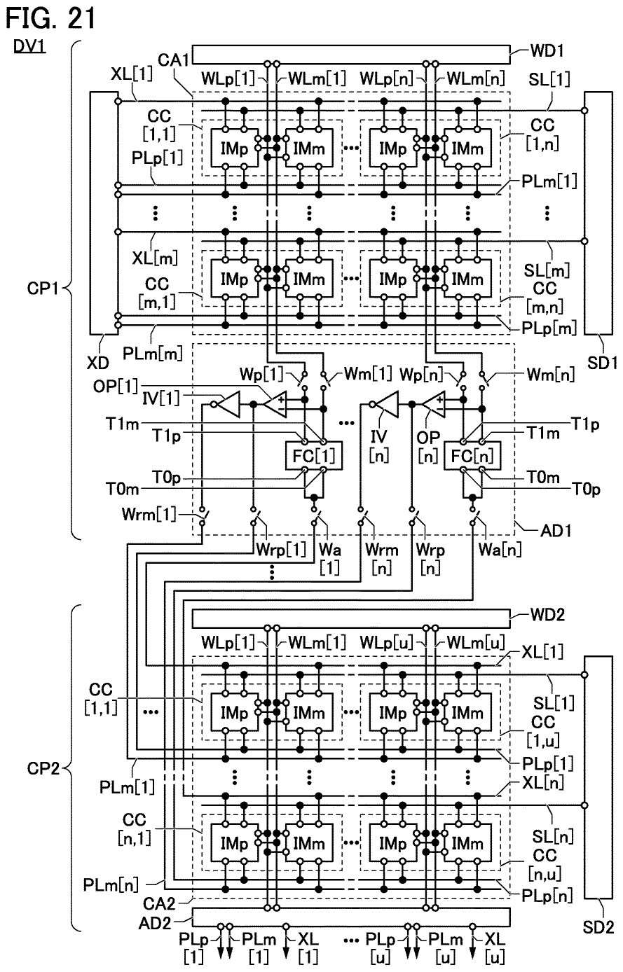

FIG. 21 is a circuit diagram illustrating a structure example of an arithmetic device using the semiconductor device of one embodiment of the present invention. An arithmetic device DV1 illustrated in FIG. 21 has a function of performing a product-sum operation of a plurality of pieces of first data and a plurality of pieces of second data, and an arithmetic operation of a function where the result of the product-sum operation is substituted as a variable. The arithmetic device DV1 is suitable for an arithmetic operation in an artificial neural network, and for example, the first data can be a weight coefficient (also referred to as connection strength) and the second data can be a value corresponding to an input signal to a neuron. The function can be an activation function used for the artificial neural network. The arithmetic device DV1 in FIG. 21 performs, for example, a product-sum operation from an input layer to the first intermediate layer and an arithmetic operation of an activation function, and a product-sum operation from the first intermediate layer to the second intermediate layer and an arithmetic operation of an activation function in an artificial neural network.

The arithmetic device DV1 includes a first arithmetic portion CP1 and a second arithmetic portion CP2, for example. The first arithmetic portion CP1 is a region that performs the product-sum operation from the input layer to the first intermediate layer and the arithmetic operation of the activation function, and the second arithmetic portion CP2 is a region that performs the product-sum operation from the first intermediate layer to the second intermediate layer and the arithmetic operation of the activation function.

The first arithmetic portion CP1 includes a cell array CA1, a driver circuit WD1, a driver circuit XD, a driver circuit SD1, and a driver circuit AD1. The second arithmetic portion CP2 includes a cell array CA2, a driver circuit WD2, a driver circuit SD2, and a driver circuit AD2.

The cell arrays CA1 and CA2 each include a plurality of arithmetic circuits CC; for example, the arithmetic circuits CC are arranged in a matrix of m rows and n columns (each of m and n is an integer greater than or equal to 1) in the cell array CA1, and the arithmetic circuits CC are arranged in a matrix of n rows and u columns (u is an integer greater than or equal to 1) in the cell array CA2. Note that m corresponds to the number of neurons provided in the input layer, n corresponds to the number of neurons provided in the first intermediate layer, and u corresponds to the number of neurons provided in the second intermediate layer.

In FIG. 21, in the cell array CA1, [i,j] is added to the reference numeral of the arithmetic circuit CC positioned at the addresses of the i-th row and the j-th column (here, i is an integer greater than or equal to 1 and less than or equal to m and j is an integer greater than or equal to 1 and less than or equal to n). In the cell array CA2, [j,k] is added to the reference numeral of the arithmetic circuit CC positioned at the address of the j-th row and the k-th column (here, k is an integer greater than or equal to 1 and less than or equal to u). Note that FIG. 21 selectively illustrates an arithmetic circuit CC[1,1], an arithmetic circuit CC[m,1], an arithmetic circuit CC[1,n], and an arithmetic circuit CC[m,n] among the plurality of arithmetic circuits CC included in the cell array CA1, and selectively illustrates the arithmetic circuit CC[1,1], an arithmetic circuit CC[n,1], an arithmetic circuit CC[1,u], and an arithmetic circuit CC[n,u] among the plurality of arithmetic circuits CC included in the cell array CA2.

The arithmetic circuits CC provided in the cell arrays CA1 and CA2 each include an arithmetic cell IMp and an arithmetic cell IMm, for example. Specifically, in the arithmetic circuit CC in FIG. 21, the arithmetic cells IMp and IMm are illustrated on the left and right sides, respectively. Thus, in the cell arrays CA1 and CA2, the arithmetic cells IMp and IMm are alternately provided for each column.

In each of the cell arrays CA1 and CA2, a plurality of wirings XL, a plurality of wirings PLp, a plurality of wirings PLm, and a plurality of wirings SL extend in the rows. In each of the cell arrays CA1 and CA2, a plurality of wirings WLp and a plurality of wirings WLm extend in the columns.

Specifically, in the cell array CA1, wirings XL[1] to XL[m] extend as the plurality of wirings XL; wirings PLp[1] to PLp[m] extend as the plurality of wirings PLp; wirings PLm[1] to PLm[m] extend as the plurality of wirings PLm; wirings SL[1] to SL[m] extend as the plurality of wirings SL; wirings WLp[1] to WLp[n] extend as the plurality of wirings WLp; and wirings WLm[1] to WLm[n] extend as the plurality of wirings WLm, for example. In the cell array CA2, wirings XL[1] to XL[n] extend as the plurality of wirings XL; wirings PLp[1] to PLp[n] extend as the plurality of wirings PLp; wirings PLm[1] to PLm[n] extend as the plurality of wirings PLm; wirings SL[1] to SL[n] extend as the plurality of wirings SL; wirings WLp[1] to WLp[u] extend as the plurality of wirings WLp; and wirings WLm[1] to WLm[u] extend as the plurality of wirings WLm, for example.

In first arithmetic portion CP1, the driver circuit WD1 is connected to the wirings WLp[1] to WLp[n] and the wirings WLm[1] to WLm[n]. The driver circuit XD is connected to the wirings XL[1] to XL[m], the wirings PLp[1] to PLp[m], and the wirings PLm[1] to PLm[m]. The driver circuit SD1 is connected to the wirings SL[1] to SL[m].

The driver circuit AD1 is connected to the wirings WLp[1] to WLp[n] and the wirings WLm[1] to WLm[n] extending to the cell array CA1. The driver circuit AD1 is connected to the wirings XL[1] to XL[n], the wirings PLp[1] to PLp[n], and the wirings PLm[1] to PLm[n] extending to the cell array CA2.

The driver circuit WD2 is connected to the wirings WLp[1] to WLp[u] and the wirings WLm[1] to WLm[u] extending to the cell array CA2. The driver circuit SD2 is connected to the wirings SL[1] to SL[n] extending to the cell array CA2. The driver circuit AD2 is connected to the wirings WLp[1] to WLp[u] and the wirings WLm[1] to WLm[u] extending to the cell array CA2. In the example illustrated in FIG. 21, the driver circuit AD2 is connected to the wirings XL[1] to XL[u], the wirings PLp[1] to PLp[u], and the wirings PLm[1] to PLm[u] for transmitting a signal to a layer (an intermediate layer or an output layer) subsequent to the second intermediate layer.

In the cell array CA1, the arithmetic cells IMp and IMm included in the arithmetic circuit CC[i,j] are connected to the wirings XL[i], PLp[i], PLm[i], SL[i], WLp[j], and WLm[j].

In the cell array CA2, the arithmetic cells IMp and IMm included in the arithmetic circuit CC[j,k] are connected to the wirings XL[j], PLp[j], PLm[j], SL[j], WLp[k], and WLm[k].

The arithmetic circuit CC[i,j] in the cell array CA1 has a function of holding the first data corresponding to a signal (e.g., a current signal or a voltage signal) transmitted from the wirings WLp[j] and WLm[j] and a function of multiplying the held first data by the second data corresponding to a signal transmitted from the wirings XL[i], PLp[i], and PLm[i]. Specifically, the wiring XL[i] is a wiring transmitting a signal indicating the absolute value of the second data, and the wirings PLp[i] and PLm[i] are wirings transmitting a signal indicating the sign (positive, negative, or 0) of the second data. In addition, the arithmetic circuit CC[i,j] has a function of outputting the multiplication result of the first and second data to the wirings WLp[j] and WLm[j] as a signal.

Like the arithmetic circuit CC[i,j] in the cell array CA1, the arithmetic circuit CC[j,k] in the cell array CA2 has a function of holding the first data corresponding to a signal transmitted from the wirings WLp[k] and WLm[k] and a function of multiplying the held first data by the second data corresponding to a signal transmitted from the wirings XL[j], PLp[j], and PLm[j]. The second data here is the result obtained through the product-sum operation from the input layer to the first intermediate layer and the arithmetic operation of the activation function in the artificial neural network, and corresponds to the result of an arithmetic operation performed by the driver circuit AD1 in the first arithmetic portion CP1. The wiring XL[j] is a wiring transmitting a signal indicating the absolute value of the second data, and the wirings PLp[j] and PLm[j] are wirings transmitting a signal indicating the sign (positive, negative, or 0) of the second data. In addition, the arithmetic circuit CC[j,k] has a function of outputting the multiplication result of the first and second data to the wirings WLp[k] and WLm[k] as a signal.

The driver circuit WD1 has a function of, for example, obtaining the first data from the outside, converting the first data into a signal (e.g., a current signal or a voltage signal) to be written to the arithmetic circuit CC of the cell array CA1, and transmitting the signal to the wirings WLp and WLm. Specifically, for example, the driver circuit WD1 obtains the first data w[i,j](here, w[i,j] is a real number) from the outside, and transmits the first data w[i,j] to the wirings WLp[j] and WLm[j] so that the first data w[i,j] is held in the arithmetic cells IMp and IMm included in the arithmetic circuit CC[i,j]. Here, the first data w[i,j] corresponds to a weight coefficient (connection strength) between a neuron of the input layer and a neuron of the first intermediate layer in the artificial neural network.

The first data w[i,j] held in the arithmetic circuit CC[i,j] is expressed using two variables wp[i,j] and wm[i,j]. For example, when the first data w[i,j] is greater than 0, the first data w[i,j] can be expressed as wp[i,j]=w[i,j] and wm[i,j]=0. For example, when the first data w[i,j] is less than 0, the first data w[i,j] can be expressed as wp[i,j]=0 and wm[i,j]=−w[i,j]. For example, when the first data is 0, the first data can be expressed as wp[i,j]=0 and wm[i,j]=0. From the above, the first data w[i,j] can be expressed as w[i,j]=wp[i,j]−wm[i,j].

Note that wp[i,j] is held in the arithmetic cell IMp of the arithmetic circuit CC[i,j], and wm[i,j] is held in the arithmetic cell IMm of the arithmetic circuit CC[i,j].

The driver circuit SD1 has a function of, for example, transmitting a selection signal to the wiring SL[i], in order to supply the selection signal to the arithmetic circuits CC[i,1] to CC[i,n] arranged in the i-th row of the cell array CA1 when the first data w[i,1] to w[i,n] are written to the arithmetic circuits CC[i,1] to CC[i,n] in the i-th row of the cell array CA1. In addition, the driver circuit SD1 has a function of transmitting a non-selection signal to the wirings SL[1] to SL[m] other than the wiring SL[i], in order to supply the non-selection signal to the arithmetic circuits CC[1,1] to CC[m,n] arranged in the rows other than the i-th row of the cell array CA1 when the first data w[i,1] to w[i,n] are written to the arithmetic circuits CC[i,1] to CC[i,n] in the i-th row of the cell array CA1. Note that while the first arithmetic portion CP1 of the arithmetic device DV1 performs a product-sum operation, the first data is written to none of the arithmetic circuits CC[1,1] to CC[m,n], and thus the driver circuit SD1 transmits a non-selection signal to all of the wirings SL[1] to SL[m].

The driver circuit XD has a function of obtaining the second data from the outside, converting the second data into a signal to be transmitted to the arithmetic circuit CC, and transmitting the signal to the wirings XL[i], PLp[i], and PLm[i]. Specifically, a current in an amount corresponding to the absolute value of the second data flows through the wiring XL[i], and a potential signal corresponding to the sign (positive, negative, or 0) of the second data is supplied to each of the wirings PLp[i] and PLm[i]. For example, when the second data transmitted by the driver circuit XD is x[i](here, x[i] is a real number), the driver circuit XD supplies a current in an amount corresponding to |x[i]| to the wiring XL[i]. When the second data x[i] is a positive value, the driver circuit XD supplies a high-level potential to the wiring PLp[i] and a low-level potential to the wiring PLm[i], for example. When the second data x[i] is a negative value, the driver circuit XD supplies a low-level potential to the wiring PLp[i] and a high-level potential to the wiring PLm[i], for example. When the second data x[i] is 0, the driver circuit XD supplies a low-level potential to each of the wirings PLp[i] and PLm[i], for example.

When a signal corresponding to x[i] is transmitted as the second data from the wiring XL[i] to each of the arithmetic cell IMp holding wp[i,j] and the arithmetic cell IMm holding wm[i,j], multiplication of wp[i,j] by |x[i]| is performed in the arithmetic cell IMp and multiplication of wm[i,j] by |x[i]| is performed in the arithmetic cell IMm.

When the second data x[i] is a positive value, to each of the arithmetic cells IMp and IMm, a high-level potential is supplied from the wiring PLp[i] and a low-level potential is supplied from the wiring PLm[i]. At this time, electrical continuity is established between the arithmetic cell IMp and the wiring WLp[j], and is not established between the arithmetic cell IMp and the wiring WLm[j]. In addition, electrical continuity is not established between the arithmetic cell IMm and the wiring WLp[j], and is established between the arithmetic cell IMm and the wiring WLm[j]. Then, the arithmetic cell IMp supplies a current corresponding to wp[i,j]×|x[i]| to the wiring WLp[j], and the arithmetic cell IMm supplies a current corresponding to wm[i,j]×|x[i]| to the wiring WLm[j].

Specifically, when the first data w[i,j] is a positive value, wm[i,j]=0 and wm[i,j]×|x[i]|=0; consequently, a current does not flow between the arithmetic cell IMm and the wiring WLm[j], and a current corresponding to wp[i,j]×|x[i]| flows between the arithmetic cell IMp and the wiring WLp[j]. When the first data w[i,j] is a negative value, wp[i,j]=0 and wp[i,j]×|x[i]|=0; consequently, a current does not flow between the arithmetic cell IMp and the wiring WLp[j], and a current corresponding to wm[i,j]×|x[i]| flows between the arithmetic cell IMm and the wiring WLm[j]. When the first data w[i,j] is 0, wp[i,j]=0 and wm[i,j]=0, and thus wp[i,j]×|x[i]|=0 and wm[i,j]×|x[i]|=0; consequently, a current does not flow between the arithmetic cell IMp and the wiring WLp[j] or between the arithmetic cell IMm and the wiring WLm[j].

When the second data x[i] is a negative value, to each of the arithmetic cells IMp and IMm, a low-level potential is supplied from the wiring PLp[i] and a high-level potential is supplied from the wiring PLm[i]. At this time, electrical continuity is not established between the arithmetic cell IMp and the wiring WLp[j], and is established between the arithmetic cell IMp and the wiring WLm[j]. In addition, electrical continuity is established between the arithmetic cell IMm and the wiring WLp[j], and is not established between the arithmetic cell IMm and the wiring WLm[j]. Then, the arithmetic cell IMp supplies a current corresponding to wp[i,j]×|x[i]| to the wiring WLm[j], and the arithmetic cell IMm supplies a current corresponding to wm[i,j]×|x[i]| to the wiring WLp[j].

Specifically, when the first data w[i,j] is a positive value, wm[i,j]=0 and wm[i,j]×|x[i]|=0; consequently, a current does not flow between the arithmetic cell IMm and the wiring WLp[j], and a current corresponding to wp[i,j]×|x[i]| flows between the arithmetic cell IMp and the wiring WLm[j]. When the first data w[i,j] is a negative value, wp[i,j]=0 and wp[i,j]×|x[i]|=0; consequently, a current does not flow between the arithmetic cell IMp and the wiring WLm[j], and a current corresponding to wm[i,j]×|x[i]| flows between the arithmetic cell IMm and the wiring WLp[j]. When the first data w[i,j] is 0, wp[i,j]=0 and wm[i,j]=0, and thus wp[i,j]×|x[i]|=0 and wm[i,j]×|x[i]|=0; consequently, a current does not flow between the arithmetic cell IMp and the wiring WLm[j] or between the arithmetic cell IMm and the wiring WLp[j].

When the second data x[i] is 0, a low-level potential is supplied from each of the wirings PLp[i] and PLm[i] to each of the arithmetic cells IMp and IMm. At this time, electrical continuity is not established between the arithmetic cell IMp and the wiring WLp[j] or WLm[j] and between the arithmetic cell IMm and the wiring WLp[j] or WLm[j]. Thus, a current does not flow between the arithmetic cell IMp and the wiring WLp[j] or WLm[j] or between the arithmetic cell IMm and the wiring WLp[j] or WLm[j], regardless of the value of the first data w[i,j].

In the case of the above operation, in the j-th column of the cell array CA1, a total current corresponding to the sum of wp[1,j]×|x[1]| to wp[m,j]×|x[m]| output from the m arithmetic cells IMp arranged in the j-th column flows through the wiring WLp[j]. Similarly, a total current corresponding to the sum of wm[1,j]×|x[1]| to wm[m,j]×|x[m]| output from the m arithmetic cells IMm arranged in the j-th column flows through the wiring WLm[j].

Furthermore, the total current flowing through the wiring WLp[j] is the sum of the positive values obtained by w[i,j]×x[i], and the total current flowing through the wiring WLm[j] is the sum of the negative values obtained by w[i,j]×x[i]; thus, the result of the product-sum operation of the first data w[1,j] to w[m,j] and the second data x[1] to x[m] can be obtained by obtaining the differential current between the total current flowing through the wiring WLp[j] and the total current flowing through the wiring WLm[j].

Note that the arithmetic cells IMp and IMm have functions of holding wp and wm respectively, in addition to a function of performing multiplication; thus, the operation method of the arithmetic device DV1 including the arithmetic cells IMp and IMm is referred to as an in-memory computing (iMC) method or a computing in-memory (CiM) method in some cases. Examples of a memory element that can be provided in each of the arithmetic cells IMp and IMm include a variable resistor used in a resistive random access memory (ReRAM), a magnetic tunnel junction (MTJ) element used in a magnetoresistive random access memory (MRAM), a memory element used in a phase-change random access memory (PRAM), and a ferroelectric capacitor used in a ferroelectric random access memory (FeRAM). As the memory element, a capacitor can be used. In particular, a gain-cell memory circuit combining a capacitor used as a memory element, an amplifier transistor, and a holding transistor can be used as the arithmetic cell.

The driver circuit AD1 has a function of, for example, obtaining currents flowing through the wirings WLp[j] and WLm[j], performing an arithmetic operation of a function where the differential current is substituted as a variable, and transmitting a signal corresponding to the arithmetic operation result to the wirings XL[j], PLp[j], and PLm[j] extending to the cell array CA2.

The driver circuit AD1 illustrated in FIG. 21 includes, for example, a switch Wp[1] to a switch Wp[n], a switch Wm[1] to a switch Wm[n], a switch Wa[1] to a switch Wa[n], a switch Wrp[1] to a switch Wrp[n], a switch Wrm[1] to a switch Wrm[n], a circuit FC[1] to a circuit FC[n], a comparator OP[1] to a comparator OP[n], and an inverter IV[1] to an inverter IV[n]. The circuit FC illustrated in FIG. 4, 7, 8, or 11 described in the above embodiment can be used as the circuits FC[1] to FC[n]. That is, the circuits FC[1] to FC[n] in FIG. 21 can perform an arithmetic operation of any one of the identity function shown in FIG. 5, the Leaky ReLU function shown in FIG. 10, and the Hard Tanh function shown in FIG. 12. Note that each of the circuits FC[1] to FC[n] in FIG. 21 includes the terminals T1p, T1m, T0p, and T0m illustrated in FIGS. 4, 7, 8, and 11.

In the j-th column of the cell array CA1, the wiring WLp[j] is connected to a first terminal of the switch Wp[j], and the wiring WLm[j] is connected to a first terminal of the switch Wm[j]. A second terminal of the switch Wp[j] is connected to the terminal T1p of the circuit FC[j] and a non-inverting input terminal of the comparator OP[j], and a second terminal of the switch Wm[j] is connected to the terminal T1m of the circuit FC[j] and an inverting input terminal of the comparator OP[j]. A first terminal of the switch Wa[j] is connected to the terminals T0p and T0m of the circuit FC[j]. An output terminal of the comparator OP[j] is connected to an input terminal of the inverter IV[j] and a first terminal of the switch Wrp[j], and an output terminal of the inverter IV[j] is connected to a first terminal of the switch Wrm[j].

A second terminal of the switch Wa[j] is connected to the wiring XL[j] extending to the cell array CA2. A second terminal of the switch Wrp[ ] is connected to the wiring PLp[ ] extending to the cell array CA2. A second terminal of the switch Wrm[j] is connected to the wiring PLm[j] extending to the cell array CA2.

As each of the switches included in the driver circuit AD1, an electrical switch can be used, for example. As the electrical switch, a transistor can be used, for example. In particular, an analog switch combining a plurality of transistors is preferably used as the electrical switch. Note that other than the electrical switch, a mechanical switch may be used as each of the switches included in the driver circuit AD1, for example.

The comparator OP[j] has a function of comparing potentials of the inverting and non-inverting input terminals and outputting the comparison result from the output terminal as a potential. Note that the comparator OP[j] may have a function of comparing currents flowing through the inverting and non-inverting input terminals and outputting the comparison result from the output terminal as a potential. In order that the circuit FC[j] can generate a differential current between currents flowing through the terminals T1p and T1m, it is preferable that no current be input to and output from the inverting and non-inverting input terminals of the comparator OP[j]. Therefore, each of the inverting and non-inverting input terminals of the comparator OP[j] is preferably in a high impedance state.

The inverter IV[j] has a function of obtaining a potential input to the input terminal as a signal and outputting a signal with the inverted logic of the signal from the output terminal. Specifically, the inverter IV[j] outputs a low-level potential from the output terminal when a high-level potential is input to the input terminal, and outputs a high-level potential from the output terminal when a low-level potential is input to the input terminal. Since the input terminal of the inverter IV[j] is connected to the output terminal of the comparator OP[j], the inverter IV[j] outputs a signal with the inverted logic of the comparison result of the comparator OP[j] from the output terminal.

When the driver circuit AD1 obtains currents flowing through the wirings WLp[j] and WLm[j] in the j-th column of the cell array CA1, the switches Wp[j] and Wm[j] are turned on. Accordingly, electrical continuity is established between the wiring WLp[j] and the terminal T1p of the circuit FC[j], so that the circuit FC[j] can obtain the total current flowing through the wiring WLp[j](e.g., I_{SP} illustrated in FIG. 4, 7, 8, or 11). In addition, electrical continuity is established between the wiring WLm[j] and the terminal T1m of the circuit FC[j], so that the circuit FC[j] can obtain the total current flowing through the wiring WLm[j](e.g., I_{SM} illustrated in FIG. 4, 7, 8, or 11). Thus, the circuit FC[j] can obtain a differential current (e.g., I_{DP} or I_{DM} illustrated in FIG. 7, 8, or 11) of the total current flowing through the wiring WLp[j] and the total current flowing through the wiring WLm[j], and can make a current corresponding to the result of the arithmetic operation of the function shown in FIG. 5, 10, or 12 (e.g., I_{OP} or I_{OM} illustrated in FIG. 4, 7, 8, or 11) flow between the terminal T0p or T0m and the wiring XL[j] extending to the cell array CA2 through the switch Wa[j].

As described in Embodiment 1, in the case where the result of the arithmetic operation of the function is a positive value, a current flows through the terminal T0p of the circuit FC[j] and a current does not flow through the terminal T0m of the circuit FC[j]. In the case where the result of the arithmetic operation of the function is a negative value, a current does not flow through the terminal T0p of the circuit FC[j] and a current flows through the terminal T0m of the circuit FC[j]. In the case where the result of the arithmetic operation of the function is 0, a current does not flow through the terminal T0p or T0m of the circuit FC[j]. That is, a current does not flow through one or both of the terminals T0p and T0m of the circuit FC[j]. In addition, since the terminals T0p and T0m are connected to each other, a current based on the absolute value of the result of the arithmetic operation of the function performed in the circuit FC[j] flows through the wiring XL[j] extending to the cell array CA2.

When the switches Wp[j] and Wm[j] are turned on in the j-th column of the cell array CA1, the comparator OP[j] obtains potentials at the terminals T1p and T1m through the non-inverting and inverting input terminals, respectively. At this time, the potential levels at the terminals T1p and T1m depend on which of the total current I_{SP} flowing through the wiring WLp[j] and the total current I_{SM} flowing through the wiring WLm[j] is larger.

Specifically, when I_{SP} is larger than I_{SM}, the result of the arithmetic operation of the function shown in FIG. 5, 10, or 12 is a positive value in the circuit FC[j]. Since I_{SP} is larger than I_{SM}, the potential of the terminal T1p is higher than that of the terminal T1m, and the comparator OP[j] outputs a high-level potential from the output terminal, for example. The inverter IV[j] receives the high-level potential at the input terminal, and outputs a low-level potential from the output terminal. Accordingly, the high-level potential from the output terminal of the comparator OP[j] is supplied to the wiring PLp[j] extending to the cell array CA2 through the switch Wrp[j], and the low-level potential from the output terminal of the inverter IV[j] is supplied to the wiring PLm[j] extending to the cell array CA2 through the switch Wrm[j]. That is, when the result of the arithmetic operation of the function in the circuit FC[j] is a positive value, the comparator OP[j] supplies a high-level potential to the wiring PLp[j] extending to the cell array CA2 and the inverter IV[j] supplies a low-level potential to the wiring PLm[j] extending to the cell array CA2, as signals corresponding to the sign (positive) of the result of the arithmetic operation of the function.

When I_{SM} is larger than I_{SP}, the result of the arithmetic operation of the function shown in FIG. 5, 10, or 12 is a negative value in the circuit FC[j]. Since I_{SM} is larger than I_{SP}, the potential of the terminal T1m is higher than that of the terminal T1p, and the comparator OP[j] outputs a low-level potential from the output terminal, for example. The inverter IV[j] receives the low-level potential at the input terminal, and outputs a high-level potential from the output terminal. Thus, the low-level potential from the output terminal of the comparator OP[j] is supplied to the wiring PLp[j] extending to the cell array CA2 through the switch Wrp[j], and the high-level potential from the output terminal of the inverter IV[j] is supplied to the wiring PLm[j] extending to the cell array CA2 through the switch Wrm[j]. That is, when the result of the arithmetic operation of the function in the circuit FC[j] is a negative value, the comparator OP[j] supplies a low-level potential to the wiring PLp[j] extending to the cell array CA2 and the inverter IV[j] supplies a high-level potential to the wiring PLm[j] extending to the cell array CA2, as signals corresponding to the sign (negative) of the result of the arithmetic operation of the function.

As described above, the driver circuit AD1 can substitute the result of the product-sum operation performed in the cell array CA1 into any one of the functions shown in FIGS. 5, 10, and 12 as a variable, and output the result of the arithmetic operation of the function as new second data. Specifically, the driver circuit AD1 can supply a current based on the absolute value of the second data to the wiring XL[j] extending to the cell array CA2, and supply a potential corresponding to the sign of the second data to the wirings PLp[j] and PLm[j] extending to the cell array CA2 as a signal.

Like the driver circuit WD1, the driver circuit WD2 has a function of obtaining the first data from the outside, converting the first data into a signal (e.g., a current signal or a voltage signal) to be written to the arithmetic circuit CC of the cell array CA2, and transmitting the signal to the wirings WLp and WLm. Specifically, for example, the driver circuit WD2 obtains the first data w[j,k](here, w[j,k] is a real number) from the outside, and transmits the first data w[j,k] to the wirings WLp[k] and WLm[k] so that the first data w[j,k] is held in the arithmetic cells IMp and IMm included in the arithmetic circuit CC[j,k]. Here, the first data w[j,k] corresponds to a weight coefficient between a neuron in the first intermediate layer and a neuron in the second intermediate layer in the artificial neural network.

Like the driver circuit SD1, the driver circuit SD2 has a function of, for example, transmitting a selection signal to the wiring SL[j], in order to supply the selection signal to the arithmetic circuits CC[j,1] to CC[j,u] arranged in the j-th row of the cell array CA2 when the first data w[j,1] to w[j,u] are written to the arithmetic circuits CC[j,1] to CC[j,u] in the j-th row of the cell array CA2. In addition, the driver circuit SD2 has a function of transmitting a non-selection signal to the wirings SL[1] to SL[n] other than the wiring SL[j], in order to supply the non-selection signal to the arithmetic circuits CC[i,1] to CC[j,u] arranged in the rows other than the j-th row of the cell array CA2 when the first data w[j,1] to w[j,u] are written to the arithmetic circuits CC[j,1] to CC[j,u] in the j-th row of the cell array CA2. Note that while the second arithmetic portion CP2 of the arithmetic device DV1 performs a product-sum operation, the first data is written to none of the arithmetic circuits CC[1,1] to CC[n,u], and thus the driver circuit SD2 transmits a non-selection signal to all of the wirings SL[1] to SL[n].

While the first data is written to each of the arithmetic circuits CC of the cell array CA2, the arithmetic operation result in the first arithmetic portion CP1 is transmitted from the driver circuit AD1 to the arithmetic circuit CC of the cell array CA2 as the second data, whereby the product-sum operation of the first and second data is performed in the cell array CA2 of the second arithmetic portion CP2, as in the cell array CA1 of the first arithmetic portion CP1.

Like the driver circuit AD1, the driver circuit AD2 has a function of, for example, obtaining total currents flowing through the wirings WLp[j] and WLm[j], performing an arithmetic operation of a function where the differential current is substituted as a variable, and transmitting a signal corresponding to the arithmetic operation result to a layer (an intermediate layer or an output layer) subsequent to the second intermediate layer. Through the above operation of the driver circuit AD2, an arithmetic operation of an activation function for neurons of the second intermediate layer in the artificial neural network is performed, and the result of the arithmetic operation can be obtained. In the case where any one of the identity function, the Leaky ReLU function, and the Hard Tanh function shown in FIGS. 5, 10, and 12 is used as the activation function, the driver circuit AD2 can have a circuit structure similar to that of the driver circuit AD1.

### Structure Example 2 of Arithmetic Device

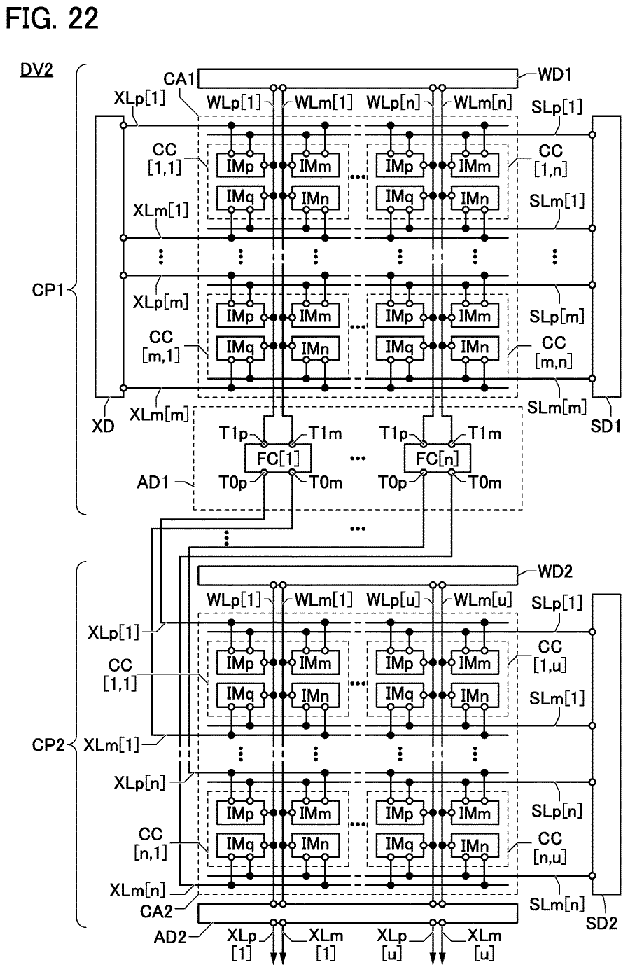

The structure of the arithmetic device of one embodiment of the present invention is not limited to that of the arithmetic device DV1 illustrated in FIG. 21. The arithmetic device of one embodiment of the present invention can have a structure of an arithmetic device DV2 illustrated in FIG. 22 whose structure is changed from that of the arithmetic device DV1 in FIG. 21.

The arithmetic device DV2 illustrated in FIG. 22 is different from the arithmetic device DV1 in FIG. 21 in that the number of arithmetic cells included in the arithmetic circuit CC is not two but four in each of the cell arrays CA1 and CA2. The arithmetic device DV2 illustrated in FIG. 22 is different from the arithmetic device DV1 in FIG. 21 also in that, in each of the cell arrays CA1 and CA2, wirings XLp and XLm extend in the row direction instead of the wiring XL, wirings SLp and SLm extend in the row direction instead of the wiring SL, and the wirings PLp and PLm are not provided.

Furthermore, the arithmetic device DV2 does not include the wiring PLp or PLm in each of the cell arrays CA1 and CA2, and thus is different from the arithmetic device DV1 also in the circuit structure of the driver circuit AD1. Although a specific circuit structure is not illustrated, the driver circuit AD2 of the arithmetic device DV2 may also be different from that of the arithmetic device DV1.

The arithmetic circuit CC provided in the cell arrays CA1 and CA2 each include the arithmetic cell IMp, the arithmetic cell IMm, an arithmetic cell IMq, and an arithmetic cell IMn, for example. Specifically, in the arithmetic circuit CC in FIG. 22, the arithmetic cells IMp, IMm, IMq, and IMn are illustrated on the upper left side, the upper right side, the lower left side, and the lower right side, respectively.

In each of the cell arrays CA1 and CA2, a plurality of wirings XLp, a plurality of wirings XLm, a plurality of wirings SLp, and a plurality of wirings SLm extend in the rows. In each of the cell arrays CA1 and CA2, a plurality of wirings WLp and a plurality of wirings WLm extend in the columns.

Specifically, in the cell array CA1, wirings XLp[1] to XLp[m] extend as the plurality of wirings XLp; wirings XLm[1] to XLm[m] extend as the plurality of wirings XLm; wirings SLp[1] to SLp[m] extend as the plurality of wirings SLp; wirings SLm[1] to SLm[m] extend as the plurality of wirings SLm; wirings WLp[1] to WLp[n] extend as the plurality of wirings WLp; and wirings WLm[1] to WLm[n] extend as the plurality of wirings WLm, for example. In the cell array CA2, wirings XLp[1] to XLp[n] extend as the plurality of wirings XLp; wirings XLm[1] to XLm[n] extend as the plurality of wirings XLm; wirings SLp[1] to SLp[n] extend as the plurality of wirings SLp; wirings SLm[1] to SLm[n] extend as the plurality of wirings SLm; wirings WLp[1] to WLp[u] extend as the plurality of wirings WLp; and wirings WLm[1] to WLm[u] extend as the plurality of wirings WLm, for example.

In the cell array CA1, the driver circuit XD is connected to the wirings XLp[1] to XLp[m] and the wirings XLm[1] to XLm[m]. The driver circuit SD1 is connected to the wirings SLp[1] to SLp[m] and the wirings SLm[1] to SLm[m].

In the cell array CA1, the wirings WLp[1] to WLp[n] and the wirings WLm[1] to WLm[n] are connected to the driver circuits WD1 and AD1, as in the arithmetic device DV1 in FIG. 21. The driver circuit AD1 is connected to the wirings XLp[1] to XLp[n] and the wirings XLm[1] to XLm[n] extending to the cell array CA2.

In the cell array CA2, the driver circuit SD2 is connected to the wirings SLp[1] to SLp[n] and the wirings SLm[1] to SLm[n].

In the cell array CA2, the wirings WLp[1] to WLp[u] and the wirings WLm[1] to WLm[u] are connected to the driver circuits WD2 and AD2, as in the arithmetic device DV1 in FIG. 21. In the example illustrated in FIG. 22, the driver circuit AD2 is connected to the wirings XLp[1] to XLp[u] and the wirings XLm[1] to XLm[u] for transmitting a signal to a layer (an intermediate layer or an output layer) subsequent to the second intermediate layer.

The arithmetic circuit CC provided in the cell arrays CA1 and CA2 has a function of holding the first data corresponding to signals transmitted from the wirings WLp and WLm and a function of multiplying the held first data by the second data corresponding to signals transmitted from the wirings XLp and XLm, for example.

The driver circuit WD1 has a function of transmitting the first data w[i,j] obtained from the outside to each of the arithmetic cells IMp, IMm, IMq, and IMn included in the arithmetic circuit CC[i,j] of the cell array CA1. These arithmetic cells each have a function of holding a value corresponding to the first data w[i,j].

The first data w[i,j] held in the arithmetic circuit CC[i,j] is expressed using two variables wp[i,j] and wm[i,j] as in the arithmetic device DV1. Note that wp[i,j] is held in the arithmetic cells IMp and IMn, and wm[i,j] is held in the arithmetic cells IMm and IMq.

The driver circuit XD in FIG. 22 has a function of, for example, obtaining the second data from the outside, converting the second data into a signal to be transmitted to the arithmetic circuit CC of the cell array CA1, and transmitting the signal to the wirings XLp and XLm. Specifically, for example, the driver circuit XD obtains the second data x[i](here, x[i] is a real number) from the outside, and transmits the second data x[i] to the arithmetic cells IMp, IMm, IMq, and IMn included in the arithmetic circuit CC[i,j].

The second data x[i]transmitted to the arithmetic circuit CC[i,j] is expressed using two variables xp[i] and xm[i]. For example, when the second data x[i] is a number greater than 0, the second data x[i] can be expressed as xp[i]=x[i] and xm[i]=0. For example, when the second data x[i] is a number less than 0, the second data x[i] can be expressed as xp[i]=0 and xm[i]=−x[i]. For example, when the second data is 0, the second data can be expressed as xp[i]=0 and xm[i]=0. Therefore, from the above, x[i] can be expressed as x[i]=xp[i]−xm[i]. Note that the driver circuit XD transmits xp[i] to the wiring XLp[i], and transmits xm[i] to the wiring XLm[i].

When xp[i] and xm[i] are transmitted respectively from the wirings XLp[i] and XLm[i] to the arithmetic circuit CC[i,j] holding wp[i,j] and wm[i,j], multiplication is performed in each arithmetic cell included in the arithmetic circuit CC[i,j]. Specifically, multiplication of wp[i,j] by xp[i] is performed in the arithmetic cell IMp, multiplication of wm[i,j] by xp[i] is performed in the arithmetic cell IMm, multiplication of wm[i,j] by xm[i] is performed in the arithmetic cell IMq, and multiplication of wp[i,j] by xm[i] is performed in the arithmetic cell IMn. The results of the multiplication w[i,j]×x[i] performed in the arithmetic cells are shown in the table below. Note that the table below categorizes the results based on whether w[i,j] is positive, negative, or zero and whether x[i] is positive, negative, or zero.

TABLE 2

| | w [i, j] > 0 | w[i, j] = 0 | w[i, j] < 0 |
|---|---|---|---|
| x[i] > 0 | IMp: wp × xp | IMp: 0 | IMp: 0 |
| | IMm: 0 | IMm: 0 | IMm: wm × xp |
| | IMq: 0 | IMq: 0 | IMq: 0 |
| | IMn: 0 | IMn: 0 | IMn: 0 |
| x[i] = 0 | IMp: 0 | IMp: 0 | IMp: 0 |
| | IMm: 0 | IMm: 0 | IMm: 0 |
| | IMq: 0 | IMq: 0 | IMq: 0 |
| | IMn: 0 | IMn: 0 | IMn: 0 |
| x[i] < 0 | IMp: 0 | IMp: 0 | IMp: 0 |
| | IMm: 0 | IMm: 0 | IMm: 0 |
| | IMq: 0 | IMq: 0 | IMq: wm × xm |
| | IMn: wp × xm | IMn: 0 | IMn: 0 |

According to the above table, when the result of the multiplication w[i,j]×x[i] performed in the arithmetic circuit CC[i,j] is a positive value, a current corresponding to the value of wp×xp (=w[i,j]×x[i]) flows between the arithmetic cell IMp and the wiring WLp, or a current corresponding to the value of wm×xm (=w[i,j]×x[i]) flows between the arithmetic cell IMq and the wiring WLp. Similarly, when the result of the multiplication w[i,j]×x[i,j] performed in the arithmetic circuit CC[i,j] is a negative value, a current corresponding to the value of wm×xp (=−w[i,j]×x[i]) flows between the arithmetic cell IMm and the wiring WLm, or a current corresponding to the value of wp×xm (=−w[i,j]×x[i]) flows between the arithmetic cell IMn and the wiring WLm. When the result of the multiplication w[i,j]×x[i,j] performed in the arithmetic circuit CC[i,j] is 0, a current does not flow between the arithmetic cell IMp and the wiring WLp, between the arithmetic cell IMq and the wiring WLp, between the arithmetic cell IMm and the wiring WLp, or between the arithmetic cell IMn and the wiring WLm.

In the case of the above operation, in the j-th column of the cell array CA1, a total current corresponding to the sum of wp×xp and wm×xm output respectively from the m arithmetic cells IMp and the m arithmetic cells IMq arranged in the j-th column flows through the wiring WLp[j]. Similarly, a total current corresponding to the sum of wm×xp and wp×xm output respectively from the m arithmetic cells IMm and the m arithmetic cells IMn arranged in the j-th column flows through the wiring WLm[j].

Furthermore, the total current flowing through the wiring WLp[j] is the sum of the positive values obtained by w[i,j]×x[i], and the total current flowing through the wiring WLm[j] is the sum of the negative values obtained by w[i,j]×x[i]; thus, the result of the product-sum operation of the first data w[1,j] to w[m,j] and the second data x[1] to x[m] can be obtained by obtaining the differential current between the total current flowing through the wiring WLp[j] and the total current flowing through the wiring WLm[j].

The driver circuit AD1 illustrated in FIG. 22 has a function of, for example, obtaining currents flowing through the wirings WLp[j] and WLm[j], performing an arithmetic operation of a function where the differential current is substituted as a variable, and transmitting a signal corresponding to the arithmetic operation result to the wirings XLp[j] and XLm[j] extending to the cell array CA2.

The driver circuit AD1 illustrated in FIG. 22 includes the circuits FC[1] to FC[n], for example. For the circuits FC[1] to FC[n], the description of the circuits FC[1] to FC[n] included in the driver circuit AD1 of the arithmetic device DV1 can be referred to.

In the j-th column of the cell array CA1, the wiring WLp[j] is connected to the terminal T1p of the circuit FC[j], and the wiring WLm[j] is connected to the terminal Tim of the circuit FC[j]. The terminal T0p of the circuit FC[j] is connected to the wiring XLp[j] extending to the cell array CA2, and the terminal T0m of the circuit FC[j] is connected to the wiring XLm[j] extending to the cell array CA2.

Unlike the driver circuit AD1 of the arithmetic device DV1, the driver circuit AD1 of the arithmetic device DV2 is not provided with the switches Wp[1] to Wp[n], the switches Wm[1] to Wm[n], the switches Wrp[1] to Wrp[n], the switches Wrm[1] to Wrm[n], or the switches Wa[1] to Wa[n]. In the driver circuit AD1 of the arithmetic device DV2, the switches included in the circuits FCp and FCm of the circuit FC, for example, can serve as alternatives to the switches Wp[1] to Wp[n], the switches Wm[1] to Wm[n], and the switches Wa[1] to Wa[n]. Specifically, in the case where the circuits FCp and FCm have the circuit structure of the circuit FCa in FIG. 1A, the switches W1, W2, and W3 included in each of the circuits FCp and FCm can serve as alternatives to the switches Wp, Wm, and Wa, respectively.

When the driver circuit AD1 obtains currents flowing through the wirings WLp[j] and WLm[j] in the j-th column of the cell array CA1, electrical continuity is established between the wiring WLp[j] and the terminal T1p of the circuit FC[j] and between the wiring WLm[j] and the terminal T1m of the circuit FC[j]. Thus, the circuit FC[j] can obtain the total current flowing through the wiring WLp[j](e.g., I_{SP} illustrated in FIG. 4, 7, 8, or 11) and the total current flowing through the wiring WLm[j](e.g., I_{SM} illustrated in FIG. 4, 7, 8, or 11). Accordingly, the circuit FC[j] can obtain a differential current (e.g., I_{DP} Or I_{DM} illustrated in FIG. 7, 8, or 11) of the total current flowing through the wiring WLp[j] and the total current flowing through the wiring WLm[j], and can make a current corresponding to the result of the arithmetic operation of the function shown in FIG. 5, 10, or 12 (e.g., I_{OP} or I_{OM} illustrated in FIG. 4, 7, 8, or 11) flow between the terminal T0p and the wiring XLp[U]extending to the cell array CA2 and between the terminal T0m and the wiring XLm[j] extending to the cell array CA2.

As described in Embodiment 1, when the result of the arithmetic operation of the function shown in FIG. 5, 10, or 12 is a positive value, a current in an amount corresponding to the positive value flows through the terminal T0p of the circuit FC[j], and a current does not flow through the terminal T0m of the circuit FC[j]. When the result of the arithmetic operation of the function shown in FIG. 5, 10, or 12 is a negative value, a current does not flow through the terminal T0p of the circuit FC[j], and a current in an amount corresponding to the negative value flows through the terminal T0m of the circuit FC[j]. When the result of the arithmetic operation of the function shown in FIG. 5, 10, or 12 is 0, a current does not flow through the terminal T0p or T0m of the circuit FC[j].

That is, currents flowing through the terminals T0p and T0m of the circuit FC[j] can be transmitted to the cell array CA2 of the second arithmetic portion CP2 as the second data transmitted from the first intermediate layer to the second intermediate layer in the artificial neural network.

For the driver circuits WD2, SD2, and AD2, the above description of the driver circuits WD1, SD1, and AD1 can be referred to. Thus, the product-sum operation in the cell array CA2 can be performed in a manner similar to that in the cell array CA1 described above.

As described above, a product-sum operation and an arithmetic operation of a function can also be performed in the arithmetic device DV2 as in the arithmetic device DV1. The driver circuit AD1 of the arithmetic device DV2 does not include an inverter or a comparator like the driver circuit AD1 of the arithmetic device DV1, and thus can have a smaller area than the driver circuit AD1 of the arithmetic device DV1. The arithmetic device DV2 does not include an inverter or a comparator in the driver circuit AD1, and thus can have low power consumption.

With the use of the arithmetic device DV1 illustrated in FIG. 21 or the arithmetic device DV2 illustrated in FIG. 22, an arithmetic operation of an artificial neural network using any one of the identity function, the Leaky ReLU function, and the Hard Tanh function shown in FIGS. 5, 10, and 12 as an activation function can be performed. Accordingly, a vanishing gradient problem in the artificial neural network can be solved in some cases.

### Structure Example 3 of Arithmetic Device

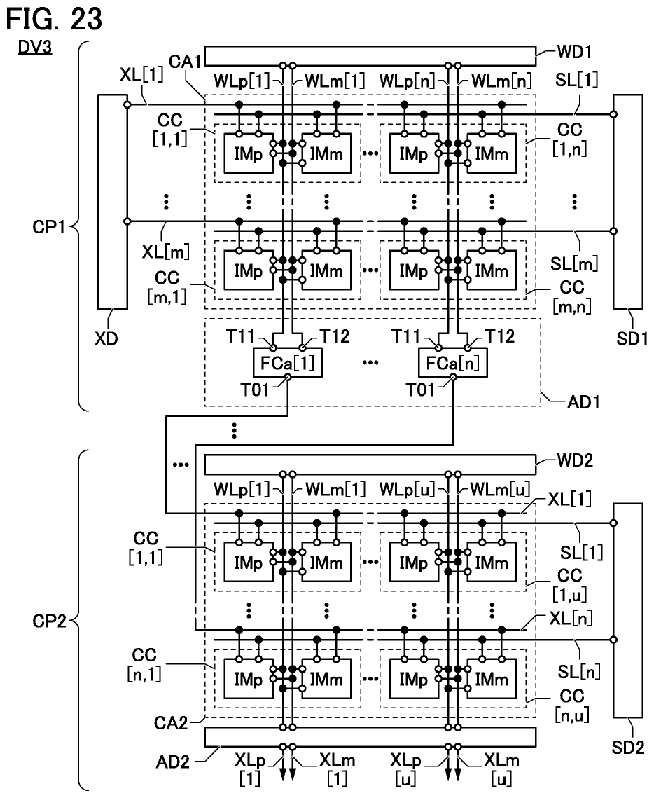

An arithmetic device DV3 illustrated in FIG. 23 is different from the arithmetic devices DV1 and DV2 described above, and can perform an arithmetic operation of an artificial neural network using a ReLU function as an activation function with the circuit FCa in FIG. 1A described in Embodiment 1.

Like the arithmetic device DV1 in FIG. 21, the arithmetic device DV3 includes the driver circuits WD1, XD, SD1, AD1, WD2, SD2, and AD2. For the driver circuits WD1, SD1, WD2, and SD2 of the arithmetic device DV3, the description of the driver circuits WD1, SD1, WD2, and SD2 of the arithmetic device DV1 in FIG. 21 can be referred to.

Like the arithmetic device DV1 in FIG. 21, the arithmetic device DV3 includes the cell arrays CA1 and CA2 where a plurality of arithmetic circuits CC each including two arithmetic cells are arranged.

In the cell array CA1 of the arithmetic device DV3, as in the arithmetic device DV1 in FIG. 21, the wirings WLp and WLm connected to the driver circuits WD1 and AD1 extend in the column direction, the wiring XL connected to the driver circuit XD extends in the row direction, and the wiring SL connected to the driver circuit SD1 extends in the row direction. In the cell array CA2 of the arithmetic device DV3, as in the arithmetic device DV1 in FIG. 21, the wirings WLp and WLm connected to the driver circuits WD2 and AD2 extend in the column direction, the wiring XL connected to the driver circuit AD1 extends in the row direction, and the wiring SL connected to the driver circuit SD2 extends in the row direction.

Thus, the arithmetic cells IMp and IMm provided in the cell arrays CA1 and CA2 in the arithmetic device DV3 are each connected to the wirings WLp, WLm, XL, and SL, as in the arithmetic device DV1.

Like the driver circuit XD provided in the arithmetic device DV1 in FIG. 21, the driver circuit XD of the arithmetic device DV3 has a function of obtaining the second data from the outside, converting the second data into a signal to be transmitted to the arithmetic circuit CC, and transmitting the signal to the wiring XL[i]. Note that the second data is not a negative value but a positive value or 0. Thus, unlike in the arithmetic device DV1, the wirings PLp and PLm for transmitting the sign of the second data as a signal are not provided in the cell array CA1 or CA2 of the arithmetic device DV3.

The driver circuit AD1 of the arithmetic device DV3 includes a circuit FCa[1] to a circuit FCa[n], as each of which the circuit FCa in FIG. 1A is used, for example. Like the circuit FCa in FIG. 1A, the circuits FCa[1] to FCa[n] each include the terminals T11 and T12 functioning as the input terminals and the terminal T01 functioning as the output terminal.

In the j-th column of the cell array CA1, the wiring WLp[j] is connected to the terminal T11 of the circuit FCa[j], and the wiring WLm[j] is connected to the terminal T12 of the circuit FCa[j]. The terminal T13 of the circuit FCa[j] is connected to the wiring XL[j] extending to the cell array CA2.

In the j-th column of the cell array CA1 of the arithmetic device DV3, the circuit FCa[j] can hold a value corresponding to the total current flowing through the wiring WLp[j](e.g., I_{SP} illustrated in FIG. 1A), as described in Embodiment 1. When the total current flowing through the wiring WLm[j](e.g., I_{SM} illustrated in FIG. 1A) is obtained, a differential current (e.g., I_{OP} illustrated in FIG. 1A) between the total current flowing through the wiring WLp[j] and the total current flowing through the wiring WLm[j] can flow through the terminal T01 of the circuit FCa[j]. Note that as described in Embodiment 1, when the amount of the total current flowing through the wiring WLm[j] is larger than or equal to that of the total current flowing through the wiring WLp[j], a current does not flow through the terminal T01 of the circuit FCa[j].

As described above, the driver circuit AD1 can substitute the result of the product-sum operation performed in the cell array CA1 into the ReLu function shown in FIG. 2 as a variable, and output the result of the arithmetic operation of the function as new second data. Specifically, the driver circuit AD1 supplies a current corresponding to the second data to the wiring XL[j] extending to the cell array CA2, which enables an arithmetic operation between the first and second intermediate layers in the artificial neural network.

Note that this embodiment can be combined with the same embodiment or any of the other embodiments in this specification as appropriate. For example, the configurations, structures, methods, and the like described in this embodiment can be used in an appropriate combination with any of the other configurations, the other structures, the other methods, and the like described in this embodiment. Alternatively, for example, the configurations, structures, methods, and the like described in this embodiment can be used in an appropriate combination with any of the configurations, structures, methods, and the like described in the other embodiments and the like.

### Embodiment 3

In this embodiment, examples of a schematic plan view and a cross-sectional structure of the semiconductor device described in the above embodiments are described.

### Layout Example of Semiconductor Device

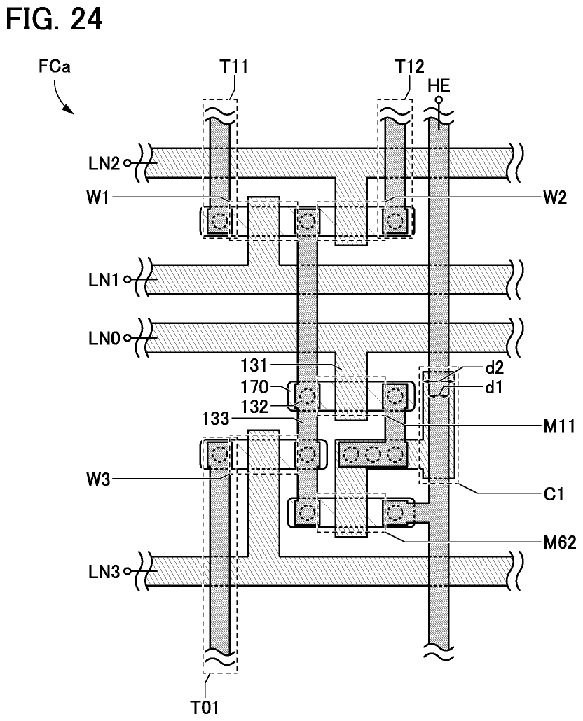

FIG. 24 is a schematic plan view illustrating an example of a circuit structure of the circuit FCa, which is the semiconductor device described in the above embodiments.

Specifically, the schematic plan view in FIG. 24 illustrates an example of a circuit layer including the circuit FCa illustrated in FIG. 1A. In FIG. 24, the switches W1 to W3 in FIG. 1A are illustrated as transistors that are electrical switches.

The circuit layer includes a conductive layer 131, a conductive layer 132, a conductive layer 133, and a region 170 that also serves as part of the transistor. Note that for clarification of the schematic plan view, FIG. 24 does not illustrate an insulating layer included in the circuit layer.

Each of the transistors illustrated in FIG. 24 includes a substrate, the region 170 including a low-resistance region and a semiconductor region formed in the substrate, the conductive layer 132 formed over the low-resistance region and the conductive layer 131 described later, a gate insulating film formed in the semiconductor region, the conductive layer 131 formed over the gate insulating film, and the conductive layer 133 formed above the conductive layer 131 and the conductive layer 132.

For example, the region 170 is positioned below the conductive layers 131 and 132, and the conductive layer 133 is positioned above the conductive layers 131 and 132. Note that the region 170, the conductive layer 131, the conductive layer 132, and the conductive layer 133 can be formed in this order.

In the schematic plan view in FIG. 24, the region 170 in contact with the conductive layer 132 is a low-resistance region and has a function of a source or a drain of the transistor, for example. The conductive layer 132 has a function of a wiring for connection to a wiring or the like positioned above the conductive layer 132. Thus, the conductive layer 132 is referred to as a contact plug in some cases.

Part of the conductive layer 131 positioned above the region 170 has a function of a gate of the transistor, for example. The region 170 overlapping with the conductive layer 131 is the semiconductor region of the transistor.

In the schematic plan view in FIG. 24, part of the conductive layer 133 has a function of a wiring or a terminal. For example, the conductive layer 133 is provided to include a region extending as the wiring HE. In addition, the conductive layer 133 is provided to include regions serving as the terminals T11 to T13. The conductive layer 131 is provided to include regions extending as the wirings LN0 to LN3. Thus, each of the conductive layers 131 and 133 is preferably formed using a material having high conductivity.

Each of the above conductive layers can be formed by a lithography method, for example. Specifically, for example, in the case where the conductive layer 132 is formed, a conductive material to be the conductive layer 132 is deposited by one or more methods selected from a sputtering method, a chemical vapor deposition (CVD) method, a pulsed laser deposition (PLD) method, and an atomic layer deposition (ALD) method, and then a desired pattern can be formed by a photolithography method. The conductive layers other than the conductive layer 132, the semiconductor layer, and the insulating layer can also be formed by a method similar to the above.

In this specification and the like, examples of the lithography method include a photolithography method, an ion beam lithography method, an X-ray lithography method, an electron lithography method, a multiphoton lithography method, an interference lithography method, and a nanoimprinting method.

The capacitor C1 illustrated in FIG. 24 has a parallel-plate-type structure. The capacitor C1 can be provided in a region where the wiring HE extends. Thus, a region of the capacitor C1 can be easily ensured, whereby the area of the circuit FCa can be reduced.

In FIG. 24, a width d1 of the conductive layer 133 including one of a pair of electrodes of the capacitor C1 is smaller than a width d2 of the conductive layer 131 including the other of the pair of electrodes of the capacitor C1. When an insulating layer functioning as a dielectric is formed over the conductive layer 131, defective formation of the insulating layer might occur at the edge or its periphery of the conductive layer 131. Specifically, the coverage with the insulating layer formed at the edge or its periphery of the conductive layer 131 might be low; thus, in the case where the width d1 is larger than the width d2, the edge or its periphery of the conductive layer 131 and the region of the conductive layer 133 overlapping with the edge or its periphery of the conductive layer 131 are sometimes in contact with each other to be short-circuited. Therefore, the width d1 is preferably smaller than the width d2.

By contrast, in the case where the coverage with the insulating layer formed at the edge or its periphery of the conductive layer 131 can be improved, the width d1 is preferably larger than the width d2. Specifically, since the capacitance value of the capacitor is proportional to the area of a region where the one of the pair of electrodes, the dielectric, and the other of the pair of electrodes overlap with each other, the area of the region is preferably increased to achieve a higher capacitance. When the width d1 is larger than the width d2, the width of the region can be increased from d1 to d2. In this case, the conductive layer 133 is formed above the edge of the conductive layer 131; thus, the area of the one of the pair of electrodes of the capacitor C1 is increased and the capacitance value of the capacitor C1 can be increased.

Since the second terminals of the switches W1 and W2 are connected to each other in FIG. 1A, the switches can be formed to share the region 170 as illustrated in FIG. 24. This can reduce the formation area of the circuit FCa, resulting in downsizing of an arithmetic device including the circuit FCa (e.g., the arithmetic device DV1 in FIG. 21, the arithmetic device DV2 in FIG. 22, or the arithmetic device DV3 in FIG. 23).

Note that the schematic plan view of the semiconductor device of one embodiment of the present invention is not limited to that in FIG. 24. The schematic plan view of the semiconductor device of one embodiment of the present invention can be changed from that in FIG. 24 as appropriate depending on circumstances.

### Cross-Sectional Structure Example of Semiconductor Device

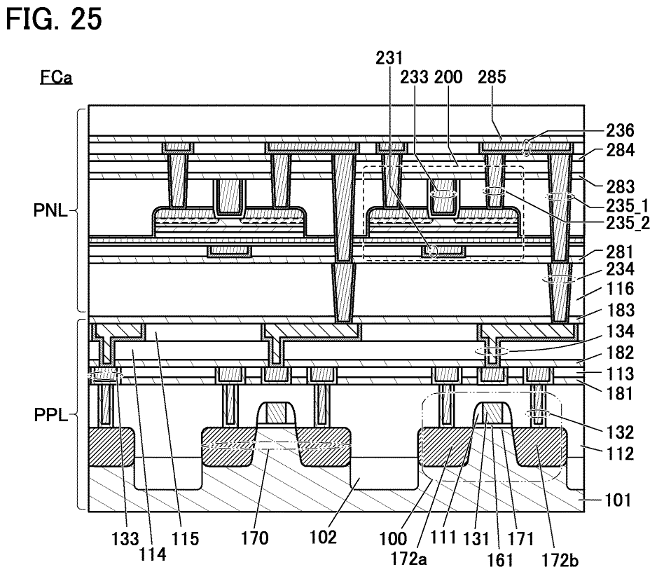

FIG. 25 is a schematic cross-sectional view illustrating a structure example of the circuit FCa described in the above embodiments. Unlike in the schematic plan view in FIG. 24, the circuit FCa includes a circuit layer PPL and a circuit layer PNL positioned above the circuit layer PPL in FIG. 25, for example. The schematic cross-sectional view in FIG. 25 illustrates an example where a transistor 100 is included in the circuit layer PPL and a transistor 200 is included in the circuit layer PNL.

The circuit layer PPL can be formed by providing a circuit element such as a transistor or a capacitor over a substrate, for example. As the substrate, a semiconductor substrate (e.g., a single crystal substrate formed of silicon or germanium) can be used. Besides such a semiconductor substrate, for example, any of the following can be used: a silicon on insulator (SOI) substrate, a glass substrate, a quartz substrate, a plastic substrate, a sapphire glass substrate, a metal substrate, a stainless steel substrate, a substrate including stainless steel foil, a tungsten substrate, a substrate including tungsten foil, a flexible substrate, an attachment film, and paper and a base film each including a fibrous material. Note that the substrate included in the circuit layer PPL is described as a semiconductor substrate containing silicon in this embodiment.

When a semiconductor substrate containing silicon as a material is used as the substrate included in the circuit layer PPL, the transistors included in the circuit FCa described in Embodiment 1 can be formed on the semiconductor substrate. In that case, the transistors are Si transistors. The Si transistor has high field-effect mobility and thus can make a large amount of on-state current flow. Accordingly, the driving speed of each of the above-listed driver circuits can be increased, and the range of a signal can be expanded, for example.

FIG. 25 illustrates the transistor 100 included in the circuit layer PPL as an example of the Si transistor. When the transistor 100 is a Si transistor, a CMOS circuit including a p-channel transistor and an n-channel transistor can be formed in the circuit layer PPL.

The stacked-layer structure of the circuit layers PPL and PNL can be formed by directly forming the circuit layer PNL over the circuit layer PPL as illustrated in FIG. 25. Alternatively, the stacked-layer structure can be formed in the following manner: the circuit layer PNL is formed by providing a circuit element such as a transistor or a capacitor over a substrate, and the substrate is mounted over the circuit layer PPL. Note that in the case where the circuit layer PNL is directly formed over the circuit layer PPL, the circuit layer PNL preferably includes an OS transistor as the transistor 200. An IO transistor can be used as the OS transistor. The OS transistor can be formed over a substrate such as a semiconductor substrate, an insulator substrate, or a conductor substrate or over a film such as a conductive film, an insulating film, or a semiconductor film, and thus can be easily provided over a semiconductor substrate where a Si transistor is formed (over the circuit layer PPL).

Alternatively, a p-channel transistor may be provided as a Si transistor in the circuit layer PPL, and an n-channel transistor may be provided as an OS transistor in the circuit layer PNL. Specifically, for example, in the circuit FCa illustrated in FIG. 1A, the transistor M62 can be provided in the circuit layer PPL, and the transistor M11 and the transistors serving as the switches W1 to W3 can be provided in the circuit layer PNL. Thus, the circuit FCa can be a CMOS circuit in which a p-channel transistor and an n-channel transistor are stacked. It can be said that an OS transistor having an extremely low off-state current is suitably used as each of the transistors serving as the switches W1 to W3.

In a CMOS circuit using silicon transistors, both p-type and n-type wells need to be formed in the silicon wafer to form p-type and n-type transistors separately. This causes problems such as a complexity of the manufacturing process, limitation in transistor placement that reduces circuit design flexibility, and difficulty in high integration. Meanwhile, the semiconductor device illustrated in FIG. 25 can use only a p-channel transistor as the silicon transistor (the transistor 100), and thus can be manufactured through a simplified process. Furthermore, the p-channel transistor and the n-channel transistor can be stacked, which not only increases circuit design flexibility but also facilitates higher integration.

In the case where the circuit layer PNL is formed by providing a circuit element such as a transistor or a capacitor over a substrate and the substrate is mounted over the circuit layer PPL, a flip-chip bonding method or a wire bonding method can be used. Alternatively, the circuit layer PNL may be mounted over the circuit layer PPL in the following manner: a first bonding layer is provided on the circuit layer PPL side, a second bonding layer is provided on the substrate of the circuit layer PNL, and the first and second bonding layers are bonded to each other by surface activated bonding and/or hydrophilic bonding. In particular, bonding achieved by using copper (Cu) as a conductor included in each of the first and second bonding layers and (directly) bonding copper of the first and second bonding layers is referred to as Cu—Cu (copper-copper) direct bonding.

The transistor 100 is provided over a substrate 101 and includes the conductive layer 131 functioning as a gate, an insulating layer 161 and an insulating layer 111 functioning as gate insulating films, and the region 170 including part of the substrate 101. Note that the region 170 includes a semiconductor region 171 including part of the substrate and low-resistance regions 172a and 172b functioning as source and drain regions.

The semiconductor region 171, the low-resistance region 172a, and the low-resistance region 172b illustrated in FIG. 25 are formed by providing an element isolation layer 102 in the substrate 101. It can be said that the element isolation layer 102 is provided to separate a plurality of transistors on the substrate 101 from each other. The element isolation layer 102 can be formed by a local oxidation of silicon (LOCOS) method, a shallow trench isolation (STI) method, or a mesa isolation method.

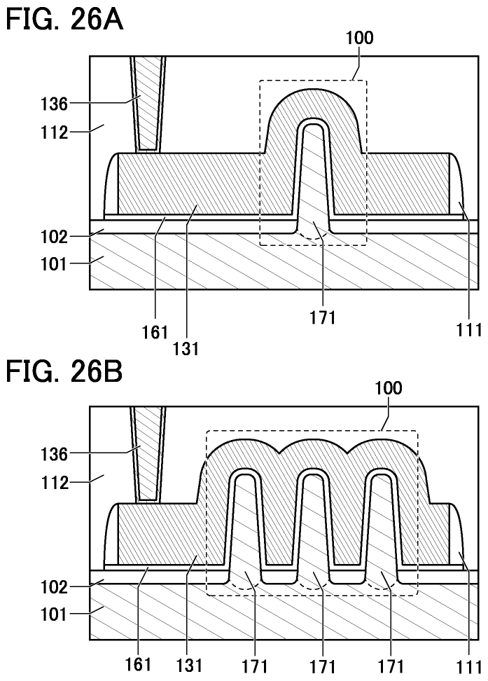

In the transistor 100 illustrated in FIG. 25, the semiconductor region 171 (part of the substrate 101) where a channel is formed can have a projecting shape as illustrated in a schematic cross-sectional view in FIG. 26A. Note that FIG. 26A is a schematic cross-sectional view of the transistor 100 in the channel width direction. The conductive layer 131 is provided to cover the side and top surfaces of the semiconductor region 171 with the insulating layer 161 therebetween. Note that the conductive layer 131 may be formed using a material for adjusting the work function. The transistor 100 is also referred to as a fin-type transistor because it utilizes a projecting portion of the semiconductor substrate. Note that an insulating layer serving as a mask for forming the projecting portion may be provided in contact with the top of the projecting portion. Although the case where the projecting portion is formed by processing part of the semiconductor substrate is described here, a semiconductor film having a projecting shape may be formed by processing an SOI substrate.

In FIG. 26A, a conductive layer 136 is provided to be in contact with the top surface of the conductive layer 131 and fill an opening formed in an insulating layer 112. Note that the conductive layer 136 functions as a contact plug or a wiring.

As the transistor 100 includes a larger number of projecting semiconductor regions 171, the transistor 100 can have a higher-on state current. The number of projecting semiconductor regions 171 is not limited and can be one or more in accordance with required characteristics. For example, as illustrated in a schematic cross-sectional view in FIG. 26B, the transistor 100 may include a plurality of projecting semiconductor regions 171. Furthermore, the transistors 100 including different numbers of projecting semiconductor regions 171 can be provided in the semiconductor circuit.

Note that the transistor 100 illustrated in FIGS. 25, 26A, and 26B is just an example and is not limited to having the structure illustrated therein; an appropriate transistor is used in accordance with a circuit structure or a driving method.

Wiring layers including an interlayer film, a wiring, and a plug may be provided in the circuit FC. A plurality of wiring layers can be provided in accordance with the design. In this specification and the like, a wiring and a plug connected to the wiring may be a single component. That is, part of a conductive layer functions as a wiring in some cases and part of a conductive layer functions as a plug in other cases.

For example, the insulating layer 112, an insulating layer 181, and an insulating layer 113 are stacked over the transistor 100 in this order as interlayer films. The conductive layer 132 and the like are embedded in the insulating layer 112. The conductive layer 133 and the like are embedded in the insulating layers 181 and 113. Note that the conductive layers 132 and 133 function as contact plugs or wirings. Thus, it can be said that one of the source and the drain of the transistor 100 is connected to the conductive layers 132 and 133.

The insulating layer functioning as an interlayer film may function as a planarization film that covers a roughness thereunder. For example, the top surface of the insulating layer 112 may be planarized by planarization treatment using a chemical mechanical polishing (CMP) method or the like to improve the planarity.

A wiring layer may be provided over the insulating layer 113 and the conductive layer 133. For example, in FIG. 25, an insulating layer 182, an insulating layer 114, an insulating layer 115, an insulating layer 183, and an insulating layer 116 are stacked in this order over the insulating layer 113 and the conductive layer 133. In addition, a conductive layer 134 is formed in the insulating layers 182, 114, and 115. The conductive layer 134 functions as a contact plug or a wiring. That is, the conductive layer 133 is in direct contact with the conductive layer 134 functioning as a contact plug or a wiring.

An opening portion is provided in the insulating layers 183 and 116, and a conductive layer 234 is embedded in the opening portion. The opening portion is provided in a region overlapping with the conductive layer 134. The conductive layer 234 functions as a contact plug or a wiring. Thus, it can be said that the conductive layer 134 is in direct contact with the conductive layer 234 functioning as a contact plug or a wiring.

An insulating layer 281 is provided over the insulating layer 116 and the conductive layer 234. In the insulating layer 281, a conductive layer 235_1 is embedded as a contact plug or a wiring for connection to an upper circuit (e.g., a circuit element of a circuit included in the circuit layer PNL).

Next, a structure example of the transistor 200 included in the circuit layer PNL illustrated in FIG. 25 is described.

In the circuit layer PNL in FIG. 25, the transistor 200 is formed over the insulating layer 281, for example. The insulating layer 281 is positioned above the circuit layer PPL. In the circuit layer PNL, an insulating layer 283, an insulating layer 284, and an insulating layer 285 are positioned above the insulating layer 281.

Note that each of the insulating layers 181 to 183 and the insulating layers 281 to 285 illustrated in FIG. 25 preferably functions as a barrier insulating film that inhibits passage of impurities such as water and hydrogen. Thus, the insulating layers 181 to 183 and the insulating layers 281 to 285 are preferably formed using an insulating material having a function of inhibiting diffusion of impurities such as a hydrogen atom, a hydrogen molecule, a water molecule, a nitrogen atom, a nitrogen molecule, a nitrogen oxide molecule (e.g., N₂O, NO, or NO₂), and a copper atom (an insulating material through which the impurities are less likely to pass). Alternatively, it is preferable to use an insulating material having a function of inhibiting diffusion of oxygen (e.g., one or both of an oxygen atom and an oxygen molecule) (an insulating material through which the oxygen is less likely to pass). For the materials that can be used for the insulating layers 181 to 183 and the insulating layers 281 to 285, the description of the insulating layer included in the transistor can be referred to.

One of a source and a drain of the transistor 200 is connected to a conductive layer 236 formed over the insulating layer 284 through a conductive layer 235_2 functioning as a contact plug. In the circuit layer PNL, the conductive layer 235_1 is embedded in a position overlapping with the conductive layer 234. Thus, the conductive layer 235_1 is in contact with the top surface of the conductive layer 234. The conductive layer 236 is connected to the conductive layer 234 through the conductive layer 235_1. Although not illustrated in FIG. 25, the conductive layer 133 connected to the conductive layer 134 may be connected to the conductive layer 131, for example. That is, the gate of the transistor 100 may be connected to one of the source and the drain of the transistor 200 in FIG. 25.

The gate electrode of the transistor 200 extends in the depth direction of FIG. 25 as a conductive layer 233 serving as a wiring, for example.

Note that as illustrated in FIG. 25, the transistor 200 may be provided with a conductive layer 231 functioning as a back gate below its island-shaped semiconductor layer. By providing a back gate for the transistor and changing the potential of the back gate, the threshold voltage of the transistor can be changed. For example, when including a back gate, the transistor 200 is less affected by an external electric field and can keep its an off state stably. Thus, providing the back gate can stabilize the operation of the transistor 200.

Note that in the case where a back gate is provided for the transistor, no conductive layer is preferably provided around the back gate in order to avoid formation of parasitic capacitance with the back gate.

The transistor 200 is preferably a transistor using an oxide semiconductor, which is one type of metal oxide, in a semiconductor layer where a channel is formed (also referred to as OS transistor). An oxide semiconductor has a band gap of 2 eV or more, achieving an extremely low off-state current. Thus, the transistor 200 can be used not only in the circuit FC but also in the arithmetic cell IMp, the arithmetic cell IMm, or the like described in Embodiment 2 as a holding transistor. In this case, the holding transistor can have a low off-state current, enabling a smaller number of refresh operations and accordingly reducing power consumption of the arithmetic device DV1 or DV2.

In addition, the OS transistor operates stably even in a high-temperature environment and has small fluctuation in characteristics. For example, the off-state current hardly increases even in a high-temperature environment. Specifically, the off-state current hardly increases even at an environment temperature higher than or equal to room temperature (e.g., 25 °C) and lower than or equal to 200 °C. In addition, the on-state current is less likely to decrease even in a high-temperature environment. When the OS transistor is used as a holding transistor that can be included in the arithmetic cell IMp, the arithmetic cell IMm, or the like described in Embodiment 2, the arithmetic cell can operate stably even in a high-temperature environment and thus can have high reliability.

In particular, when the above oxide semiconductor is indium oxide, that is, the transistor 200 is an IO transistor, a low off-state current and a high on-state current can be achieved. Accordingly, the circuit FC, the arithmetic device DV1, the arithmetic device DV2, or the arithmetic device DV3 having both high reliability and high operation speed can be obtained in some cases.

### Structure Example of Transistor

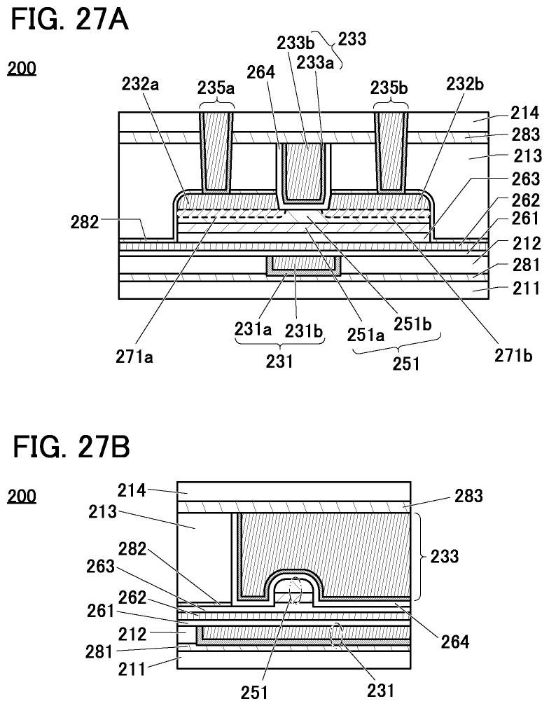

Next, a specific structure example of a transistor having a gate last (GL) structure (also referred to as a trench gate self align or top gate self align (TGSA) structure), which can be used as the transistor 200 illustrated in FIG. 25, is described. The transistor 200 illustrated in FIGS. 27A and 27B is an example of a transistor having the GL structure.

FIG. 27A is a schematic cross-sectional view of the transistor 200 in the channel length direction, and FIG. 27B is a schematic cross-sectional view of the transistor 200 in the channel width direction.

As illustrated in FIGS. 27A and 27B, the transistor 200 includes a semiconductor layer 251a, a semiconductor layer 251b, the conductive layer 231, a conductive layer 232a, a conductive layer 232b, the conductive layer 233, an insulating layer 261 to an insulating layer 264, the insulating layer 281 to the insulating layer 283, and an insulating layer 212 to an insulating layer 214, for example. Note that the transistor 200 does not include all the above components in some cases. For example, the transistor 200 does not necessarily include the conductive layer 231 having a function of the back gate electrode.

The conductive layer 231 (a conductive layer 231a and a conductive layer 231b) and the insulating layer 212 are placed above a substrate (not illustrated). The conductive layer 231 is preferably provided to be embedded in the insulating layer 212. Specifically, the conductive layer 231a is preferably provided in contact with the bottom surface and the sidewall of an opening portion provided in the insulating layer 212. The conductive layer 231b is preferably provided to be embedded in a depressed portion formed by the conductive layer 231a. In the transistor 200 illustrated in FIGS. 27A and 27B, the top surface of the conductive layer 231b is substantially level with the top surfaces of the conductive layer 231a and the insulating layer 212.

Like the insulating layer 112, the insulating layer 212 has a function of a planarization film for eliminating a level difference made by a plug or the like, for example. Thus, the insulating layer 212 can be formed using a material similar to that for the insulating layer 112.

When a material with a low dielectric constant is used for the insulating layer 212, parasitic capacitance between wirings can be reduced. For example, silicon oxide, silicon oxynitride, silicon nitride oxide, or silicon nitride can be used for the insulating layer 212. Alternatively, for example, silicon oxide to which fluorine is added, silicon oxide to which carbon is added, silicon oxide to which carbon and nitrogen are added, or porous silicon oxide can be used for the insulating layer 212. Silicon oxide and silicon oxynitride are particularly preferable because of their thermal stability. In particular, a material such as silicon oxide, silicon oxynitride, or porous silicon oxide is preferably used, in which case a region containing oxygen released by heating can be easily formed. Alternatively, a photosensitive resin can be used for the insulating layer 212, for example. A material combined with any of the above insulating materials as appropriate may be used for the insulating layer 212.

Note that in this specification, oxynitride refers to a material that contains more oxygen than nitrogen, and nitride oxide refers to a material that contains more nitrogen than oxygen. For example, silicon oxynitride refers to a material that contains more oxygen than nitrogen, and silicon nitride oxide refers to a material that contains more nitrogen than oxygen.

A semiconductor layer 251 and the conductive layer 233 are provided in a region overlapping with the conductive layer 231. The semiconductor layer 251b is provided over the semiconductor layer 251a. The conductive layers 232a and 232b are provided over the semiconductor layer 251b to be apart from each other. The insulating layer 213 is provided over the conductive layers 232a and 232b. An opening portion is formed in a region of the insulating layer 213 between the conductive layers 232a and 232b. The conductive layer 233 is provided in the opening portion. The insulating layer 264 is provided between the conductive layer 233 and each of the semiconductor layer 251b, the conductive layer 232a, the conductive layer 232b, and the insulating layer 213. Here, as illustrated in FIGS. 27A and 27B, the top surface of the conductive layer 233 is preferably substantially level with the top surfaces of the insulating layers 264 and 213. Hereinafter, the conductive layers 231a and 231b are collectively referred to as the conductive layer 231 in some cases. The semiconductor layers 251a and 251b are collectively referred to as the semiconductor layer 251 in some cases. The conductive layers 232a and 232b are collectively referred to as a conductive layer 232 in some cases.

In addition, as illustrated in FIG. 27A, a region 271a is sometimes formed as a low-resistance region at and near the interface between the semiconductor layer 251b and the conductive layer 232a. Similarly, a region 271b is sometimes formed as a low-resistance region at and near the interface between the semiconductor layer 251b and the conductive layer 232b. In that case, the region 271a functions as one of a source region and a drain region, and the region 271b functions as the other of the source region and the drain region. The channel formation region is formed in a region interposed between the regions 271a and 271b.

For the channel formation region of the semiconductor layer 251, a metal oxide functioning as an oxide semiconductor is preferably used. In particular, indium oxide described in Embodiment 3 is suitable as the metal oxide. Note that a variety of metal oxides other than indium oxide to be the channel formation region of the transistor 200 are described below.

For example, as the metal oxide to be the channel formation region of the transistor 200, it is preferable to use a metal oxide having a band gap of 2 eV or more, preferably 2.5 eV or more. Specifically, for example, in the transistor 200 in FIGS. 27A and 27B, a metal oxide functioning as an oxide semiconductor is preferably used for the semiconductor layer 251.

Structures of metal oxides are classified into a single crystal structure and other structures (non-single-crystal structures). Examples of non-single-crystal structures include a c-axis aligned crystalline (CAAC) structure, a polycrystalline structure, a nanocrystalline (nc) structure, an amorphous-like (a-like) structure, and an amorphous structure. There is no particular limitation on the structure of the metal oxide of one embodiment of the present invention, and any of the above structures can be employed. Note that a crystalline metal oxide typified by a CAAC metal oxide and an nc metal oxide is preferably used to obtain a highly reliable semiconductor device.

The metal oxide preferably contains at least indium. Indium and zinc may be contained. In addition to them, an element M may be contained. Note that the element M can be one or more selected from aluminum, gallium, silicon, yttrium, tin, copper, vanadium, chromium, manganese, beryllium, boron, titanium, iron, nickel, germanium, zirconium, molybdenum, lanthanum, cerium, neodymium, hafnium, tantalum, tungsten, magnesium, calcium, strontium, barium, cobalt, and antimony. In particular, the element M can be one or more of aluminum, gallium, yttrium, and tin. Furthermore, the element M preferably contains one or both of gallium and tin.

As the above metal oxide, it is possible to use indium oxide (also referred to as an indium oxide or IO), a gallium oxide (also referred to as gallium oxide), a zinc oxide (also referred to as zinc oxide), an indium zinc oxide (an In—Zn oxide), an indium tin oxide, an indium titanium oxide, an indium gallium oxide (an In—Ga oxide), an indium gallium aluminum oxide, an indium gallium tin oxide, a gallium zinc oxide, an aluminum zinc oxide, an indium tin zinc oxide, an indium titanium zinc oxide, an indium gallium zinc oxide (also referred to as an In—Ga—Zn oxide or IGZO), an indium gallium tin zinc oxide, an indium gallium aluminum zinc oxide, or the like. Alternatively, it is possible to use an indium tin oxide containing silicon, a gallium tin oxide, an aluminum tin oxide, or the like.

As described above, the metal oxide preferably contains indium, in particular. Specifically, indium oxide is suitably used as the metal oxide. In particular, crystalline indium oxide is suitably used.

A sputtering method or an ALD method can be suitably used for formation of the metal oxide. A sputtering method enables formation of a metal oxide film having high crystallinity or high film density. An ALD method, in which one atomic layer can be deposited, enables formation of a metal oxide film having few defects such as pinholes, formation of a metal oxide film having high coverage, and formation of a metal oxide film at low temperatures, for example. After the formation of a metal oxide film, impurity removal treatment is preferably performed to remove an impurity (which is typically water, hydrogen, carbon, or nitrogen here) from the metal oxide film. Examples of the impurity removal treatment include plasma treatment and heat treatment. An example of the plasma treatment is microwave plasma treatment.

In this specification, a microwave refers to an electromagnetic wave having a frequency greater than or equal to 300 MHz and less than or equal to 300 GHz. Microwave plasma treatment refers to, for example, treatment using an apparatus including a power source for generating high-density plasma using microwaves. Microwave plasma treatment can also be referred to as microwave-excited high-density plasma treatment.

In the transistor 200, two layers of the semiconductor layers 251a and 251b are stacked in and around the region where a channel is formed (hereinafter also referred to as a channel formation region); however, the present invention is not limited thereto. For example, a single-layer structure of the semiconductor layer 251b or a stacked-layer structure of three or more layers may be employed. Moreover, each of the semiconductor layers 251a and 251b may have a stacked-layer structure of two or more layers.

The conductive layer 233 functions as a first gate electrode (sometimes referred to as a top gate electrode or a front gate electrode) of the transistor, and as described above, the conductive layers 232a and 232b each function as a source electrode or a drain electrode. As described above, the conductive layer 233 is formed to be embedded in the opening of the insulating layer 213 and the region between the conductive layers 232a and 232b. Here, the conductive layers 233, 232a, and 232b are formed in a self-aligned manner with respect to the opening of the insulating layer 213. In other words, in the transistor 200, the first gate electrode can be positioned between the source electrode and the drain electrode in a self-aligned manner. Thus, the conductive layer 233 can be formed without an alignment margin, resulting in a reduction in the area occupied by the transistor 200. Accordingly, the density of arithmetic cells in an arithmetic device can be increased.

In FIGS. 27A and 27B, the conductive layer 233 has a two-layer structure. Here, the conductive layer 233 preferably includes a conductive layer 233a and a conductive layer 233b placed over the conductive layer 233a. For example, the conductive layer 233a is preferably placed to cover the bottom and side surfaces of the conductive layer 233b. In that case, a conductive material that is not easily oxidized or a conductive material having a function of inhibiting diffusion of oxygen is preferably used for the conductive layer 233a.

The conductive layer 233a is preferably formed using a conductive material having a function of inhibiting diffusion of impurities such as a hydrogen atom, a hydrogen molecule, a water molecule, a nitrogen atom, a nitrogen molecule, a nitrogen oxide molecules, and a copper atom. Alternatively, the conductive layer 233a is preferably formed using a conductive material having a function of inhibiting diffusion of oxygen. When the conductive layer 233a has a function of inhibiting diffusion of oxygen, the conductivity of the conductive layer 233b can be inhibited from being lowered because of oxidization of the conductive layer 233b due to oxygen in the insulating layer 213 and the like. As the conductive material having a function of inhibiting diffusion of oxygen, for example, titanium, titanium nitride, tantalum, tantalum nitride, ruthenium, or ruthenium oxide is preferably used.

A conductive layer having high conductivity is preferably used as the conductive layer 233b. For example, a conductive material containing tungsten, copper, or aluminum as its main component can be used for the conductive layer 233b. The conductive layer 233b may have a stacked-layer structure, for example, a stacked-layer structure of titanium or titanium nitride and the above conductive material.

Thus, the conductive layers 232a and 232b are preferably formed using a conductive material that is not easily oxidized or a conductive material having a function of inhibiting diffusion of oxygen. Examples of the conductive material include a conductive material containing nitrogen and a conductive material containing oxygen. The use of such a conductive material can inhibit a reduction in the conductivity of the conductive layers 232a and 232b. When formed using a conductive material containing a metal and nitrogen, the conductive layers 232a and 232b contain at least the metal and nitrogen. As the material used for the conductive layers 232a and 232b, a conductive material that is not easily oxidized or a conductive material having a function of inhibiting diffusion of oxygen can be selected from the above-described materials that can be used for the conductive layers 233a and 233b, for example.

A conductive layer 235a and a conductive layer 235b (sometimes collectively referred to as a conductive layer 235) illustrated in FIG. 27A correspond to the conductive layer 2352 illustrated in FIG. 25. The conductive layers 235a and 235b can be formed using a conductive material containing tungsten, copper, or aluminum as its main component. The conductive layers 235a and 235b can each have a stacked-layer structure including a plurality of layers. In the stacked-layer structure, a conductive material having a function of inhibiting passage of impurities such as water and hydrogen and a material having high conductivity are preferably stacked.

The conductive layer 231 functions as a second gate electrode (sometimes referred to as a bottom gate electrode or a second gate electrode) in some cases. In that case, by changing a potential applied to the conductive layer 231 independently of a potential applied to the conductive layer 233, the threshold voltage Vₜₕ of the transistor 200 can be controlled. In particular, by applying a negative potential to the conductive layer 231, Vₜₕ of the transistor 200 can be increased and the off-state current can be reduced. Thus, the drain current at the time when a potential applied to the conductive layer 233 is 0 V can be lower in the case where a negative potential is applied to the conductive layer 231 than in the case where the negative potential is not applied to the conductive layer 231.

The conductive layer 231 is preferably larger than the channel formation region in the semiconductor layer 251. In particular, it is preferable that the conductive layer 231 extend as a wiring beyond an end portion of the semiconductor layer 251 that intersects with the channel width direction, as illustrated in FIG. 27B. That is, the conductive layers 231 and 233 preferably overlap with each other with the insulating layer therebetween, in a region beyond the side surface of the semiconductor layer 251 in the channel width direction.

As illustrated in FIG. 27A, the conductive layer 233 preferably includes the conductive layer 233a provided on the inner side of the insulating layer 264 and the conductive layer 233b provided to be embedded on the inner side of the conductive layer 233a. Although the conductive layer 233 has a two-layer structure in FIGS. 27A and 27B, the present invention is not limited to this. For example, the conductive layer 233 may have a single-layer structure or a stacked-layer structure of three or more layers.

For the conductive layers 231 and 233, any one selected from the above-described materials that can be used for the conductive layers 235a and 235b can be used, for example.

As illustrated in FIGS. 27A and 27B, the transistor 200 preferably includes an insulating layer 211 placed over a substrate (not illustrated), the insulating layer 281 placed over the insulating layer 211, the insulating layer 212 placed over the insulating layer 281, the conductive layer 231 placed to be embedded in the insulating layer 212, the insulating layer 261 placed over the insulating layer 212 and the conductive layer 231, an insulating layer 262 placed over the insulating layer 261, and an insulating layer 263 placed over the insulating layer 262. The semiconductor layer 251a is preferably placed over the insulating layer 263.

As illustrated in FIGS. 27A and 27B, an insulating layer 282 is preferably placed between the insulating layer 213 and each of the insulating layer 262, the insulating layer 263, the semiconductor layer 251a, the semiconductor layer 251b, the conductive layer 232a, and the conductive layer 232b. Here, as illustrated in FIGS. 27A and 27B, the insulating layer 282 is preferably in contact with the side surface of the insulating layer 264, the top and side surfaces of the conductive layer 232a, the top and side surfaces of the conductive layer 232b, the top and side surfaces of the semiconductor layer 251a, the semiconductor layer 251b, and the insulating layer 263, and the top surface of the insulating layer 262.

Note that the insulating layer 264 has a function of a first gate insulating film of the transistor 200. The insulating layers 261 to 263 have a function of a second gate insulating film. For these insulating films, silicon oxide, silicon oxynitride, silicon nitride oxide, silicon nitride, silicon oxide to which fluorine is added, silicon oxide to which carbon is added, silicon oxide to which carbon and nitrogen are added, or porous silicon oxide can be used, for example. Other than the above, a single-layer structure or a stacked-layer structure of an insulating layer containing what is called a high-k material, such as aluminum oxide, hafnium oxide, tantalum oxide, zirconium oxide, lead zirconate titanate (PZT), strontium titanate (SrTiO₃), or (Ba,Sr)TiO₃(BST) can be used, for example. Alternatively, aluminum oxide, bismuth oxide, germanium oxide, niobium oxide, silicon oxide, titanium oxide, tungsten oxide, yttrium oxide, or zirconium oxide may be added to the above material for the insulating layer, for example. Alternatively, these insulators may be subjected to nitriding treatment.

The insulating layers 283 and 214 functioning as interlayer films are preferably placed over the transistor 200. Here, the insulating layer 283 is preferably placed in contact with the top surfaces of the conductive layer 233, the insulating layer 264, and the insulating layer 213. In that case, the top surface of the insulating layer 213 is preferably planarized.

The conductive layer 235 (the conductive layers 235a and 235b) connected to the transistor 200 and functioning as a plug is preferably provided. Thus, the conductive layer 235 is provided in contact with the inner wall of an opening in the insulating layers 282, 213, 283, and 214. In particular, a structure may be employed where a first conductive layer of the conductive layer 235 is provided in contact with the inner wall and a second conductive layer of the conductive layer 235 is provided on the side surface of the first conductive layer. Here, the top surface of the conductive layer 235 and the top surface of the insulating layer 214 can be roughly level with each other.

Specifically, for example, a first conductive layer of the conductive layer 235a is provided in contact with the inner wall of one of two openings in the insulating layers 214, 283, 213, and 282, and a second conductive layer of the conductive layer 235a is formed in contact with the side surface of the first conductive layer. Note that the conductive layer 232a is positioned on part of the bottom portion of the opening, and the conductive layer 235a is in contact with the conductive layer 232a. Similarly, for example, a first conductive layer of the conductive layer 235b is provided in contact with the inner wall of the other of the two openings in the insulating layers 214, 283, 213, and 282, and a second conductive layer of the conductive layer 235b is formed in contact with the side surface of the first conductive layer. Note that the conductive layer 232b is positioned on part of the bottom portion of the opening, and the conductive layer 235b is in contact with the conductive layer 232b.

Although the conductive layer 235 has a stacked-layer structure of the first and second conductive layers in the transistor 200, the present invention is not limited thereto. For example, the conductive layer 235 may have a single-layer structure or a stacked-layer structure of three or more layers.

As illustrated in FIG. 27B, the side surface of the semiconductor layer 251 is covered with the conductive layer 233 in a region of the semiconductor layer 251b not overlapping with the conductive layer 232, i.e., the channel formation region of the semiconductor layer 251. This facilitates application of an electric field of the conductive layer 233 having a function of the first gate electrode to the side surface of the semiconductor layer 251, and consequently, the channel formation region of the semiconductor layer 251 can be electrically surrounded by the electric field of the conductive layer 233. Hence, the transistor 200 can have a higher on-state current and higher frequency characteristics.

The dielectric constant of the insulating layer 213 is preferably lower than that of the insulating layer 262, for example. In the case where a material with a low dielectric constant is used for an interlayer film, parasitic capacitance generated between wirings can be reduced. Thus, the insulating layer 213 can be formed using a material with a low dielectric constant that can be used for the insulating layer 212.

The transistor of the semiconductor device of one embodiment of the present invention does not necessarily have the GL structure illustrated in FIGS. 27A and 27B. For example, the transistor may have a structure where the source and drain electrodes are positioned at different heights and a current flowing in the semiconductor layer flows in the height direction (also referred to as a vertical-channel transistor, a vertical field effect transistor (VFET), a vertical transistor, a vertical-channel-type transistor, or the like). Since the source and drain electrodes are positioned at different heights, the channel length direction can be regarded as including a height-direction (vertical-direction) component.

In a vertical-channel transistor, a current flowing in a semiconductor layer flows in the height direction; thus, the formation area of the transistor can be smaller than that of a transistor having the GL structure in a plan view. In other words, when a vertical-channel transistor is used as the transistor included in the semiconductor device, the circuit area of the semiconductor device can be reduced.

Note that this embodiment can be combined with the same embodiment or any of the other embodiments in this specification as appropriate. For example, the configurations, structures, methods, and the like described in this embodiment can be used in an appropriate combination with any of the other configurations, the other structures, the other methods, and the like described in this embodiment. Alternatively, for example, the configurations, structures, methods, and the like described in this embodiment can be used in an appropriate combination with any of the configurations, structures, methods, and the like described in the other embodiments and the like.

### Embodiment 4

In this embodiment, an indium oxide film that can be used for the semiconductor layer of the transistor included in the semiconductor device of one embodiment of the present invention will be described.

In this specification and the like, indium oxide including at least a crystal part or a crystal region in a film is referred to as crystal IO or crystalline IO. Examples of crystal IO or crystalline IO include single crystal indium oxide, polycrystal indium oxide, and microcrystal indium oxide.

Indium oxide is a semiconductor material having physical properties completely different from those of an oxide semiconductor such as an In—Ga—Zn oxide (hereinafter, also referred to as IGZO) or zinc oxide.

The dependence of the Hall mobility on the carrier concentration of indium oxide, silicon, and IGZO will be described.

IGZO has a tendency in which the Hall mobility is higher as the carrier concentration is higher. By contrast, single crystal indium oxide has a tendency in which the Hall mobility is higher as the carrier concentration is lower. This tendency is similar to that of silicon; as the concentration of a dopant (impurity) in a material is lower, impurity scattering is inhibited more and thus the Hall mobility is higher. That is, single crystal indium oxide having higher purity and being more intrinsic has higher Hall mobility. Consequently, the physical properties of single crystal indium oxide are different from those of IGZO and similar to those of silicon. Note that the tendency of non-single-crystal (e.g., polycrystal) indium oxide is sometimes different from that of single crystal indium oxide.

A carrier concentration range suitable for a channel formation region of a transistor is a range including a value of 1×10¹⁵ cm⁻³, e.g., a range higher than or equal to 1×10¹⁴ cm⁻³ and lower than or equal to 1×10¹⁸ cm⁻³. The adequately lowered carrier concentration will increase the Hall mobility to approximately 270 cm²/(V·s).

Indium oxide can contain an element that reduces the carrier concentration. Examples of the element that reduces the carrier concentration include magnesium, calcium, zinc, cadmium, and copper. When indium is replaced with any of these elements, the carrier concentration can be reduced. Other examples include nitrogen, phosphorus, arsenic, and antimony. When oxygen is replaced with any of these elements, the carrier concentration can be reduced.

An element that reduces the carrier concentration can be regarded as an element that imparts p-type conductivity. Adding an element that reduces the carrier concentration to an indium oxide film sometimes facilitates the indium oxide film to be an i-type or substantially i-type film. In that case, the concentration of the element that reduces the carrier concentration in the indium oxide film is preferably higher than or equal to 1×10¹⁶ atoms/cm³ and lower than or equal to 8×10²⁰ atoms/cm³, further preferably higher than or equal to 1×10¹⁶ atoms/cm³ and lower than or equal to 4×10²⁰ atoms/cm³, still further preferably higher than or equal to 1×10¹⁶ atoms/cm³ and lower than or equal to 8×10¹⁹ atoms/cm³, yet still further preferably higher than or equal to 1×10¹⁶ atoms/cm³ and lower than or equal to 5×10¹⁹ atoms/cm³. With such a concentration, the carrier concentration can be reduced while the crystal structure of indium oxide is maintained.

By contrast, an increase in carrier concentration can reduce electrical resistance. A carrier concentration range suitable for a source region and a drain region of a transistor, a resistor, or a transparent conductive film is, for example, a range including a value of 1×10²⁰ cm⁻³, e.g., a range higher than or equal to 1×10¹⁹ cm⁻³ and lower than or equal to 1×10²² cm⁻³. The adequately increased carrier concentration will reduce the resistivity to 1×10⁻⁴ Ω·cm or lower.

Indium oxide can contain an element that increases the carrier concentration. For example, the same element as a source electrode and a drain electrode of a transistor is preferably contained. Examples of the element that increases the carrier concentration include titanium, zirconium, hafnium, tantalum, tungsten, molybdenum, tin, silicon, and boron. It is particularly preferable that an oxide of the element have conductivity or semiconductor properties.

An element that increases the carrier concentration can also be regarded as an element that imparts n-type conductivity. The concentration of the element that increases the carrier concentration in the indium oxide film is preferably higher than or equal to 1×10¹⁶ atoms/cm³ and lower than or equal to 8×10²⁰ atoms/cm³, further preferably higher than or equal to 1×10¹⁶ atoms/cm³ and lower than or equal to 4×10²⁰ atoms/cm³, still further preferably higher than or equal to 1×10¹⁶ atoms/cm³ and lower than or equal to 8×10¹⁹ atoms/cm³, yet still further preferably higher than or equal to 1×10¹⁶ atoms/cm³ and lower than or equal to 5×10¹⁹ atoms/cm³. With such a concentration, the carrier concentration can be increased while the crystal structure of indium oxide is maintained. Note that antimony also functions as an element that increases the carrier concentration in some cases.

Since valence electrons of indium oxide can be controlled in this manner, the threshold voltage of a transistor containing indium oxide in its semiconductor layer can be controlled. In addition, a region with a low carrier concentration and a region with a high carrier concentration can be used as a channel formation region and source and drain regions, respectively, of a transistor. Thus, what is called an n-i-n junction (a junction between an n-type region, an i-type region, and an n-type region) can be formed. Although valence electron control in a transistor using silicon is generally known, the valence electron control in a transistor containing indium oxide is a novel technical idea that cannot be conceived usually. With use of this technical idea, a transistor that has high mobility, has a low off-state current, can be normally off, and has high reliability can be achieved.

An indium oxide film preferably has crystallinity. In particular, the indium oxide film is preferably a polycrystalline film, further preferably a single crystal film. A single crystal film does not have a crystal grain boundary (also referred to as a grain boundary). The use of a single crystal film can inhibit carrier scattering or the like at the crystal grain boundary, thereby achieving a transistor having high field-effect mobility. In addition, the use of a single crystal film produces an excellent effect of reducing a variation in transistor characteristics caused by the crystal grain boundary.

A polycrystalline film is preferable because it can reduce carrier scattering as compared with a microcrystalline film or an amorphous film and enables a transistor to have high field-effect mobility. In the case of using a polycrystalline film, it is preferable to use a film that has as large a crystal grain size as possible and few crystal grain boundaries. In the case where the crystal grain boundary is neither included nor observed in a channel formation region of a transistor including a polycrystalline film, the channel formation region is positioned in a single crystal region included in the polycrystalline film and thus the transistor can be regarded as a transistor including a single crystal film.

The crystallinity of indium oxide can be analyzed with an X-ray diffraction (XRD) pattern, a transmission electron microscope (TEM) image, or an electron diffraction (ED) pattern, for example. Alternatively, two or more of these methods may be combined for the analysis.

In this specification and the like, a semiconductor layer where no crystal grain boundary is observed in a channel formation region, a semiconductor layer where a channel formation region is included in one crystal grain, or a semiconductor layer where the directions of crystal axes of at least two regions in a channel formation region are the same can be regarded as a single crystal film.

A channel formation region refers to a region of a semiconductor layer that overlaps with (or faces) a gate electrode with a gate insulating layer therebetween and is positioned between a region in contact with a source electrode and a region in contact with a drain electrode. A crystal grain, a crystal grain boundary, a crystal axis, a crystal orientation, or the like in a channel formation region can be confirmed in observation of a cross section including a semiconductor layer, a source electrode, and a drain electrode.

Impurities in the indium oxide film can function as a carrier scattering source and thus can cause a reduction in field-effect mobility and inhibit crystal growth. Examples of the impurities for the indium oxide film include boron and silicon. The concentrations of the impurities in the indium oxide film in the channel formation region are preferably as low as possible. For example, the concentrations of the impurity elements are each lower than or equal to 0.1%, preferably lower than or equal to 0.01% (100 ppm). Note that carbon, hydrogen, and the like are elements that would be contained in a film formation gas or a precursor in film formation, and the amounts of these elements remaining in the indium oxide film might be larger than those of the impurities.

The indium oxide film may contain an element that can form a trivalent cation like indium as long as the cubic crystal structure (bixbyite structure) is maintained. Examples of the element include Group 13 elements such as gallium and aluminum and Group 3 elements in the periodic table. Since these elements bond with oxygen more strongly than indium, the addition of these elements to the indium oxide film can inhibit formation of oxygen vacancies (V_{O}) in the indium oxide film. In addition, since these elements exist mainly as trivalent cations in oxides, the carrier concentration of the indium oxide film can be kept low. In this way, the threshold voltage of the transistor can be shifted in the positive direction. In addition, the transistor can be normally-off Thus, a transistor with favorable electrical characteristics can be provided.

The concentration of the above element in the indium oxide film is, for example, preferably higher than or equal to 1×10¹⁶ atoms/cm³ and lower than or equal to 8×10²⁰ atoms/cm³, further preferably higher than or equal to 1×10¹⁶ atoms/cm³ and lower than or equal to 4×10²⁰ atoms/cm³, still further preferably higher than or equal to 1×10¹⁶ atoms/cm³ and lower than or equal to 8×10¹⁹ atoms/cm³, yet still further preferably higher than or equal to 1×10¹⁶ atoms/cm³ and lower than or equal to 5×10¹⁹ atoms/cm³.

Note that the element that imparts n-type conductivity, the element that imparts p-type conductivity, and the element that can be a trivalent cation can each be added to an indium oxide film by an ion doping method, an ion implantation method, a thermal diffusion method, or the like. Alternatively, the element that imparts n-type conductivity, the element that imparts p-type conductivity, and the element that can be a trivalent cation can each be added to a sputtering target, a film formation gas, a precursor for ALD, or the like used in forming an indium oxide film. Alternatively, the element that imparts n-type conductivity, the element that imparts p-type conductivity, and the element that can be a trivalent cation can each be autodoped from a film formation chamber of the indium oxide film. Note that autodoping refers to automatic addition of an element contained in a member of the film formation chamber or the like into the indium oxide film at the time of film formation.

A transistor including the above indium oxide film can have a field-effect mobility higher than or equal to 50 cm²/(V·s), preferably higher than or equal to 100 cm²/(V·s), further preferably higher than or equal to 150 cm²/(V·s), still further preferably higher than or equal to 200 cm²/(V·s), yet still further preferably higher than or equal to 250 cm²/(V·s).

One feature of an indium oxide film is to have a higher property of transmitting (diffusing) oxygen than an IGZO film. For example, oxygen diffusing in an indium oxide film is transmitted through the indium oxide film and released as an oxygen molecule. When reacting with hydrogen contained in the film, oxygen is released as a water molecule in some cases. In the case where the film includes oxygen vacancies, the oxygen vacancies are filled with diffusing oxygen atoms. Since oxygen easily diffuses in the indium oxide film, oxygen vacancies in the indium oxide film are filled with oxygen more easily than those in an IGZO film.

As described above, the oxygen vacancies in the indium oxide film are reduced more easily than those in the IGZO film; thus, a transistor including such an indium oxide film can have extremely high reliability.

Hydrogen diffuses in the indium oxide film. Hydrogen diffusing into the indium oxide film from the outside is transmitted through the indium oxide film and is released as a hydrogen molecule. When reacting with oxygen contained in the film, hydrogen is released as a water molecule.

Indium oxide has features of a small effective mass of electrons and a large effective mass of holes. In addition, the effective mass of electrons in indium oxide hardly depends on the crystal orientation. Thus, a transistor containing indium oxide having crystallinity can have high field-effect mobility and high frequency characteristics (also referred to as f characteristics). A large effective mass of holes allows a transistor to have an extremely low off-state current. For example, the off-state current per micrometer of channel width of a transistor including an indium oxide film can be lower than or equal to 1 fA (1×10⁻¹⁵ A) or lower than or equal to 1 aA (1×10⁻¹⁸ A) at 125 °C, and can be lower than or equal to 1 aA (1×10⁻¹⁸ A) or lower than or equal to 1 zA (1×10⁻²¹ A) at room temperature (25 °C). Since indium oxide has a smaller effective mass of electrons and a larger effective mass of holes than silicon, a transistor containing indium oxide can have higher field-effect mobility and lower off-state current than a Si transistor.

A seed layer is preferably provided in contact with at least part of the indium oxide film having crystallinity. A material of the seed layer is preferably selected such that the difference in a lattice constant (also referred to as lattice mismatch) between the crystal included in indium oxide and the crystal included in the material is small. In that case, the crystallinity of the indium oxide film can be improved. As a layer in contact with at least part of the indium oxide film having crystallinity, a substrate (e.g., a single crystal substrate) may be used.

One of methods for evaluating the degree of a lattice mismatch is a method using a value of a lattice mismatch degree described below. A lattice mismatch degree Δa [%] of a crystal included in a film to be formed (here, the indium oxide film) with respect to the crystal included in the seed layer is calculated by the formula: Δa=((L₁−L₂)/L₂)×100. Here, L₁ is the lattice constant or the length of the unit lattice vector of the crystal included in the film to be formed, and L₂ is the lattice constant or the length of the unit lattice vector of the crystal included in the seed layer.

The absolute value of the lattice mismatch degree Δa between the seed layer and the indium oxide film is preferably as small as possible, most preferably 0. For example, Δa can be greater than or equal to −5% and less than or equal to 5%, preferably greater than or equal to −4% and less than or equal to 4%, further preferably greater than or equal to −3% and less than or equal to 3%, still further preferably greater than or equal to −2% and less than or equal to 2%.

An indium oxide crystal has a cubic crystal structure (a bixbyite structure). For example, an yttria-stabilized zirconia (YSZ) crystal can have a cubic crystal structure (a fluorite crystal structure). The lattice mismatch degree of an indium oxide crystal with respect to an YSZ crystal having the cubic crystal structure is within the range of −2% to 2%, which enables epitaxial growth of a single crystal film of indium oxide over the YSZ substrate.

The crystal structures of the seed layer and the indium oxide film do not necessarily have the same crystal system or crystal orientation in some cases. For example, a film including a crystal with a hexagonal crystal structure or a trigonal crystal structure can be provided below an indium oxide film including a crystal with a cubic crystal structure. For example, when the crystal orientation of a seed layer surface is set to [001] and the crystal orientation of a bottom surface of the indium oxide film is set to [111], the necessary condition for crystal orientation in epitaxial growth can be satisfied. Examples of a hexagonal or trigonal crystal structure include a wurtzite structure, a YbFe₂O₄-type structure, a Yb₂Fe₃O₇-type structure, and variations of these structures. An example of a crystal having a YbFe₂O₄-type structure or a Yb₂Fe₃O₇-type structure is IGZO.

Note that this embodiment can be combined with the same embodiment or any of the other embodiments in this specification as appropriate. For example, the configurations, structures, methods, and the like described in this embodiment can be used in an appropriate combination with any of the other configurations, the other structures, the other methods, and the like described in this embodiment. Alternatively, for example, the configurations, structures, methods, and the like described in this embodiment can be used in an appropriate combination with any of the configurations, structures, methods, and the like described in the other embodiments and the like.

### Embodiment 5

In this embodiment, examples of an electronic component that can use the semiconductor device described in the above embodiment are described. The electronic component including the semiconductor device of one embodiment of the present invention is effective in improving performance, e.g., reducing power consumption.

### [Electronic Component]

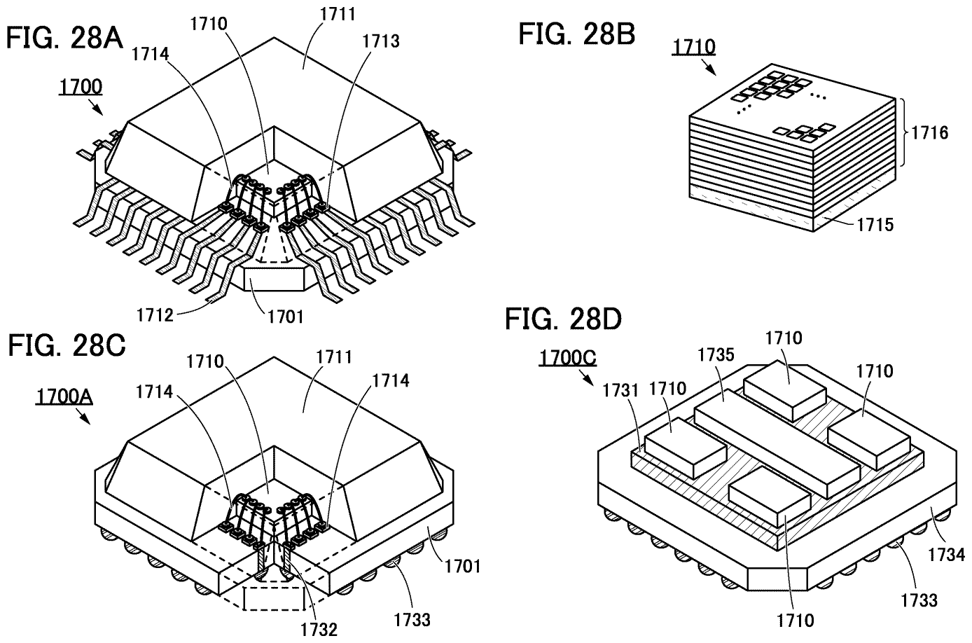

FIG. 28A is a perspective view of an electronic component 1700. The electronic component 1700 illustrated in FIG. 28A includes a substrate 1701, a semiconductor device 1710 over the substrate 1701, and a mold 1711. The semiconductor device 1710 is sealed with the mold 1711. Note that FIG. 28A omits illustrations of some parts to show the inside of the electronic component 1700.

As the substrate 1701, a ceramic substrate, a plastic substrate, or a glass epoxy substrate can be used, for example.

The electronic component 1700 is provided with a lead frame 1712, for example. Part of the lead frame 1712 positioned over the substrate 1701 is covered with the mold 1711, and another part of the lead frame 1712 is exposed outside the mold 1711. In particular, the lead frame 1712 exposed outside the mold 1711 functions as a terminal for mounting the electronic component 1700 on a printed circuit board, for example.

In the mold 1711, an electrode pad 1713 is provided over the lead frame 1712, and the electrode pad 1713 is electrically connected to the semiconductor device 1710 through a wire 1714. The electronic component 1700 is mounted on a printed circuit board by making the lead frame 1712 be in contact with a wiring on the printed circuit board side, for example. A plurality of electronic components are combined and connected to each other on the printed circuit board in this manner, which forms the circuit board.

Next, the semiconductor device 1710 will be described. As illustrated in FIG. 28B, the semiconductor device 1710 includes a driver circuit layer 1715 and a memory layer 1716. Note that the memory layer 1716 can have a structure where a plurality of memory cell arrays are stacked. The memory cell array can include the arithmetic cell described in the above embodiment, a driver cell, a memory cell, and the like. A stacked-layer structure of the driver circuit layer 1715 and the memory layer 1716 can be a monolithic stacked-layer structure. In the monolithic stacked-layer structure, layers can be connected to each other without using a through electrode technique such as through silicon via (TSV) and a bonding technique such as Cu—Cu direct bonding. The monolithic stacked-layer structure of the driver circuit layer 1715 and the memory layer 1716 enables, for example, what is called an on-chip memory structure where a memory is directly formed on a processor. The on-chip memory structure allows an interface portion between the processor and the memory to operate at high speed. For example, when the processor is the arithmetic device described in the above embodiment, the transmission speed of the first data or the second data from the memory to the arithmetic device can be increased.

With the on-chip memory structure, the sizes of a connection wiring and the like can be smaller than those of the case where the through electrode technique such as TSV is employed; thus, the number of connection pins can be increased. The increase in the number of connection pins enables parallel operation, which can improve the bandwidth of the memory (also referred to as memory bandwidth).

It is preferable that the plurality of memory cell arrays included in the memory layer 1716 be formed using IO transistors and be monolithically stacked. The monolithic stacked-layer structure of memory cell arrays can improve the bandwidth of the memory and/or the access latency of the memory. Note that the bandwidth refers to the data transfer amount per unit time, and the access latency refers to a period of time from data access to the start of data transmission. In the case where Si transistors are used for the memory layer 1716, the monolithic stacked-layer structure is difficult to form as compared with the case where IO transistors are used for the memory layer 1716. Therefore, IO transistors are superior to Si transistors in the monolithic stacked-layer structure.

The semiconductor device 1710 may be called a die. Note that in this specification and the like, a die refers to a chip piece obtained by, for example, forming a circuit pattern on a disc-like substrate (also referred to as a wafer) or the like and cutting the substrate into dies in a process of manufacturing a semiconductor chip. Examples of semiconductor materials that can be used for the die include silicon (Si), silicon carbide (SiC), and gallium nitride (GaN). For example, a die obtained from a silicon substrate (also referred to as a silicon wafer) is referred to as a silicon die in some cases.

Next, FIG. 28C illustrates a variation example of the electronic component 1700. In an electronic component 1700A illustrated in FIG. 28C, unlike in the electronic component 1700, the lead frame 1712 is not used and an electrode 1733 is provided on the bottom portion of the substrate 1701. The electrode 1733 has a function of a connection terminal for mounting the electronic component 1700A on a printed circuit board.

FIG. 28C illustrates an example where the electrodes 1733 are formed of solder balls. Solder balls are provided in a matrix on the bottom portion of the substrate 1701, so that ball grid array (BGA) mounting can be achieved. Thus, the substrate 1701 is provided with a through-hole via (through via), and a conductive layer 1732 functioning as a wiring is provided in the via. The electrode pad 1713 is provided over and in contact with the conductive layer 1732 over the substrate 1701, and the electrode 1733 is provided under and in contact with the conductive layer 1732 under the substrate 1701.

Alternatively, the electrode 1733 may be formed not of a solder ball but of a conductive pin. When conductive pins are provided in a matrix on the bottom portion of the substrate 1701, pin grid array (PGA) mounting can be achieved.

The electronic component 1700A can be mounted on another substrate by a variety of mounting methods other than BGA and PGA. Examples of a mounting method include staggered pin grid array (SPGA), land grid array (LGA), quad flat package (QFP), quad flat J-leaded package (QFJ), and quad flat non-leaded package (QFN).

The electronic component of one embodiment of the present invention may have a structure of a system in package (SiP) or a multi chip module (MCM). For example, in an electronic component 1700C illustrated in FIG. 28D, an interposer 1731 is provided on a package substrate 1734 (a printed circuit board), and a semiconductor device 1735 and a plurality of semiconductor devices 1710 are provided on the interposer 1731.

In the electronic component 1700C illustrated in FIG. 28D, the semiconductor devices 1710 are used as high bandwidth memories (HBM), for example. The semiconductor device 1735 can be used as an arithmetic circuit for an integrated circuit such as a CPU, a GPU, or a field programmable gate array (FPGA), for example.

Like the substrate 1701, the package substrate 1734 can be a ceramic substrate, a plastic substrate, or a glass epoxy substrate, for example. As the interposer 1731, a silicon interposer or a resin interposer can be used, for example.

The interposer 1731 includes a plurality of wirings and has a function of connecting a plurality of integrated circuits with different terminal pitches. The plurality of wirings are provided in a single layer or multiple layers. In addition, the interposer 1731 has a function of connecting an integrated circuit provided on the interposer 1731 to an electrode provided on the package substrate 1734. Accordingly, the interposer is referred to as a “redistribution substrate” or an “intermediate substrate” in some cases. Furthermore, a through electrode is provided in the interposer 1731 and the through electrode is used to connect an integrated circuit and the package substrate 1734 in some cases. In a silicon interposer, a through electrode can be formed by a through electrode technique such as TSV.

An HBM needs to be connected to many wirings to achieve a wide memory bandwidth. Thus, an interposer on which an HBM is mounted requires minute and densely formed wirings. For this reason, a silicon interposer is preferably used as the interposer on which an HBM is mounted.

In a SiP or an MCM that includes a silicon interposer, a decrease in reliability due to a difference in the expansion coefficient between an integrated circuit and the interposer is less likely to occur. Furthermore, a surface of a silicon interposer has high flatness; thus, poor connection between the silicon interposer and an integrated circuit provided on the silicon interposer is less likely to occur. It is particularly preferable to use a silicon interposer for a 2.5D package (2.5-dimensional mounting) in which a plurality of integrated circuits are arranged side by side on the interposer.

In the case where a plurality of integrated circuits with different terminal pitches are connected with use of a silicon interposer or a through electrode formed by TSV or the like, a space for a width of the terminal pitch and the like is needed. Accordingly, in the case where the size of the electronic component 1700C is reduced, the width of the terminal pitch becomes an issue, which sometimes makes it difficult to provide a large number of wirings for obtaining a wide memory bandwidth. For this reason, the above-described monolithic stacked-layer structure using the IO transistors is suitable. Memory cell arrays stacked using a through electrode technique such as TSV and monolithically stacked memory cell arrays can be combined, for example. A structure combining memory cell arrays stacked using a through electrode technique such as TSV and monolithically stacked memory cell arrays is referred to as a composite structure in some cases.

When the temperature of the electronic component 1700C is increased by heat generated at the time of driving, for example, various characteristics of a circuit element (e.g., a transistor) provided in the electronic component 1700C might be degraded; thus, a heat sink (a radiator plate) is preferably provided to overlap with the electronic component 1700C. In the case of providing a heat sink, integrated circuits provided on the interposer 1731 preferably have the same height. For example, in the electronic component 1700C described in this embodiment, the semiconductor devices 1710 and the semiconductor device 1735 preferably have the same height.

Note that this embodiment can be combined with the same embodiment or any of the other embodiments in this specification as appropriate. For example, the configurations, structures, methods, and the like described in this embodiment can be used in an appropriate combination with any of the other configurations, the other structures, the other methods, and the like described in this embodiment. Alternatively, for example, the configurations, structures, methods, and the like described in this embodiment can be used in an appropriate combination with any of the configurations, structures, methods, and the like described in the other embodiments and the like.

### Embodiment 6

In this embodiment, electronic devices including the electronic component described in the above embodiment and an information processing system including the electronic devices are described.

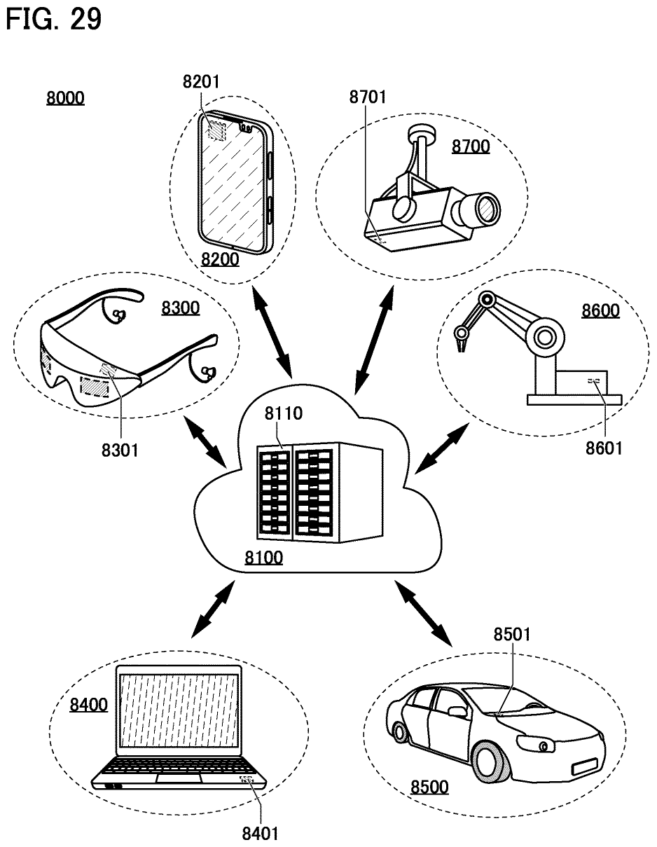

FIG. 29 illustrates a structure example of an information processing system. An information processing system 8000 illustrated in FIG. 29 includes electronic devices and a server provided in the network.

FIG. 29 illustrates, as examples of the electronic devices, a portable information terminal 8200, a wearable information terminal 8300, a laptop personal computer 8400, an automobile 8500, an industrial robot 8600, and a camera 8700. FIG. 29 also illustrates a network 8100 and a large computer 8110 provided in the network 8100.

The large computer 8110 sometimes refers to a plurality of computers installed in a server room or the like, for example. An example of the large computer 8110 is a rack mount computer in which a plurality of computers are stored in a rack. Note that the large computer 8110 is referred to as a supercomputer in some cases. In the data processing system 8000, the large computer 8110 is also referred to as a server or a cloud server in some cases.

Each of the plurality of computers included in the large computer 8110 includes a motherboard, and the motherboard is provided with a plurality of slots, a plurality of connection terminals, and the like. One or a plurality of PC cards can be inserted in the slots, for example. The PC card is an example of a processing board provided with an arithmetic processing device such as a CPU or a GPU. As the arithmetic processing device, the electronic component 1700 can be used, for example.

The large computer 8110 can also function as a parallel computer. When the large computer 8110 is used as a parallel computer, large-scale computation necessary for artificial intelligence learning and inference can be performed, for example.

For wired communication in the network 8100, an IEEE communication standard such as Ethernet (registered trademark) can be used. Examples of communication include electrical communication using an electric wire such as a twisted pair cable and optical communication using an optical fiber.

Meanwhile, for wireless communication in the network 8100, as a communication protocol or a communication technology, a communication standard such as the fourth-generation mobile communication system (4G), the fifth-generation mobile communication system (5G), or the sixth-generation mobile communication system (6G), or an IEEE communication standard such as Wi-Fi (registered trademark) or Bluetooth (registered trademark) can be used.

As the network 8100, a personal area network (PAN), a local area network (LAN), a campus area network (CAN), a metropolitan area network (MAN), a wide area network (WAN), or a global area network (GAN) can be used, for example. When a GAN is used as the network 8100, for example, the Internet, which is an infrastructure of the world wide web (WWW), can be used.

Note that in the case where the information processing system 8000 uses a LAN as the network 8100, the risk of confidential information leakage can be lower than in the case of using the Internet, for example.

A company or an individual that manages the large computer 8110 can provide a service to the user of the electronic device, using the data processing system 8000 via the network 8100, for example. An example of the service is a utility form called cloud computing. The cloud computing allows the user of the above electronic device to utilize the capability of the large computer 8110, such as large-capacity data storing or large-scale arithmetic operation, and other applications.

In particular, providing the semiconductor device of one embodiment of the present invention in the above electronic devices and the large computer 8110 enables a large-scale arithmetic operation of an artificial neural network or the like. Accordingly, the data processing system 8000 can provide a service to the user in a utility form called cloud AI or edge AI.

Cloud AI generally refers to a utility form of a service in which artificial neural network learning and inference are performed on the large computer 8110 side. When each electronic device transmits input data for the artificial neural network to the large computer 8110, which has trained on collected data in advance, the large computer 8110 performs inference on the input data. The inference result is transmitted from the large computer 8110 to each electronic device, and can be utilized on the electronic device side. Cloud AI, in which the large computer 8110 performs learning and inference, is suitable for an arithmetic operation on a large amount of data and processing including a complicated arithmetic operation.

Meanwhile, edge AI generally refers to a utility form of a service in which artificial neural network learning and inference are performed on the electronic device side. In this case, the large computer 8110 provides an artificial neural network model, a weight coefficient (sometimes referred to as weight data, a connection coefficient, or the like) to each electronic device, for example. In addition, the results of learning and inference performed on the electronic device side are transmitted to the large computer 8110. A utility form in which the large computer 8110 performs artificial neural network learning and the electronic device performs inference using the trained artificial neural network is also referred to as edge AI in some cases.

Edge AI, in which artificial neural network inference is performed by each electronic device, can reduce the necessary communication time relative to cloud AI. That is, edge AI is suitable for real-time analysis of input data. In addition, the amount of data transmitted between each electronic device and the large computer 8110 is also reduced, leading to reductions in cost and power consumption associated with data communication. Moreover, the reduction in the amount of data transmission can mitigate security risks such as information leakage. Therefore, edge AI is suitable for constructing a small-scale system, for example.

Note that the semiconductor device of one embodiment of the present invention has extremely low power consumption in a standby state, and thus can be suitably used for edge AI. Specific examples of an edge AI system will be described below.

### [Portable Information Terminal]

The portable information terminal 8200 illustrated in FIG. 29 is an electronic device in which a display device and a touch panel are integrated. The portable information terminal 8200 can include an electronic component 8201 as the electronic component 1700, and thus can perform a large-scale arithmetic operation of an artificial neural network or the like. The portable information terminal 8200 can include a camera.

When the portable information terminal 8200 includes a camera, edge AI image recognition can be performed on an image captured by the portable information terminal 8200. Examples of a recognition target include a human, an animal, a plant, letters, and a pictogram. Specifically, when performed on an image of a human face, a fingerprint, a palm print, an iris, a vein, or the like, the image recognition can be utilized for biometric authentication.

### [Wearable Information Terminal]

The wearable information terminal 8300 illustrated in FIG. 29 is an electronic device that can be worn on a human head. The wearable information terminal 8300 in FIG. 29 includes a structure body covering the eyes, a display device, a temple to be hooked on the ears, and earphones. Other examples of the wearable information terminal include a head-mounted display (HMD) and a glasses-type XR device. Like the portable information terminal 8200, the wearable information terminal 8300 can include a camera.

The wearable information terminal 8300 can include an electronic component 8301 as the electronic component 1700, and thus can perform large-scale arithmetic operation of an artificial neural network or the like.

When including a camera, the wearable information terminal 8300 can display a captured image on the display device in real-time. By performing edge AI image recognition on an image displayed on the display device, information about an object in the image can be additionally displayed on the same display device. The image recognition can also be used for risk prediction to assess potential collision hazards of moving objects such as a pedestrian, a bicycle, an automobile, and a train displayed on the display device.

### [Laptop Personal Computer]

The laptop personal computer 8400 illustrated in FIG. 29 is an electronic device mainly used on a desk. The laptop personal computer 8400 can include an electronic component 8401 as the electronic component 1700, and thus can perform a large-scale arithmetic operation of an artificial neural network or the like.

For example, the laptop personal computer 8400 can use edge AI for its arithmetic processing during application use. For example, the edge AI can be used for upconverting an image (including a still image and a moving image) on the display device for higher resolution in real time, translating text into another language, or editing text, an image, or the like.

### [Automobile]

The automobile 8500 illustrated in FIG. 29 is an example of a moving vehicle. The automobile 8500 can include an electronic component 8501 as the electronic component 1700, and thus can be used as an electronic device for the edge AI.

The edge AI in the automobile 8500 can be utilized for applications such as autonomous driving, risk prediction during autonomous driving, and air-conditioning management in the automobile, for example.

Although an automobile is described as an example of a moving vehicle in this specification, other examples of a moving vehicle include a train, a monorail train, a ship, and a flying object (e.g., a helicopter, an unmanned aircraft (drone), an airplane, or a rocket). The above-listed moving vehicles can also be used as the electronic devices for edge AI.

### [Industrial Robot]

The industrial robot 8600 illustrated in FIG. 29 can be provided in a production factory, for example. The industrial robot 8600 preferably includes a plurality of drive shafts to control its driving range minutely. The industrial robot 8600 sometimes has one or more of functions of grasping, cutting, welding, coating, and bonding an object, for example. In order to sense an object, the industrial robot 8600 preferably includes a sensor such as an image detection module, a camera, or the like. Furthermore, the industrial robot 8600 preferably includes a sensor for detecting a minute current to determine whether or not an object is grasped.

The industrial robot 8600 can include an electronic component 8601 as the electronic component 1700, and thus can be used as an electronic device for the edge AI. The edge AI in the industrial robot 8600 can be utilized for applications such as classifying objects by type or size and inspecting products to determine whether it is good or defective through image recognition.

### [Camera]

The camera 8700 illustrated in FIG. 29 can be used as a surveillance camera, a security camera, or a pet camera, for example. The housing of the camera 8700 can be placed in various ways; for example, it can be placed on a desk or attached to a wall, without limited to being mounted on a ceiling as illustrated in FIG. 29.

Note that a surveillance camera, a security camera, or a pet camera is a common name and does not limit its use. For example, a pet camera may be used as a surveillance camera or a security camera, and vice versa. The camera 8700 is also referred to as a video camera in some cases.

The camera 8700 can include an electronic component 8701 as the electronic component 1700, and thus can be used as an electronic device for the edge AI. The edge AI in the camera 8700 can be utilized for security purposes to detect a moving object in an image (a still image and a moving image) captured by the camera 8700, for example. In addition, the edge AI in the camera 8700 can also be utilized for disaster prevention to detect river flooding or tsunamis.

Note that this embodiment can be combined with the same embodiment or any of the other embodiments in this specification as appropriate. For example, the configurations, structures, methods, and the like described in this embodiment can be used in an appropriate combination with any of the other configurations, the other structures, the other methods, and the like described in this embodiment. Alternatively, for example, the configurations, structures, methods, and the like described in this embodiment can be used in an appropriate combination with any of the configurations, structures, methods, and the like described in the other embodiments and the like.

### Embodiment 7

An electronic device, space equipment, and a data center (also referred to as DC) for which the semiconductor device described in the above embodiments can be used are described in this embodiment. Note that space equipment and a data center are effective in improving performance, e.g., reducing power consumption.

### [Space Equipment]

The semiconductor device of one embodiment of the present invention can be suitably used for space equipment (e.g., equipment having a function of processing and storing information).

The semiconductor device of one embodiment of the present invention can include an IO transistor. A change in electrical characteristics of the IO transistor due to radiation irradiation is small. That is, the IO transistor is highly resistant to radiation, and thus can be suitably used in an environment where radiation can enter. For example, the IO transistor can be suitably used in outer space.

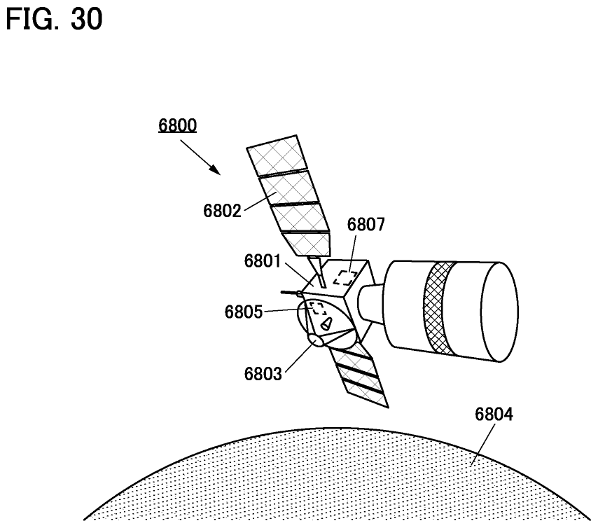

FIG. 30 illustrates an artificial satellite 6800 as an example of space equipment. The artificial satellite 6800 includes a body 6801, a solar panel 6802, an antenna 6803, a secondary battery 6805, and a control device 6807. In FIG. 30, a planet 6804 in outer space is illustrated. Note that outer space refers to, for example, space at an altitude greater than or equal to 100 km, and outer space in this specification also include thermosphere, mesosphere, and stratosphere.

Although not illustrated in FIG. 30, a battery management system (also referred to as BMS) or a battery control circuit may be provided in the secondary battery 6805. The battery management system or the battery control circuit preferably includes an IO transistor, in which case low power consumption and high reliability are achieved even in outer space.

The amount of radiation in outer space is 100 or more times that on the ground. Examples of radiation include electromagnetic waves (electromagnetic radiation) typified by X-rays and gamma rays and particle radiation typified by alpha rays, beta rays, neutron beams, proton beams, heavy-ion beams, and meson beams.

When the solar panel 6802 is irradiated with sunlight, electric power required for operation of the artificial satellite 6800 is generated. However, for example, in the situation where the solar panel is not irradiated with sunlight or the situation where the amount of sunlight with which the solar panel is irradiated is small, the amount of generated electric power is small. Accordingly, a sufficient amount of electric power required for operation of the artificial satellite 6800 might not be generated. In order to operate the artificial satellite 6800 even with a small amount of generated electric power, the artificial satellite 6800 is preferably provided with the secondary battery 6805. Note that a solar panel is referred to as a solar cell module in some cases.

The artificial satellite 6800 can generate a signal. The signal is transmitted through the antenna 6803, and can be received by a ground-based receiver or another artificial satellite, for example. When the signal transmitted by the artificial satellite 6800 is received, the position of a receiver that receives the signal can be measured. Thus, the artificial satellite 6800 can construct a satellite positioning system.

The control device 6807 has a function of controlling the artificial satellite 6800. The control device 6807 is formed with one or more selected from a CPU, a GPU, and a memory circuit, for example. Note that the semiconductor device of one embodiment of the present invention is suitably used for the control device 6807. A change in electrical characteristics due to radiation irradiation is smaller in an IO transistor than in a Si transistor. Accordingly, the IO transistor has high reliability and thus can be suitably used even in an environment where radiation can enter.

The artificial satellite 6800 can include a sensor. For example, with a structure including a visible light sensor, the artificial satellite 6800 can have a function of detecting sunlight reflected by a ground-based object. Alternatively, with a structure including a thermal infrared sensor, the artificial satellite 6800 can have a function of detecting thermal infrared rays emitted from the surface of the earth. Thus, the artificial satellite 6800 can function as an earth observing satellite, for example.

Although the artificial satellite is described as an example of space equipment in this embodiment, one embodiment of the present invention is not limited to this example. The semiconductor device of one embodiment of the present invention is suitably used also for space equipment such as a spacecraft, a space capsule, or a space probe, for example.

As described above, the IO transistor has advantageous effects over the Si transistor, such as a wide memory bandwidth and high radiation resistance.

### [Data Center]

The semiconductor device of one embodiment of the present invention can be suitably used for, for example, a storage system in a data center or the like. Long-term management of data, such as guarantee of data immutability, is required for the data center. In the case where data is managed for a long term, it is necessary to increase the scale of data center facility for installation of storages and servers for storing an enormous amount of data, stable electric power for data retention, cooling equipment for data retention, or the like. The data center preferably has a function of performing an arithmetic operation of data, and further preferably has a high arithmetic operation speed.

With use of the semiconductor device of one embodiment of the present invention for a storage system in a data center, electric power used for an arithmetic operation can be reduced and the arithmetic operation speed can be increased.

Since the semiconductor device of one embodiment of the present invention has low power consumption, heat generation from a circuit can be reduced. Accordingly, adverse effects of the heat generation on the circuit itself, the peripheral circuit, and the module can be reduced. Furthermore, the use of the semiconductor device of one embodiment of the present invention enables a data center that operates stably even in a high temperature environment. Thus, the reliability of the data center can be increased.

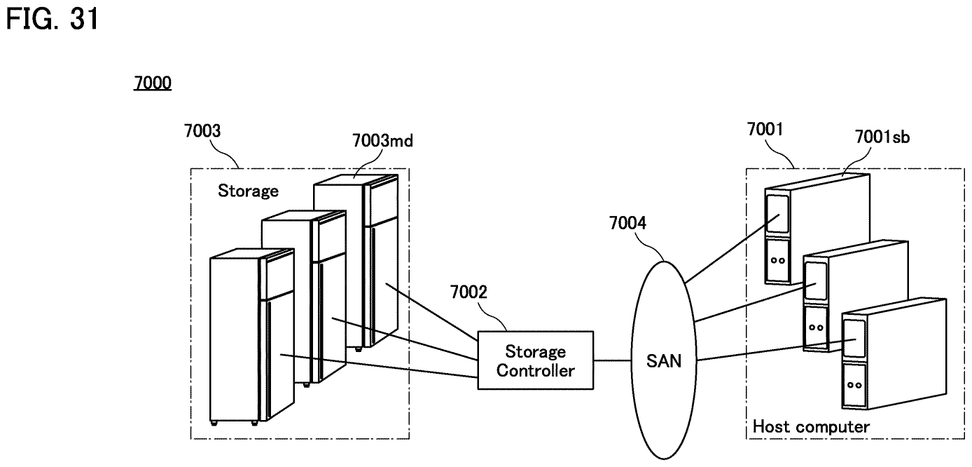

FIG. 31 illustrates a storage system that can be used in a data center. A storage system 7000 illustrated in FIG. 31 includes a plurality of servers 7001sb as a host 7001 (indicated as “Host computer” in the diagram). The storage system 7000 includes a plurality of memory devices 7003md as a storage 7003 (indicated as “Storage” in the diagram). In the illustrated example, the host 7001 and the storage 7003 are connected to each other via a storage area network 7004 (indicated as “SAN” in the diagram) and a storage control circuit 7002 (indicated as “Storage Controller” in the diagram).

The host 7001 can be a computer that accesses data stored in the storage 7003. The host 7001 is connected to another host 7001 via a network in some cases.

The data access speed, i.e., the time taken for storing and outputting data, of the storage 7003 is shortened by using a flash memory, but the time is considerably longer than the time required for a dynamic random access memory (DRAM) that can be used as a cache memory in a storage. In the storage system, in order to solve the problem of low access speed of the storage 7003, a cache memory is normally provided in the storage to shorten the time taken for storing and outputting data.

The above-described cache memory is used in the storage control circuit 7002 and the storage 7003. The data transmitted between the host 7001 and the storage 7003 is stored in the cache memories in the storage control circuit 7002 and the storage 7003 and then output to the host 7001 or the storage 7003.

With a configuration in which an IO transistor is used as a transistor for storing data in the cache memory to retain a potential corresponding to data, the frequency of refreshing can be decreased, so that power consumption can be reduced. Furthermore, downscaling is possible by stacking memory cell arrays.

The use of the semiconductor device of one embodiment of the present invention for one or more selected from an electronic component, an electronic device, a large computer, space equipment, and a data center that are described in the above embodiments will produce an effect of reducing power consumption. While the demand for energy is expected to increase with higher performance or higher integration of the above-described component, device, data center, and the like, the emission amount of greenhouse effect gases typified by carbon dioxide (CO₂) can be reduced with use of the semiconductor device of one embodiment of the present invention. Furthermore, the semiconductor device of one embodiment of the present invention has low power consumption and thus is effective as a global warming countermeasure.

Note that this embodiment can be combined with the same embodiment or any of the other embodiments in this specification as appropriate. For example, the configurations, structures, methods, and the like described in this embodiment can be used in an appropriate combination with any of the other configurations, the other structures, the other methods, and the like described in this embodiment. Alternatively, for example, the configurations, structures, methods, and the like described in this embodiment can be used in an appropriate combination with any of the configurations, structures, methods, and the like described in the other embodiments and the like.

This application is based on Japanese Patent Application Serial No. 2025-078586 filed with Japan Patent Office on May 9, 2025, the entire contents of which are hereby incorporated by reference.

What is claimed is:

1. A semiconductor device comprising:
a first circuit; and
a second circuit,
wherein the first circuit comprises a first input terminal, a second input terminal, and a first output terminal,
wherein the second circuit comprises a third input terminal, a fourth input terminal, and a second output terminal,
wherein the first circuit is configured to hold a first potential corresponding to a first current flowing through the first input terminal, generate a second current corresponding to the first potential, and make a fourth current flow through the first output terminal as a differential current between a third current flowing through the second input terminal and the second current, and
wherein the second circuit is configured to hold a second potential corresponding to the third current flowing through the third input terminal, generate a fifth current corresponding to the second potential, and make a sixth current flow through the second output terminal as a differential current between the first current flowing through the fourth input terminal and the fifth current.

2. The semiconductor device according to claim 1,
wherein each of the first circuit and the second circuit comprises a first transistor, a second transistor, a third transistor, a fourth transistor, a fifth transistor, and a first capacitor,
wherein in each of the first circuit and the second circuit, one of a source and a drain of the first transistor is electrically connected to one of a source and a drain of the second transistor, one of a source and a drain of the third transistor, one of a source and a drain of the fourth transistor, and one of a source and a drain of the fifth transistor, and the other of the source and the drain of the fifth transistor is electrically connected to a gate of the fourth transistor and a first terminal of the first capacitor,
wherein in the first circuit, the other of the source and the drain of the first transistor is electrically connected to the first input terminal, the other of the source and the drain of the second transistor is electrically connected to the second input terminal, and the other of the source and the drain of the third transistor is electrically connected to the first output terminal,
wherein in the second circuit, the other of the source and the drain of the first transistor is electrically connected to the third input terminal, the other of the source and the drain of the second transistor is electrically connected to the fourth input terminal, and the other of the source and the drain of the third transistor is electrically connected to the second output terminal,
wherein the first input terminal is electrically connected to the fourth input terminal, and
wherein the second input terminal is electrically connected to the third input terminal.

3. The semiconductor device according to claim 2,
wherein, in each of the first circuit and the second circuit:
a gate of the first transistor is electrically connected to a first wiring;
a gate of the second transistor is electrically connected to a second wiring;
a gate of the third transistor is electrically connected to a third wiring; and
a gate of the fifth transistor is electrically connected to a fourth wiring.

4. The semiconductor device according to claim 2,
wherein, in each of the first circuit and the second circuit:
each of the first transistor, the second transistor, the third transistor, and the fourth transistor comprises silicon in a channel formation region;
the fifth transistor comprises an oxide semiconductor in a channel formation region; and
all of the first transistor, the second transistor, the third transistor, and the fourth transistor are n-channel transistors or p-channel transistors.

5. A semiconductor device comprising:
a first circuit;
a second circuit;
a first current generation circuit;
a second current generation circuit; and
a current supply circuit,
wherein the first circuit comprises a first input terminal, a second input terminal, and a first output terminal,
wherein the second circuit comprises a third input terminal, a fourth input terminal, and a second output terminal,
wherein the first current generation circuit comprises a fifth input terminal, a sixth input terminal, and a third output terminal,
wherein the second current generation circuit comprises a seventh input terminal, an eighth input terminal, and a fourth output terminal,
wherein the current supply circuit comprises a fifth output terminal and a sixth output terminal,
wherein the first circuit is configured to hold a first potential corresponding to a first current flowing through the first input terminal, generate a second current corresponding to the first potential, and make a fourth current flow through the first output terminal as a differential current between a third current flowing through the second input terminal and the second current,
wherein the second circuit is configured to hold a second potential corresponding to the third current flowing through the third input terminal, generate a fifth current corresponding to the second potential, and make a sixth current flow through the second output terminal as a differential current between the first current flowing through the fourth input terminal and the fifth current,
wherein the current supply circuit is configured to generate a seventh current flowing through the fifth output terminal and an eighth current flowing through the sixth output terminal,
wherein the first current generation circuit is configured to generate a ninth current flowing through the third output terminal with reference to the smaller of the fourth current flowing through the fifth input terminal and the seventh current flowing through the sixth input terminal, and
wherein the second current generation circuit is configured to generate a tenth current flowing through the fourth output terminal with reference to the smaller of the sixth current flowing through the seventh input terminal and the eighth current flowing through the eighth input terminal.

6. The semiconductor device according to claim 5,
wherein each of the first circuit and the second circuit comprises a first transistor, a second transistor, a third transistor, a fourth transistor, a fifth transistor, and a first capacitor,
wherein in each of the first circuit and the second circuit, one of a source and a drain of the first transistor is electrically connected to one of a source and a drain of the second transistor, one of a source and a drain of the third transistor, one of a source and a drain of the fourth transistor, and one of a source and a drain of the fifth transistor, and the other of the source and the drain of the fifth transistor is electrically connected to a gate of the fourth transistor and a first terminal of the first capacitor,
wherein in the first circuit, the other of the source and the drain of the first transistor is electrically connected to the first input terminal, the other of the source and the drain of the second transistor is electrically connected to the second input terminal, and the other of the source and the drain of the third transistor is electrically connected to the first output terminal,
wherein in the second circuit, the other of the source and the drain of the first transistor is electrically connected to the third input terminal, the other of the source and the drain of the second transistor is electrically connected to the fourth input terminal, and the other of the source and the drain of the third transistor is electrically connected to the second output terminal,
wherein the first input terminal is electrically connected to the fourth input terminal, and
wherein the second input terminal is electrically connected to the third input terminal.

7. The semiconductor device according to claim 6,
wherein each of the first current generation circuit and the second current generation circuit comprises a sixth transistor, a seventh transistor, an eighth transistor, a ninth transistor, a tenth transistor, and an eleventh transistor,
wherein in the first current generation circuit, one of a source and a drain of the sixth transistor is electrically connected to the fifth input terminal, one of a source and a drain of the seventh transistor is electrically connected to the sixth input terminal, one of a source and a drain of the eighth transistor is electrically connected to the third output terminal, a gate of the sixth transistor, a gate of the seventh transistor, and a gate of the eighth transistor are electrically connected to one of the fifth input terminal and the sixth input terminal, and a gate of the ninth transistor, a gate of the tenth transistor, and a gate of the eleventh transistor are electrically connected to the other of the fifth input terminal and the sixth input terminal,
wherein in the second current generation circuit, one of the source and the drain of the sixth transistor is electrically connected to the seventh input terminal, one of the source and the drain of the seventh transistor is electrically connected to the eighth input terminal, one of the source and the drain of the eighth transistor is electrically connected to the fourth output terminal, the gate of the sixth transistor, the gate of the seventh transistor, and the gate of the eighth transistor are electrically connected to one of the seventh input terminal and the eighth input terminal, and the gate of the ninth transistor, the gate of the tenth transistor, and the gate of the eleventh transistor are electrically connected to the other of the seventh input terminal and the eighth input terminal, and
wherein in each of the first current generation circuit and the second current generation circuit, the other of the source and the drain of the sixth transistor is electrically connected to one of a source and a drain of the ninth transistor, the other of the source and the drain of the seventh transistor is electrically connected to one of a source and a drain of the tenth transistor, and the other of the source and the drain of the eighth transistor is electrically connected to one of a source and a drain of the eleventh transistor.

8. The semiconductor device according to claim 7,
wherein, in each of the first circuit and the second circuit:
a gate of the first transistor is electrically connected to a first wiring;
a gate of the second transistor is electrically connected to a second wiring;
a gate of the third transistor is electrically connected to a third wiring; and
a gate of the fifth transistor is electrically connected to a fourth wiring.

9. The semiconductor device according to claim 7,
wherein each of the first transistor, the second transistor, the third transistor, and the fourth transistor in the first circuit and the second circuit comprises silicon in a channel formation region,
wherein the fifth transistor in the first circuit and the second circuit comprises an oxide semiconductor in a channel formation region,
wherein each of the sixth transistor, the seventh transistor, the eighth transistor, the ninth transistor, the tenth transistor, and the eleventh transistor in the first current generation circuit and the second current generation circuit comprises silicon in a channel formation region,
wherein all of the first transistor, the second transistor, the third transistor, and the fourth transistor in the first circuit and the second circuit are n-channel transistors or p-channel transistors,
wherein all of the sixth transistor, the seventh transistor, the eighth transistor, the ninth transistor, the tenth transistor, and the eleventh transistor in the first current generation circuit and the second current generation circuit are p-channel transistors when all of the first transistor, the second transistor, the third transistor, and the fourth transistor in the first circuit and the second circuit are n-channel transistors, and
wherein all of the sixth transistor, the seventh transistor, the eighth transistor, the ninth transistor, the tenth transistor, and the eleventh transistor in the first current generation circuit and the second current generation circuit are n-channel transistors when all of the first transistor, the second transistor, the third transistor, and the fourth transistor in the first circuit and the second circuit are p-channel transistors.
